(19) United States
(12) Patent Application Publication
(10) Pub. No.: US 2026/0271392 A1
(43) Pub. Date: Sep. 10, 2026

(54) INTEGRATED CIRCUIT DEVICE

(71) Applicant: Samsung Electronics Co., Ltd., Suwon-si (KR)

(72) Inventors: Ohseong Kwon, Suwon-si (KR); Jaeyeol Song, Suwon-si (KR); Jeonghyuk Yim, Suwon-si (KR)

(21) Appl. No.: 19/330,287

(22) Filed: Sep. 16, 2025

(30) Foreign Application Priority Data
Mar. 5, 2025 (KR) 10-2025-0028378

(51) Int. Cl. H10D 84/85; H10D 84/01; H10D 84/83

(52) U.S. Cl. CPC H10D 84/851; H10D 84/0177; H10D 84/83135

(57) ABSTRACT

An integrated circuit device includes a fin-type active region extending in a first horizontal direction, a nanosheet stack apart in a vertical direction from a fin top surface of the fin-type active region and including a plurality of nanosheets vertically overlapping the fin top surface, a device isolation film covering sidewalls of the fin-type active region, and a gate line extending in a second horizontal direction on the fin-type active region and the device isolation film and including a work-function metal-containing structure surrounding the nanosheets, wherein the second horizontal direction intersects the first horizontal direction, wherein a first thickness in the vertical direction of a portion of the work-function metal-containing structure, which covers a top surface of the nanosheet stack, is greater than a second thickness in the second horizontal direction of a portion of the work-function metal-containing structure, which covers a sidewall of the nanosheet stack.

### CROSS-REFERENCE TO RELATED APPLICATION

This application is based on and claims priority under 35 U.S.C. §119 to Korean Patent Application No. 10-2025-0028378, filed on Mar. 5, 2025, in the Korean Intellectual Property Office, the disclosure of which is incorporated by reference herein in its entirety.

### BACKGROUND

The inventive concept relates to an integrated circuit (IC) device, and more particularly, to an IC device including a field-effect transistor (FET).

Due to development of electronics technology, downscaling of integrated circuit (IC) devices has rapidly progressed. Because highly downscaled IC devices require not only high operation speed but also high operation accuracy, it is necessary to develop a method of manufacturing an IC device that has a stable structure within a relatively small area and that is capable of improving the performance and reliability of FETs.

### SUMMARY

The inventive concept provides an integrated circuit (IC) device including a transistor region having a reduced area with the downscaling trend. The IC device may have a stable structure and improved performance and improved reliability of field-effect transistors (FETs).

According to an aspect of the inventive concept, there is provided an IC device including a fin-type active region extending in a first horizontal direction, a nanosheet stack spaced apart in a vertical direction from a fin top surface of the fin-type active region, the nanosheet stack including a plurality of nanosheets vertically overlapping the fin top surface of the fin-type active region, a device isolation film covering sidewalls of the fin-type active region, and a gate line extending in a second horizontal direction on the fin-type active region and the device isolation film, the gate line including a work-function metal-containing structure surrounding the plurality of nanosheets, wherein the second horizontal direction intersects the first horizontal direction, wherein a first thickness in the vertical direction of a portion of the work-function metal-containing structure, which covers a top surface of the nanosheet stack, is greater than a second thickness in the second horizontal direction of a portion of the work-function metal-containing structure, which covers a sidewall of the nanosheet stack.

According to another aspect of the inventive concept, there is provided an IC device including a first fin-type active region extending in a first horizontal direction in a first transistor region, a second fin-type active region extending in the first horizontal direction in a second transistor region, a first nanosheet stack spaced apart in a vertical direction from a first fin top surface of the first fin-type active region, the first nanosheet stack including a plurality of first region nanosheets vertically overlapping the first fin top surface of the first fin-type active region, a second nanosheet stack spaced apart in the vertical direction from a second fin top surface of the second fin-type active region, the second nanosheet stack including a plurality of second region nanosheets vertically overlapping the second fin top surface of the second fin-type active region, a gate line surrounding the plurality of first region nanosheets and the plurality of second region nanosheets, the gate line extending in a second horizontal direction, wherein the second horizontal direction intersects the first horizontal direction, wherein the gate line includes a blanket work-function metal-containing layer of a first conductivity type surrounding the plurality of first region nanosheets, and a work-function metal-containing structure of a second conductivity type surrounding the plurality of second region nanosheets, wherein a first thickness in the vertical direction of a portion of the work-function metal-containing structure, which covers a top surface of the second nanosheet stack, is greater than a second thickness in the second horizontal direction of a portion of the work-function metal-containing structure, which covers a sidewall of the second nanosheet stack.

According to another aspect of the inventive concept, there is provided an IC device including a first fin-type active region extending in a first horizontal direction in an NMOS transistor region, a second fin-type active region extending in the first horizontal direction in a PMOS transistor region, a device isolation film covering both sidewalls of the first fin-type active region and the second fin-type active region in a second horizontal direction, wherein the second horizontal direction intersects the first horizontal direction, a first nanosheet stack spaced apart in a vertical direction from a first fin top surface of the first fin-type active region, the first nanosheet stack including a plurality of first region nanosheets vertically overlapping the first fin top surface of the first fin-type active region, a second nanosheet stack spaced apart in the vertical direction from a second fin top surface of the second fin-type active region, the second nanosheet stack including a plurality of second region nanosheets vertically overlapping the second fin top surface of the second fin-type active region, and a gate line extending in the second horizontal direction on the first fin-type active region, the second fin-type active region, and the device isolation film, wherein the gate line includes a P-type work-function metal-containing structure surrounding the plurality of second region nanosheets, and an N-type blanket work-function metal-containing layer including a portion surrounding the plurality of first region nanosheets and a portion surrounding the plurality of second region nanosheets and the P-type work-function metal-containing structure, wherein a first thickness in the vertical direction of a portion of the P-type work-function metal-containing structure, which covers a top surface of the second nanosheet stack, is greater than a second thickness in the second horizontal direction of a portion of the P-type work-function metal-containing structure, which covers a sidewall of the second nanosheet stack, and each of both sidewalls of the P-type work-function metal-containing structure in the second horizontal direction includes concave surfaces and convex surfaces.

According to another aspect of the inventive concept, there is provided a method of manufacturing an IC device. The method includes forming a fin-type active region extending in a first horizontal direction on a substrate, forming a device isolation film to cover sidewalls of the fin-type active region, forming a nanosheet stack apart in a vertical direction from a fin top surface of the fin-type active region, the nanosheet stack including a plurality of nanosheets vertically overlapping the fin top surface of the fin-type active region, and forming a gate line extending in a second horizontal direction on the fin-type active region and the device isolation film, the gate line surrounding the plurality of nanosheets, wherein the second horizontal direction intersects the first horizontal direction, wherein the formation of the gate line includes forming a work-function metal-containing structure configured such that a first thickness in the vertical direction of a portion covering a top surface of the nanosheet stack is greater than a second thickness in the second horizontal direction of a portion covering a sidewall of the nanosheet stack.

In embodiments, the formation of the work-function metal-containing structure may include forming rough surfaces in both sidewalls of the work-function metal-containing structure in the second horizontal direction.

In other embodiments, the formation of the work-function metal-containing structure may include forming a plurality of work-function metal-containing patterns respectively between the plurality of nanosheets, the plurality of work-function metal-containing patterns being arranged in a line in the vertical direction, forming a work-function metal-containing liner to cover the plurality of nanosheets and the plurality of work-function metal-containing patterns, and forming an upper work-function metal-containing block to cover an uppermost surface of the work-function metal-containing liner. During the formation of the upper work-function metal-containing block, a thickness of the upper work-function metal-containing block in the vertical direction is greater than a thickness of each of the plurality of work-function metal-containing patterns in the vertical direction.

In other embodiments, during the formation of the plurality of work-function metal-containing patterns, in the second horizontal direction, a width of each of the plurality of work-function metal-containing patterns may be less than or equal to a width of each of the plurality of nanosheets.

In other embodiments, the formation of the work-function metal-containing liner may include forming a vertical extension of the work-function metal-containing liner to cover a sidewall of each of the plurality of nanosheets and the plurality of work-function metal-containing patterns and forming a lateral extension of the work-function metal-containing liner overlapping the device isolation film in the vertical direction. The formation of the work-function metal-containing structure further includes forming a lower work-function metal-containing block to cover the lateral extension of the work-function metal-containing liner at a position overlapping the device isolation film in the vertical direction, wherein, in the vertical direction, a thickness of the lower work-function metal-containing block is less than a thickness of the upper work-function metal-containing block.

In other embodiments, during the formation of the work-function metal-containing structure, the first thickness of the work-function metal-containing structure may be greater than a third thickness in the vertical direction of a portion of the work-function metal-containing structure, which covers the device isolation film.

In other embodiments, after the formation of the nanosheet stack and before the formation of the gate line, the method may further include forming a gate dielectric film to cover the plurality of nanosheets. The formation of the work-function metal-containing structure includes respectively forming a plurality of work-function metal-containing patterns between the plurality of nanosheets, the plurality of work-function metal-containing patterns being arranged in a line in the vertical direction and being in contact with the gate dielectric film, forming a work-function metal-containing liner in contact with the gate dielectric film to cover the plurality of nanosheets and the plurality of work-function metal-containing patterns, and forming an upper work-function metal-containing block to cover an uppermost surface of the work-function metal-containing liner, the upper work-function metal-containing block being spaced apart in the vertical direction from the gate dielectric film with the work-function metal-containing liner therebetween.

In other embodiments, the formation of the gate line may further include forming a blanket work-function metal-containing layer to surround the work-function metal-containing structure on the fin-type active region, and the blanket work-function metal-containing layer may have a conductivity type different from a conductivity type of the work-function metal-containing structure.

In other embodiments, the formation of the work-function metal-containing structure may include forming rough surfaces in both sidewalls of the work-function metal-containing structure in the second horizontal direction, and the formation of the blanket work-function metal-containing layer may include forming a plurality of protrusions in contact with the rough surfaces. The plurality of protrusions may protrude toward respective regions between the plurality of nanosheets in a second horizontal direction.

According to another aspect of the inventive concept, there is provided a method of manufacturing an IC device. The method includes forming a first fin-type active region located in a first transistor region on a substrate and a second fin-type active region located in a second transistor region on the substrate, the first fin-type active region and the second fin-type active region each extending in a first horizontal direction, forming a first nanosheet stack located on a first fin top surface of the first fin-type active region and a second nanosheet stack located on a second fin top surface of the second fin-type active region, the first nanosheet stack including a plurality of first region nanosheets, and the second nanosheet stack including a plurality of second region nanosheets, and forming a gate line surrounding the plurality of first region nanosheets and the plurality of second region nanosheets, the gate line extending in a second horizontal direction, wherein the second horizontal direction intersects the first horizontal direction, wherein the formation of the gate line includes forming a work-function metal-containing structure in which a first thickness in the vertical direction of a portion covering a top surface of the second nanosheet stack is greater than a second thickness in the second horizontal direction of a portion covering a sidewall of the second nanosheet stack in the second transistor region, and forming a blanket work-function metal-containing layer surrounding the plurality of first region nanosheets in the first transistor region and surrounding the plurality of second region nanosheets and the work-function metal-containing structure in the second transistor region, wherein the blanket work-function metal-containing layer includes a metal-containing film of a first conductivity type, and the work-function metal-containing structure includes a metal-containing film of a second conductivity type.

In embodiments, the formation of the work-function metal-containing structure may include forming rough surfaces in both sidewalls of the work-function metal-containing structure in the second horizontal direction.

In other embodiments, the formation of the blanket work-function metal-containing layer may include forming a plurality of protrusions opposite to the rough surfaces in the blanket work-function metal-containing layer.

In other embodiments, the formation of the work-function metal-containing structure may include forming a plurality of work-function metal-containing patterns respectively arranged between the plurality of second region nanosheets, the plurality of work-function metal-containing being arranged in a line in the vertical direction, forming a work-function metal-containing liner to cover the plurality of second region nanosheets and the plurality of work-function metal-containing patterns, and forming an upper work-function metal-containing block to cover an uppermost surface of the work-function metal-containing liner in the second transistor region. During the formation of the upper work-function metal-containing block, a thickness of the upper work-function metal-containing block in the vertical direction is greater than a thickness of each of the plurality of work-function metal-containing patterns in the vertical direction.

In other embodiments, during the formation of the plurality of work-function metal-containing patterns, in the second horizontal direction, a width of each of the plurality of work-function metal-containing patterns may be less than or equal to a width of each of the plurality of second region nanosheets.

In other embodiments, during the formation of the plurality of work-function metal-containing patterns, in the second horizontal direction, a width of each of the plurality of work-function metal-containing patterns may be greater than or equal to a width of each of the plurality of second region nanosheets.

In other embodiments, after the formation of the first fin-type active region and the second fin-type active region, the method may further include forming a device isolation film to cover sidewalls of each of the first fin-type active region and the second fin-type active region. The formation of the work-function metal-containing liner may include forming a vertical extension of the work-function metal containing liner and a lateral extension of the work-function metal-containing liner, the vertical extension covering a sidewall of each of the plurality of second region nanosheets, and the lateral extension overlapping the device isolation film in the vertical direction. The formation of the work-function metal-containing structure may further include forming a lower work-function metal-containing block when the upper work-function metal-containing block is formed. The lower work-function metal-containing block may cover the lateral extension of the work-function metal-containing liner at a position overlapping the device isolation film in the vertical direction and be spaced apart from the upper work-function metal-containing block. In the vertical direction, a thickness of the lower work-function metal-containing block may be less than a thickness of the upper work-function metal-containing block.

In other embodiments, after the formation of the first fin-type active region and the second fin-type active region, the method may further include forming a device isolation film to cover sidewalls of each of the first fin-type active region and the second fin-type active region. During the formation of the work-function metal-containing structure, the first thickness of the work-function metal-containing structure may be greater than a third thickness in the vertical direction of a portion of the work-function metal-containing structure, which covers the device isolation film.

In other embodiments, the formation of the gate line may further include forming a gap-fill metal film to cover the blanket work-function metal-containing layer in the first transistor region and the second transistor region. In the second transistor region, the gap-fill metal film may be spaced apart from the work-function metal-containing structure with the blanket work-function metal-containing layer therebetween.

According to another aspect of the inventive concept, there is provided a method of manufacturing an IC device. The method includes forming a first fin-type active region located in a first transistor region on a substrate and a second fin-type active region located in a second transistor region on the substrate, the first fin-type active region and the second fin-type active region each extending in a first horizontal direction, forming a device isolation film to cover sidewalls of each of the first fin-type active region and the second fin-type active region, forming a first nanosheet stack located on a first fin top surface of the first fin-type active region and a second nanosheet stack located on a second fin top surface of the second fin-type active region, the first nanosheet stack including a plurality of first region nanosheets, the second nanosheet stack including a plurality of second region nanosheets, and forming a gate line surrounding the plurality of first region nanosheets and the plurality of second region nanosheets, the gate line extending in a second horizontal direction on the first fin-type active region, the second fin-type active region, and the device isolation film, wherein the second horizontal direction intersects the first horizontal direction, wherein the formation of the gate line includes forming a work-function metal-containing structure configured such that a first thickness in the vertical direction of a portion covering a top surface of the second nanosheet stack is greater than a second thickness in the second horizontal direction of a portion covering a sidewall of the second nanosheet stack in the second transistor region, the work-function metal-containing structure having rough surfaces in both sidewalls of the second horizontal direction, and forming a blanket work-function metal-containing layer surrounding the plurality of first region nanosheets in the first transistor region and surrounding the plurality of second region nanosheets and the work-function metal-containing structure in the second transistor region, wherein the formation of the work-function metal-containing structure includes respectively forming a plurality of work-function metal-containing patterns between the plurality of second region nanosheets, the plurality of work-function metal-containing patterns being arranged in a line in the vertical direction, forming a work-function metal-containing liner to cover the plurality of second region nanosheets and the plurality of work-function metal-containing patterns, and forming an upper work-function metal-containing block and a lower work-function metal-containing block in the second transistor region, the upper work-function metal-containing block covering an uppermost surface of the work-function metal-containing liner, the lower work-function metal-containing block being spaced apart from the upper work-function metal-containing block and having a smaller thickness than the upper work-function metal-containing block in the vertical direction.

In embodiments, the formation of the blanket work-function metal-containing layer may include forming a plurality of protrusions opposite to the rough surfaces in the blanket work-function metal-containing layer.

### BRIEF DESCRIPTION OF THE DRAWINGS

Embodiments will be more clearly understood from the following detailed description taken in conjunction with the accompanying drawings in which:

FIG. 1 is a plan layout diagram of an integrated circuit (IC) device according to embodiments;

FIG. 2 is a cross-sectional view taken along line X1 - X1' of FIG. 1;

FIG. 3 is a cross-sectional view taken along line Y1 - Y1' of FIG. 1;

FIG. 4 is an enlarged cross-sectional view of portion "EX1" of FIG. 3;

FIGS. 5 and 6 are respectively cross-sectional views of IC devices according to other embodiments;

FIGS. 7 and 8 are cross-sectional views of an IC device according to other embodiments;

FIGS. 9A to 15B are cross-sectional views of a process sequence of a method of manufacturing an IC device, according to embodiments, wherein FIGS. 9A, 11A, 12A, 13A, 14A, and 15A are cross-sectional views of example cross-sectional structures of a portion corresponding to a cross-section taken along line X1 - X1' of FIG. 1, according to a process sequence, and FIGS. 9B, 10, 11B, 12B, 13B, 14B and 15B are cross-sectional views of example cross-sectional structures of a portion corresponding to a cross-section taken along line Y1 - Y1' of FIG. 1, according to a process sequence; and

FIGS. 16A to 16Q are cross-sectional views of enlarged cross-sectional configurations corresponding to portion "EX1A" of FIG. 14B, according to a process sequence, to specifically explain a method of manufacturing an IC device, according to embodiments.

### DETAILED DESCRIPTION OF THE EMBODIMENTS

Hereinafter, embodiments will be described in detail with reference to the accompanying drawings. The same reference numerals are used to denote the same elements in the drawings, and repeated descriptions thereof will be omitted.

Throughout the specification, when a component is described as "including" a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

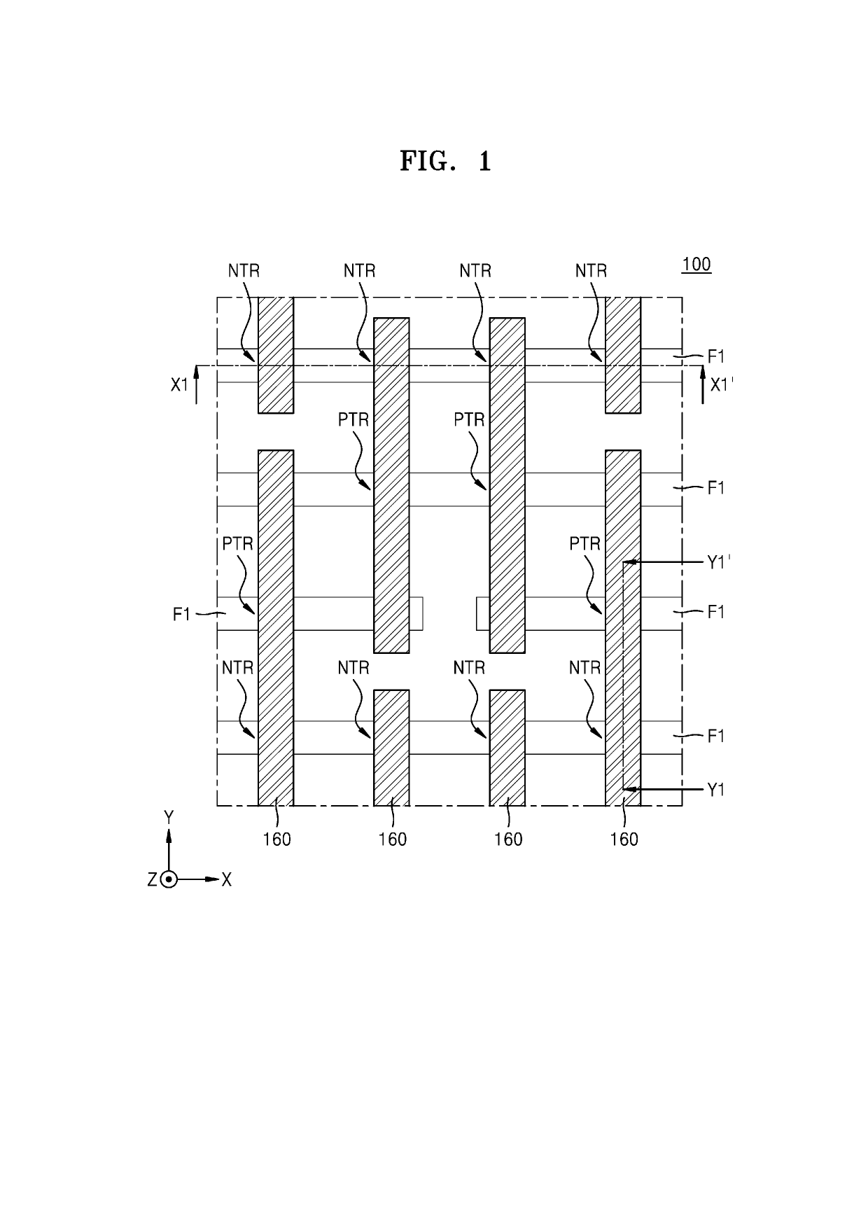

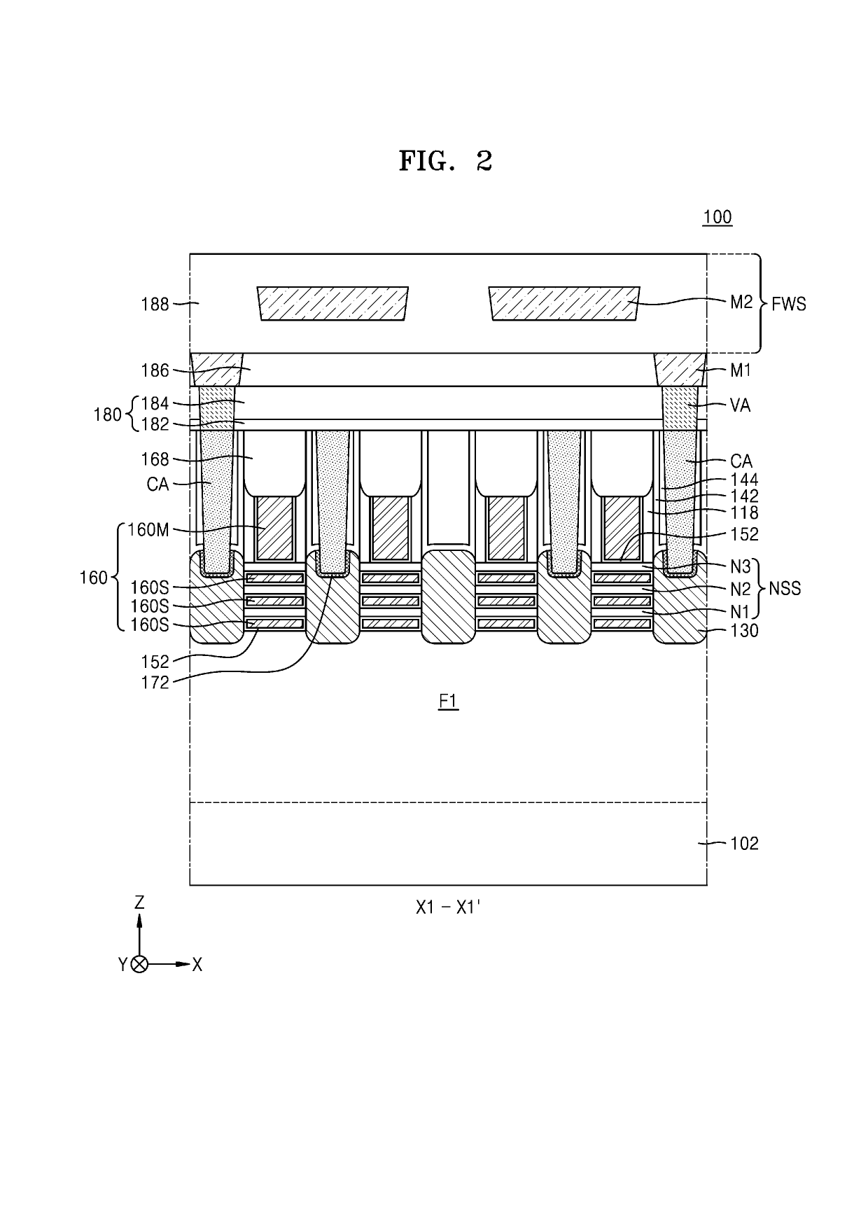

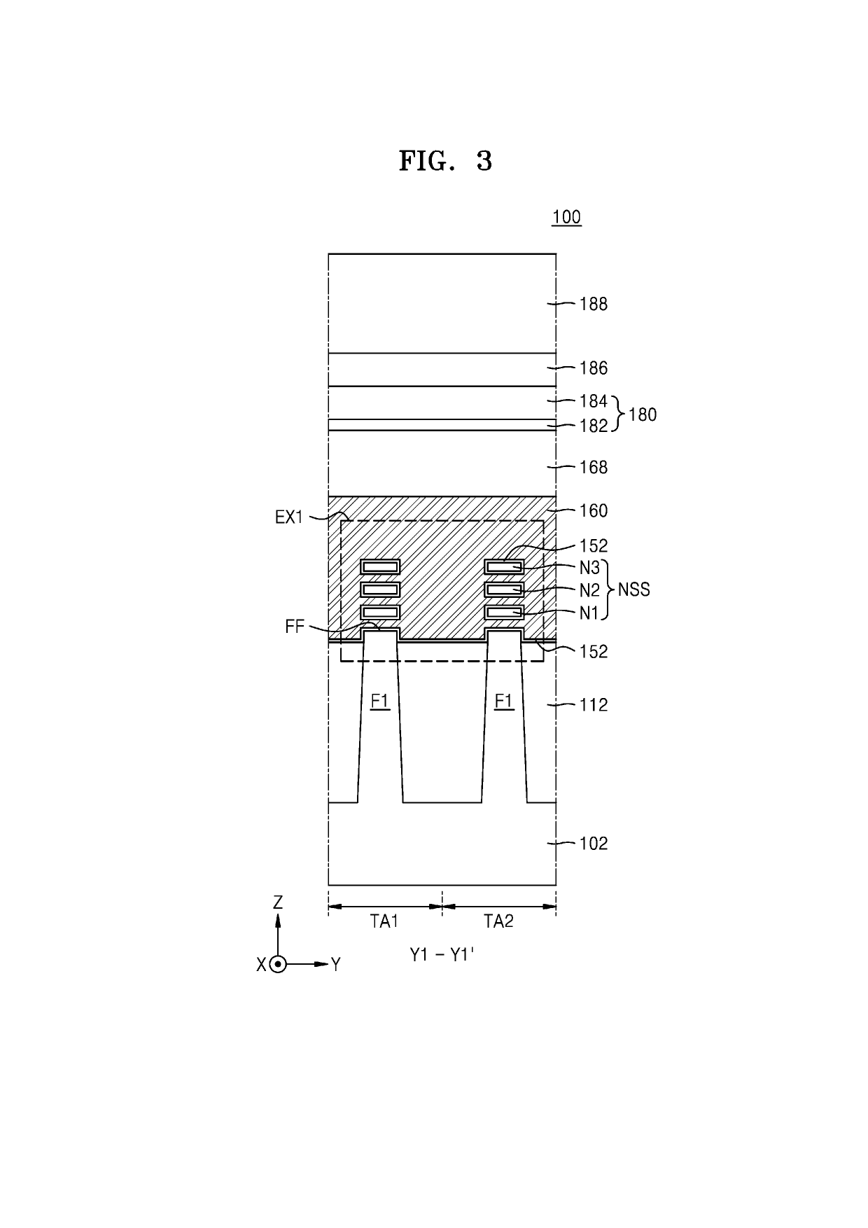

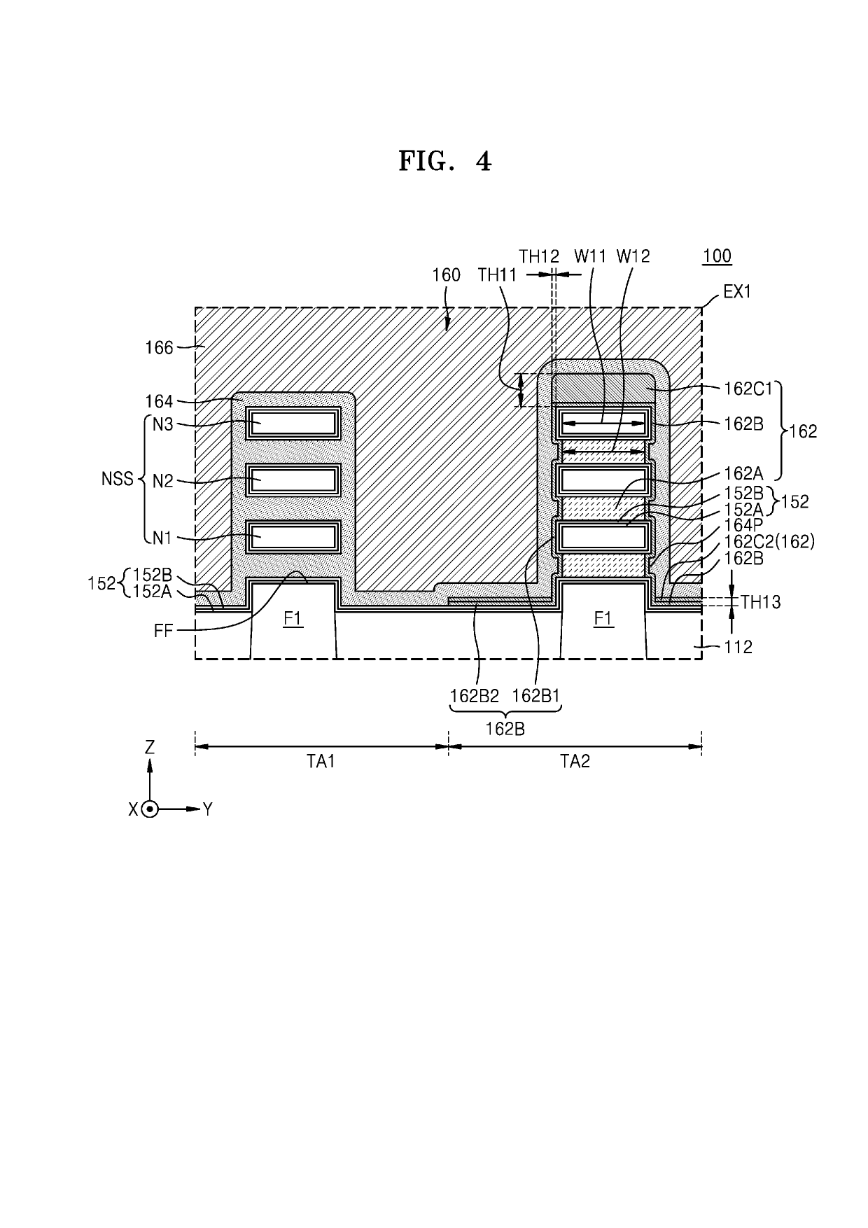

FIG. 1 is a plan layout diagram of an integrated circuit (IC) device according to embodiments. FIG. 2 is a cross-sectional view taken along line X1 - X1' of FIG. 1. FIG. 3 is a cross-sectional view taken along line Y1 - Y1' of FIG. 1. FIG. 4 is an enlarged cross-sectional view of portion "EX1" of FIG. 3. The IC device 100 including a field-effect transistor (FET) having a gate-all-around structure including an active region of a nanowire or nanosheet type and a gate surrounding the active region is described with reference to FIGS. 1 to 4.

Referring to FIGS. 1 to 4, the IC device 100 may include a plurality of fin-type active regions F1, which may extend parallel to each other in a first horizontal direction (X direction). The plurality of fin-type active regions F1 may extend lengthwise in the first horizontal direction. On the plurality of fin-type active regions F1, a plurality of gate lines 160 may extend lengthwise in a second horizontal direction (Y direction), which intersects the first horizontal direction (X direction). The first horizontal direction (X direction) and the second horizontal direction (Y direction) may be perpendicular to each other. The IC device 100 may include a plurality of transistors arranged at intersections where the plurality of gate lines 160 intersect with the plurality of fin-type active regions F1. The plurality of transistors may each be an FET having a gate-all-around (GAA) structure. The plurality of transistors may include a plurality of NMOS transistors NTR and a plurality of PMOS transistors PTR. In the IC device 100, a region in which an NMOS transistor NTR is arranged may be referred to as a first transistor region TA1, and a region in which a PMOS transistor PTR is arranged may be referred to as a second transistor region TA2.

Each of the plurality of fin-type active regions F1 may have a fin top surface FF. The fin top surface FF may be a top surface of a fin-type active region F1. Each of the plurality of fin-type active regions F1 may include silicon (Si). A plurality of nanosheet stacks NSS may be respectively arranged on the fin top surfaces FF of the plurality of fin-type active regions F1. Each of the plurality of nanosheet stacks NSS may be spaced apart from the fin top surface FF of a corresponding one of the plurality of fin-type active regions F1 in a vertical direction (Z direction) and face the fin top surface FF. Each of the plurality of nanosheet stacks NSS may include at least one nanosheet. As used herein, a nanosheet may be a conductive structure having a cross-section that is substantially perpendicular to a direction in which current flows. The nanosheet may be substituted with a nanowire in certain embodiments.

The present embodiment illustrates a configuration in which each of the plurality of nanosheet stacks NSS includes a first nanosheet N1, a second nanosheet N2, and a third nanosheet N3, but the number of nanosheets included in each of the plurality of nanosheet stacks NSS may be variously changed. For example, each of the plurality of nanosheet stacks NSS may include at least one nanosheet or at least two nanosheets, and the number of nanosheets included in the nanosheet stack NSS is not specifically limited. Each of the first to third nanosheets N1, N2, and N3 may have a channel region. In embodiments, each of the first to third nanosheets N1, N2, and N3 included in the nanosheet stack NSS may each include a silicon (Si) layer, a silicon germanium (SiGe) film, or a combination thereof. In embodiments, each of the first to third nanosheets N1, N2, and N3 may have a thickness selected in a range of about 4 nm to about 6 nm in a vertical direction. In embodiments, the first to third nanosheets N1, N2, and N3 may have the same or substantially the same thickness. The first to third nanosheets N1, N2, and N3 may include the same material.

As used herein, the nanosheet stack NSS arranged in the first transistor region TA1 may be referred to as a first nanosheet stack, and each of the first to third nanosheets N1, N2, and N3 included in the nanosheet stack NSS in the first transistor region TA1 may be referred to a first region nanosheet. As used herein, the nanosheet stack NSS arranged in the second transistor region TA2 may be referred to as a second nanosheet stack, and each of the first to third nanosheets N1, N2, and N3 included in the nanosheet stack NSS in the second transistor region TA2 may be referred to as a second region nanosheet.

As illustrated in FIGS. 3 and 4, both sidewalls of each of the plurality of fin-type active regions F1 in the second horizontal direction (Y direction) may be covered by a device isolation film 112. The device isolation film 112 may include portions overlapping the gate line 160 in the vertical direction (Z direction). The device isolation film 112 may include a silicon oxide film, without being limited thereto. As illustrated in FIGS. 3 and 4, at least one gate line 160 selected from the plurality of gate lines 160 may extend in the second horizontal direction (Y direction) on the plurality of fin-type active regions F1 and the device isolation film 112 across the first transistor region TA1 and the second transistor region TA2. As used herein, the fin-type active region F1 arranged in the first transistor region TA1, from among the plurality of fin-type active regions F1, may be referred to as a first fin-type active region, and the fin-type active region F1 arranged in the second transistor region TA2, from among the plurality of fin-type active regions F1, may be referred to as a second fin-type active region. Each of the plurality of gate lines 160 may surround the first to third nanosheets N1, N2, and N3 of the nanosheet stacks NSS, which overlap each other in the vertical direction (Z direction).

Each of the plurality of gate lines 160 may include a metal, a metal nitride, a metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from titanium nitride (TiN) and tantalum nitride (TaN). The metal carbide may include titanium aluminum carbide (TiAlC). However, a constituent material of the plurality of gate lines 160 is not limited thereto.

In embodiments, at least one gate line 160 selected from the plurality of gate lines 160 may include a work-function metal-containing structure of a first conductivity type arranged in the first transistor region TA1 and a work-function metal-containing structure of a second conductivity type arranged in the second transistor region TA2. When the first transistor region TA1 is an NMOS transistor region, the work-function metal-containing structure of the first conductivity type may be an N-type work-function metal-containing structure; when the second transistor region TA2 is a PMOS transistor region, the work-function metal-containing structure of the second conductivity type may be a P-type work-function metal-containing structure. In embodiments, the N-type work-function metal-containing structure may include a TiAlC film, and the P-type work-function metal-containing structure may include a titanium nitride (TiN) film, a tungsten nitride (WN) film, or a molybdenum nitride (MoN) film.

As illustrated in FIGS. 3 and 4, at least one gate line 160 selected from the plurality of gate lines 160 may include a blanket work-function metal-containing layer 164 surrounding the first to third nanosheets N1, N2, and N3 in the first transistor region TA1 and a work-function metal-containing structure 162 surrounding the first to third nanosheets N1, N2, and N3 in the second transistor region TA2. The blanket work-function metal-containing layer 164 may constitute the N-type work-function metal-containing structure, and the work-function metal-containing structure 162 may constitute the P-type work-function metal-containing structure. The blanket work-function metal-containing layer 164 may include a first region portion surrounding the first to third nanosheets N1, N2, and N3 in the first transistor region TA1 and a second region portion surrounding the first to third nanosheets N1, N2, and N3 and the work-function metal-containing structure 162 in the second transistor region TA2. The first region portion and the second region portion of the blanket work-function metal-containing layer 164 may be continuously connected to each other and integrally formed with each other, e.g., without a visible boundary between the first region portion and the second region portion of the blanket work-function metal-containing layer 164. For example, the first region portion and the second region portion of the blanket work-function metal-containing layer 164 may be formed by the same process.

As illustrated in further detail in FIG. 4, in the second transistor region TA2, a first thickness TH11 in the vertical direction (Z direction) of a portion of the work-function metal-containing structure 162, which covers a top surface of the nanosheet stack NSS (e.g., a top surface of the third nanosheet N3 located at an uppermost layer, from among the first to third nanosheets N1, N2, and N3), may be greater than a second thickness TH12 in the second horizontal direction (Y direction) of a portion of the work-function metal-containing structure 162, which covers a sidewall of the nanosheet stack NSS (e.g., a sidewall of each of the first to third nanosheets N1, N2, and N3). For example, the first thickness TH11 may be about three times to about 20 times greater than the second thickness TH12, without being limited thereto.

As illustrated in FIG. 4, the work-function metal-containing structure 162 may include a plurality of work-function metal-containing patterns 162A, a work-function metal-containing liner 162B, and a plurality of work-function metal-containing blocks (e.g., 162C1 and 162C2).

The plurality of work-function metal-containing patterns 162A may be respectively arranged one-by-one between the first to third nanosheets N1, N2, and N3 and between the fin-type active region F1 and the first nanosheet N1 and arranged in a line in the vertical direction (Z direction). For example, the plurality of work-function metal-containing patterns 162A may vertically overlap each other. Each of the plurality of work-function metal-containing patterns 162A may vertically overlap the first to third nanosheets N1, N2, and N3. In the second horizontal direction (Y direction), each of the first to third nanosheets N1, N2, and N3 may have a first width W11, and of each of the plurality of work-function metal-containing patterns 162A may have a second width W12 which may be less than or equal to the first width W11.

The work-function metal-containing liner 162B may conformally cover the first to third nanosheets N1, N2, and N3 and the plurality of work-function metal-containing patterns 162A. The work-function metal-containing liner 162B may be in contact with each of the plurality of work-function metal-containing patterns 162A. The work-function metal-containing liner 162B may include a vertical extension 162B1 and a lateral extension 162B2 which is integrally connected to the vertical extension 162B1 and overlaps the device isolation film 112 in the vertical direction (Z direction). The lateral extension 162B2 may extend in a horizontal direction. The vertical extension 162B1 of the work-function metal-containing liner 162B may extend in a zigzag shape in the vertical direction (Z direction) while covering the sidewall of each of the first to third nanosheets N1, N2, and N3 surrounded by the work-function metal-containing structure 162 and a sidewall of each of the plurality of work-function metal-containing patterns 162A. For example, the lateral potion 162B2 may be a portion conformally formed on side walls of the first to third nanosheets N1, N2, and N3 and a sidewall of each of the plurality of work-function metal-containing patterns 162A.

The plurality of work-function metal-containing blocks (e.g., 162C1 and 162C2) may include an upper work-function metal-containing block 162C1 and a lower work-function metal-containing block 162C2, which are spaced apart from each other. The upper work-function metal-containing block 162C1 may cover an uppermost surface of the work-function metal-containing liner 162B at a position overlapping the first to third nanosheets N1, N2, and N3 surrounded by the work-function metal-containing structure 162 in the vertical direction (Z direction). The lower work-function metal-containing block 162C2 may cover the lateral extension 162B1 of the work-function metal-containing liner 162B at a position overlapping the device isolation film 112 in the vertical direction (Z direction). Each of the upper work-function metal-containing block 162C1 and the lower work-function metal-containing block 162C2 may be in contact with the work-function metal-containing liner 162B. A thickness of the upper work-function metal-containing block 162C1 in the vertical direction (Z direction) may be greater than a thickness of each of the plurality of work-function metal-containing patterns 162A in the vertical direction (Z direction). A thickness of the lower work-function metal-containing block 162C2 in the vertical direction (Z direction) may be less than a thickness of the upper work-function metal-containing block 162C1 in the vertical direction (Z direction).

The work-function metal-containing structure 162 including a combination of the plurality of work-function metal-containing patterns 162A, the work-function metal-containing liner 162B, and the plurality of work-function metal-containing blocks (e.g., 162C1 and 162C2) may have sidewalls in the second horizontal direction (Y direction) and each sidewall may include a rough surface. As illustrated in FIGS. 3 and 4, at least one of a pair of rough surfaces that are included in the both sidewalls of the work-function metal-containing structure 162 in the second horizontal direction (Y direction) may face the nanosheet stack NSS arranged in the first transistor region TA1 in the second horizontal direction (Y direction). In the pair of rough surfaces included in the work-function metal-containing structure 162, surfaces (which may be referred to as first surfaces) covering and/or horizontally overlapping the first to third nanosheets N1, N2, and N3 surrounded by the work-function metal-containing structure 162 may include convex surfaces protruding toward the nanosheet stack NSS located in the first transistor region TA1. In the pair of rough surfaces included in the work-function metal-containing structure 162, surfaces (which may be referred to as second surfaces) covering and/or horizontally overlapping work-function metal-containing patterns 162A (or respective regions between the first to third nanosheets N1, N2, and N3 surrounded by the work-function metal-containing structure 162 and a region between the fin-type active region F1 and the first nanosheet N1) may include concave surfaces, which are concave and recessed toward work-function metal-containing patterns 162A, and the concave surfaces face the nanosheet stack NSS located in the first transistor region TA1. For example, the rough surfaces included in the work-function metal-containing structure 162 may include and/or formed of concave surfaces and convex surfaces.

In the second transistor region TA2, the first thickness TH11 in the vertical direction (Z direction) of a portion of the work-function metal-containing structure 162, which covers the top surface of the nanosheet stack NSS, may be greater than a third thickness TH13 in the vertical direction (Z direction) of a portion of the work-function metal-containing structure 162, which covers the device isolation film 112.

In embodiments, the plurality of work-function metal-containing patterns 162A, the work-function metal-containing liner 162B, and the plurality of work-function metal-containing blocks (e.g., 162C1 and 162C2) may each include a TiN film, a WN film, or a MoN film. For example, the plurality of work-function metal-containing patterns 162A, the work-function metal-containing liner 162B, and the plurality of work-function metal-containing blocks (e.g., 162C1 and 162C2) may each include a TiN film. In embodiments, the plurality of work-function metal-containing patterns 162A and the work-function metal-containing liner 162B may be obtained by using an atomic layer deposition (ALD) process, and each of the plurality of work-function metal-containing blocks (e.g., 162C1 and 162C2) may be obtained by using a physical vapor deposition (PVD) process.

As described above, in the second transistor region TA2, the blanket work-function metal-containing layer 164 may include a second region portion surrounding the first to third nanosheets N1, N2, and N3 and the work-function metal-containing structure 162. In the second transistor region TA2, the work-function metal-containing structure 162 may include a portion interposed between the blanket work-function metal-containing layer 164 and the first to third nanosheets N1, N2, and N3.

In the second transistor region TA2, the blanket work-function metal-containing layer 164 may include a plurality of protrusions 164P, which protrude toward the rough/concave surface included in each of the both sidewalls of the work-function metal-containing structure 162 in the second horizontal direction (Y direction). The plurality of protrusions 164P of the blanket work-function metal-containing layer 164 may be in contact with a plurality of concave surfaces included in a rough surface of the blanket work-function metal-containing layer 164 and protrude toward respective regions between the first to third nanosheets N1, N2, and N3 surrounded by the work-function metal-containing structure 162. Each of the plurality of protrusions 164P of the blanket work-function metal-containing layer 164 may face the work-function metal-containing pattern 162A included in the work-function metal-containing structure 162 in the second horizontal direction (Y direction). The protrusion 164P of the blanket work-function metal-containing layer 164 may be spaced apart from the work-function metal-containing pattern 162A in the second horizontal direction (Y direction) with the work-function metal-containing liner 162B therebetween.

As illustrated in FIG. 4, at least one gate line 160 selected from the plurality of gate lines 160 may further include a gap-fill metal film 166 covering the blanket work-function metal-containing layer 164 and the work-function metal-containing structure 162. The gap-fill metal film 166 may be in contact with the blanket work-function metal-containing layer 164 in the first transistor region TA1, and the gap-fill metal film 166 may be spaced apart from the work-function metal-containing structure 162 with the blanket work-function metal-containing layer 164 therebetween in the second transistor region TA2. The gap-fill metal film 166 may include tungsten (W), aluminum (Al), or a combination thereof.

A gate dielectric film 152 may be between each of the first to third nanosheets N1, N2, and N3 and the blanket work-function metal-containing layer 164 in the first transistor region TA1 and between each of the first to third nanosheets N1, N2, and N3 and the work-function metal-containing structure 162 in the second transistor region TA2. The gate dielectric film 152 may include portions covering respective surfaces of the first to third nanosheets N1, N2, and N3, portions covering sidewalls of the gate line 160, and portions covering a top surface of the device isolation film 112.

In the first transistor region TA1, the gate dielectric film 152 may be in contact with the blanket work-function metal-containing layer 164. In the second transistor region TA2, the gate dielectric film 152 may include portions in contact with the plurality of work-function metal-containing patterns 162A and portions in contact with the work-function metal-containing liner 162B. In the second transistor region TA2, the gate dielectric film 152 may be spaced apart from the upper work-function metal-containing block 162C1 in the vertical direction (Z direction) with the work-function metal-containing liner 162B therebetween.

In embodiments, the gate dielectric film 152 may have a stack structure of an interface film 152A and a high-dielectric film 152B. The interface film 152A may include a low-k dielectric film having a dielectric constant of about 9 or lower, for example, a silicon oxide film, a silicon oxynitride film, or a combination thereof. In embodiments, the interface film 152A may be omitted. The high-dielectric film 152B may include a material having a higher dielectric constant than a silicon oxide film. For example, the high-dielectric film 152B may have a dielectric constant of about 10 to about 25. The high-dielectric film 152B may include hafnium oxide, without being limited thereto.

The IC device 100 may include a plurality of source/drain regions 130 arranged on the plurality of fin-type active regions F1. A plurality of source/drain regions 130 arranged on one fin-type active region F1 may be spaced apart from each other in the first horizontal direction (X direction) with a corresponding gate line 160 therebetween. Each of the plurality of source/drain regions 130 may be in contact with the first to third nanosheets N1, N2, and N3 included in the nanosheet stack NSS adjacent thereto.

From among the plurality of source/drain regions 130, the source/drain region 130 arranged in the first transistor region TA1 may include a silicon (Si) layer doped with an n-type dopant or a silicon carbide (SiC) layer doped with an n-type dopant. The n-type dopant may be selected from phosphorus (P), arsenic (As), and antimony (Sb). From among the plurality of source/drain regions 130, the source/drain region 130 arranged in the second transistor region TA2 may include a SiGe film doped with a p-type dopant. The p-type dopant may be selected from boron (B) and gallium (Ga).

As illustrated in FIG. 2, each of the plurality of gate lines 160 may include a main gate portion 160M and a plurality of sub-gate portions 160S. The main gate portion 160M may cover the top surface of the nanosheet stack NSS and extend in the second horizontal direction (Y direction). The plurality of sub-gate portions 160S may be integrally connected to the main gate portion 160M and each be arranged in a space between two adjacent ones of the first to third nanosheets N1, N2, and N3 and a space between the fin top surface FF and the first nanosheet N1. In the vertical direction (Z direction), a thickness of each of the plurality of sub-gate portions 160S may be less than a thickness of the main gate portion 160M. From among the first to third nanosheets N1, N2, and N3, the second and third nanosheets N2 and N3, excluding the first nanosheet N1, may have a gate-all-around (GAA) structure completely surrounded by the gate line 160, e.g., in a cross-sectional view.

Both sidewalls of each of the plurality of sub-gate portions 160S included in the plurality of gate lines 160 may be spaced apart from the source/drain region 130 with the gate dielectric film 152 therebetween. The gate dielectric film 152 may be between the sub-gate portion 160S included in the gate line 160 and each of the first to third nanosheets N1, N2, and N3 and between the sub-gate portion 160S included in the gate line 160 and the source/drain region 130. The plurality of gate lines 160, the plurality of nanosheet stacks NSS, and the plurality of source/drain regions 130 may constitute a plurality of nanosheet transistors.

As illustrated in FIG. 2, both sidewalls of the gate line 160 may be covered by a plurality of insulating spacers 118. Each of the plurality of insulating spacers 118 may cover a sidewall of the main gate portion 160M on the top surface of the nanosheet stack NSS. Each of the plurality of insulating spacers 118 may be spaced apart from a corresponding gate line 160 with the gate dielectric film 152 therebetween. Each of the plurality of insulating spacers 118 may include silicon nitride, silicon oxide, silicon oxycarbide (SiOC), silicon oxycarbonitride (SiOCN), silicon carbonitride (SiCN), silicon boron nitride (SiBN), silicon oxynitride (SiON), silicon boron carbonitride (SiBCN), SiOF, SiOCH, or a combination thereof. Each of the plurality of insulating spacers 118 may include a single film including one material film selected from the materials described above or a multilayered film including a plurality of material films selected from the materials described above. As used herein, each of the terms SiOC, SiOCN, SiCN, SiBN, SiON, SiBCN, SiOF, and SiOCH refers to a material including elements included therein, without referring to a chemical formula representing a stoichiometric relationship.

A top surface of each of the gate line 160, the gate dielectric film 152, and the insulating spacer 118 may be covered by a capping insulating pattern 168. The capping insulating pattern 168 may include a silicon nitride film.

The plurality of source/drain regions 130, the device isolation film 112, and the plurality of insulating spacers 118 may be covered by an insulating liner 142. An inter-gate dielectric film 144 may be arranged on the insulating liner 142. The inter-gate dielectric film 144 may fill a space between a pair of gate lines 160, which are adjacent to each other in the first horizontal direction (X direction). In embodiments, the insulating liner 142 may include silicon nitride, SiCN, SiBN, SiON, SiOCN, SiBCN, or a combination thereof, and the inter-gate dielectric film 144 may include a silicon oxide film, without being limited thereto.

As illustrated in FIG. 2, a plurality of source/drain contacts CA may be arranged on the source/drain regions 130 each between a pair of adjacent ones of the plurality of gate lines 160. Each of the plurality of source/drain contacts CA may be electrically connected to at least one source/drain region 130 selected from the plurality of source/drain regions 130. A metal silicide film 172 may be interposed between the source/drain region 130 and the source/drain contact CA. The metal silicide film 172 may be in contact with the source/drain region 130 corresponding thereto. The source/drain contact CA may pass through the inter-gate dielectric film 144 and the insulating liner 142 in the vertical direction (Z direction) and be in contact with the metal silicide film 172. The source/drain contact CA may be electrically connected to the source/drain region 130 through the metal silicide film 172. The source/drain contact CA may pass through a portion of the source/drain region 130 in the vertical direction (Z direction). For example, the source/drain contact CA may overlap a portion of the source/drain region 130 in a horizontal direction. The insulating liner 142 and the inter-gate dielectric film 144 may surround a sidewall of the source/drain contact CA.

In embodiments, the metal silicide film 172 may include Ti, W, Ru, Nb, Mo, Hf, Ni, Co, Pt, Yb, Tb, Dy, Er, or Pd. For example, the metal silicide film 172 may include titanium silicide. In certain embodiments, the source/drain contact CA may include only a metal plug including a single metal. In other embodiments, the source/drain contact CA may include a metal plug and a conductive barrier film surrounding the metal plug. The metal plug may include molybdenum (Mo), tungsten (W), cobalt (Co), ruthenium (Ru), manganese (Mn), titanium (Ti), tantalum (Ta), aluminum (Al), copper (Cu), a combination thereof, or an alloy thereof, without being limited thereto. The conductive barrier film may include a metal or a conductive metal nitride. For example, the conductive barrier film may include titanium (Ti), tantalum (Ta), tungsten (W), titanium nitride (TiN), tantalum nitride (TaN), tungsten nitride (WN), tungsten carbon nitride (WCN), titanium silicon nitride (TiSiN), tantalum silicon nitride (TaSiN), tungsten silicon nitride (WSiN), or a combination thereof, without being limited thereto.

A top surface of each of the source/drain contact CA, a plurality of capping insulating patterns 168, and the inter-gate dielectric film 144 may be covered by an upper insulating structure 180. The upper insulating structure 180 may include an etch stop film 182 and an upper insulating film 184, which are sequentially stacked on each of the plurality of source/drain contacts CA, the plurality of capping insulating patterns 168, and the inter-gate dielectric film 144. The etch stop film 182 may include silicon carbide (SiC), silicon nitride (SiN), silicon carbonitride (SiCN), silicon oxycarbide (SiOC), aluminum nitride (AlN), aluminum oxynitride (AlON), aluminum oxide (AlO), aluminum oxycarbide (AlOC), or a combination thereof. The upper insulating film 184 may include an oxide film, a nitride film, an ultralow-k (ULK) film having an ultralow dielectric constant K of about 2.2 to about 2.4, or a combination thereof. For example, the upper insulating film 184 may include a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

As illustrated in FIG. 2, a source/drain via contact VA may be arranged on the source/drain contact CA such that a plurality of source/drain via contacts VA are arranged on the source/drain contacts CA. Each of the plurality of source/drain via contacts VA may pass through the upper insulating structure 180 and be in contact with the source/drain contact CA. From among the plurality of source/drain regions 130, some of the source/drain regions 130 may be electrically connected to the source/drain via contacts VA through metal silicide films 172 and the source/drain contacts CA. Each of the plurality of source/drain via contacts VA may include molybdenum (Mo) or tungsten (W), without being limited thereto. A gate contact may be arranged on each of the plurality of gate lines 160. The gate contact may pass through the upper insulating structure 180 and the capping insulating pattern 168 in the vertical direction (Z direction) and be electrically connected to the gate line 160. A bottom surface of the gate contact may be in contact with a top surface of the gate line 160. The gate contact may include a contact plug, which includes Mo, W, Co, Ru, Mn, Ti, Ta, Al, Cu, a combination thereof, or an alloy thereof. In embodiments, the gate contact may further include a conductive barrier pattern surrounding a portion of the contact plug. The conductive barrier pattern may include a metal or a metal nitride. For example, the conductive barrier pattern may include Ti, Ta, W, TiN, TaN, WN, WCN, TiSiN, TaSiN, WSiN, or a combination thereof, without being limited thereto.

A top surface of the upper insulating structure 180 may be covered by a frontside interlayer insulating film 186. A constituent material of the frontside interlayer insulating film 186 may be the same as a constituent material of the upper insulating film 184, which has been described above. A plurality of first wiring layers M1 may be arranged to pass through the frontside interlayer insulating film 186. The plurality of first wiring layers M1 may include the first wiring layer M1 electrically connected to and/or contacting the source/drain via contact VA. The plurality of first wiring layers M1 may include Mo, W, Co, Ru, Mn, Ti, Ta, Al, Cu, a combination thereof, or an alloy thereof, without being limited thereto.

A frontside wiring structure FWS may be arranged on the plurality of first wiring layers M1 and the frontside interlayer insulating film 186. The frontside wiring structure FWS may include a plurality of second wiring layers M2, a plurality of via contacts, and an interlayer insulating film 188 covering the plurality of second wiring layers M2 and the plurality of via contacts. The plurality of second wiring layers M2 may include a plurality of word lines. A constituent material of each of the plurality of second wiring layers M2 and the plurality of via contacts may be the same or substantially the same as a constituent material of the plurality of first wiring layers M1, which has been described above. A constituent material of the interlayer insulating film 188 may be the same or substantially the same as a constituent material of the upper insulating film 184, which has been described above.

According to the IC device 100 described with reference to FIGS. 1 to 4, even when an area of each of the first transistor region TA1 and the second transistor region TA2 having different channel types is reduced and a distance between the first transistor region TA1 and the second transistor region TA2 is reduced due to the downscaling of the IC device 100, different electrical characteristics respectively required for the first transistor region TA1 and the second transistor region TA2 may be stably ensured according to various arrangement structures in the IC device 100 including the first transistor region TA1 and the second transistor region TA2, and the performance and reliability of each of the first transistor region TA1 and the second transistor region TA2 may be ensured. In addition, the likelihood of process defects may be eliminated during the process of manufacturing the IC device 100.

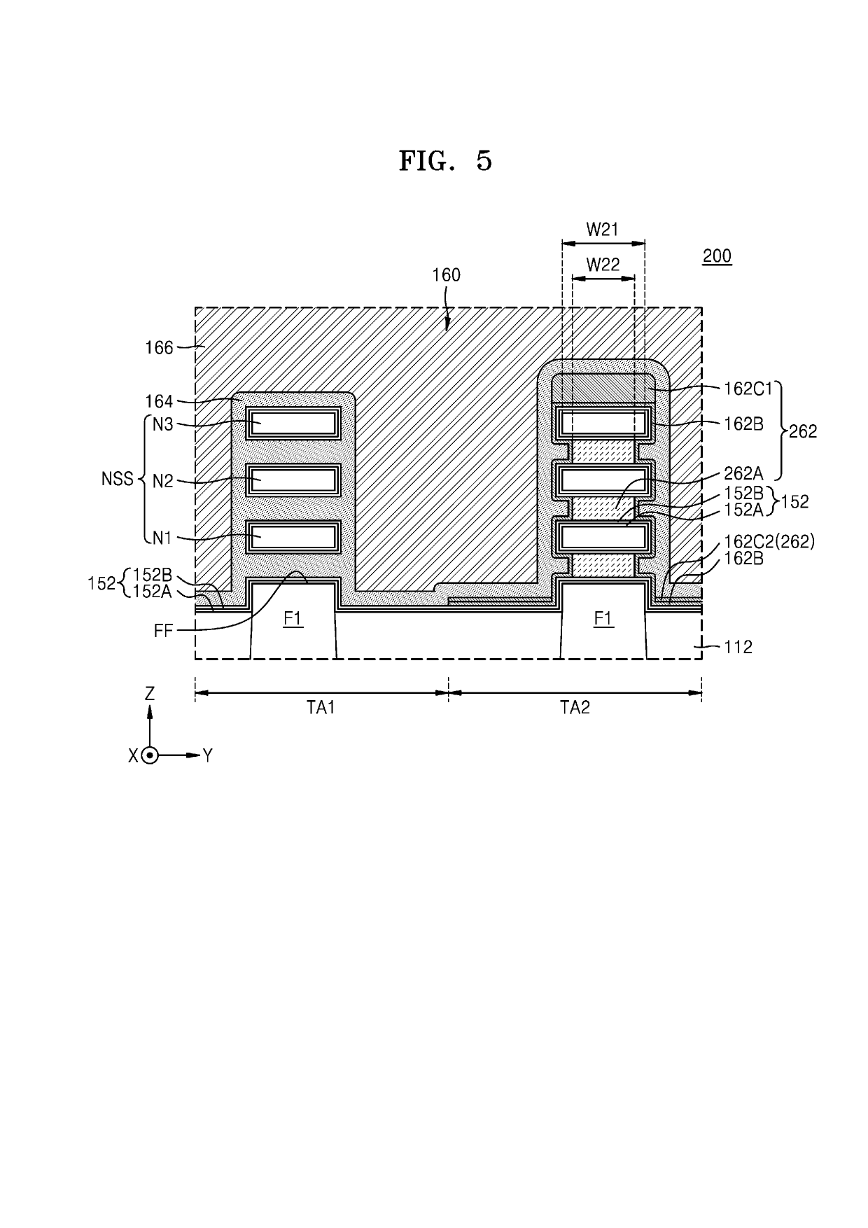

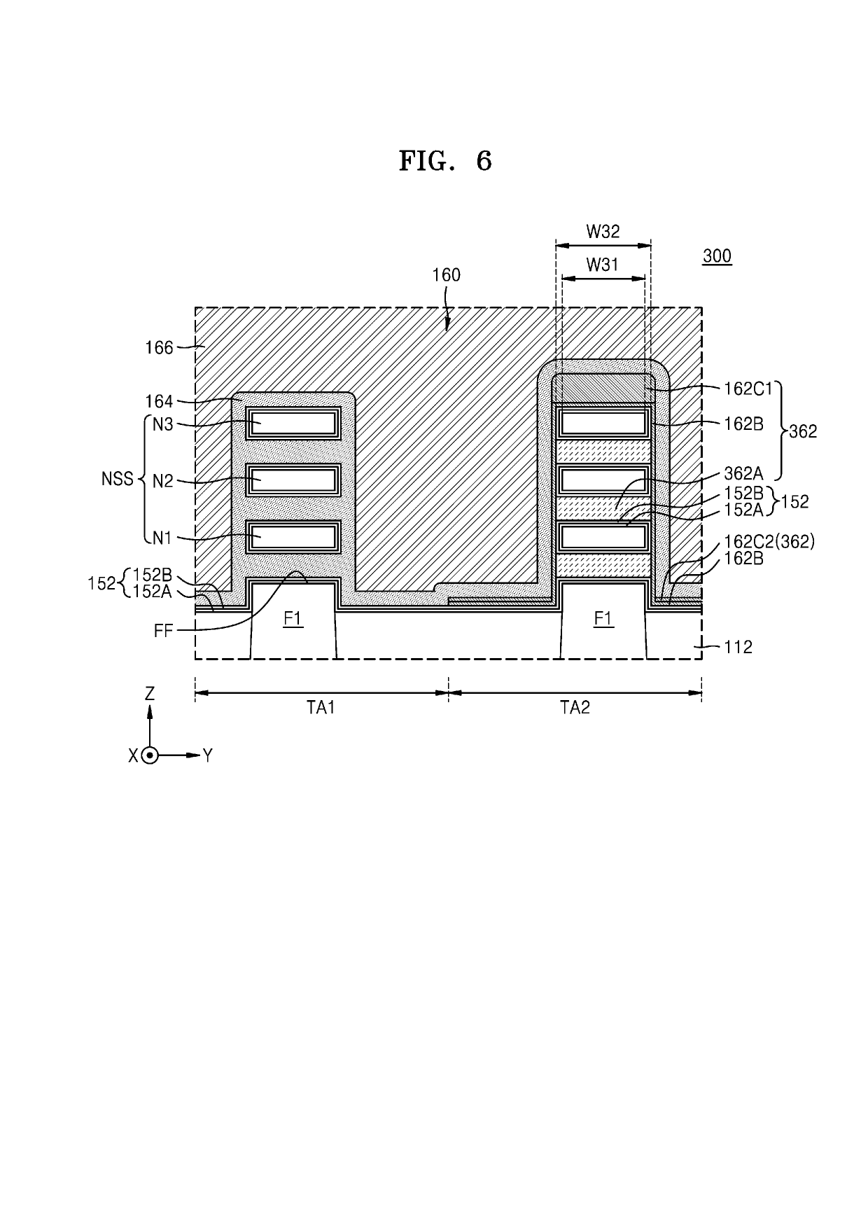

FIGS. 5 and 6 are respectively cross-sectional views of IC devices 200 and 300 according to other embodiments. FIGS. 5 and 6 each illustrate an enlarged cross-sectional configuration of a portion corresponding to region "EX1" of FIG. 3 in the IC devices 200 and 300. In FIGS. 5 and 6, the same reference numerals are used to denote the same elements as in FIGS. 1 to 4, and thus, repeated descriptions thereof are omitted.

Referring to FIG. 5, the IC device 200 may have substantially the same configuration as the IC device 100 described with reference to FIGS. 1 to 4. However, the IC device 200 may include a work-function metal-containing structure 262 instead of the work-function metal-containing structure 162 of the IC device 100.

The work-function metal-containing structure 262 may have substantially the same structure as the work-function metal-containing structure 162 described with reference to FIG. 4. However, the work-function metal-containing structure 262 may include a plurality of work-function metal-containing patterns 262A instead of the plurality of work-function metal-containing patterns 162A of the work-function metal-containing structure 162, and the plurality of work-function metal-containing patterns 262A may be respectively disposed one-by-one between first to third nanosheets N1, N2, and N3 covered by the work-function metal-containing structure 262 and between a fin-type active region F1 and the first nanosheet N1. In a second horizontal direction (Y direction), the first to third nanosheets N1, N2, and N3 covered by the work-function metal-containing structure 262 may have a first width W21, and a second width W22 of each of the plurality of work-function metal-containing patterns 262A may be less than the first width W21. The other detailed configurations of the plurality of work-function metal-containing patterns 262A may be the same or substantially the same as those of the plurality of work-function metal-containing patterns 162A, which have been described with reference to FIG. 4.

Referring to FIG. 6, the IC device 300 may have substantially the same configuration as the IC device 100 described with reference to FIGS. 1 to 4. However, the IC device 300 may include a work-function metal-containing structure 362 instead of the work-function metal-containing structure 162 of the IC device 100.

The work-function metal-containing structure 362 may have substantially the same structure as the work-function metal-containing structure 162 described with reference to FIG. 4. However, the work-function metal-containing structure 362 may include a plurality of work-function metal-containing patterns 362A instead of the plurality of work-function metal-containing patterns 162A of the work-function metal-containing structure 162, and the plurality of work-function metal-containing patterns 362A may be respectively arranged one-by-one between the first to third nanosheets N1, N2, and N3 covered by the work-function metal-containing structure 362 and between the fin-type active region F1 and the first nanosheet N1. In the second horizontal direction (Y direction), the first to third nanosheets N1, N2, and N3 covered by the work-function metal-containing structure 362 may have a first width W31, and a second width W32 of each of the plurality of work-function metal-containing patterns 362A may be greater than the first width W31. The other detained configurations of the plurality of work-function metal-containing patterns 362A may be the same or substantially the same as those of the plurality of work-function metal-containing patterns 162A, which have been described above with reference to FIG. 4.

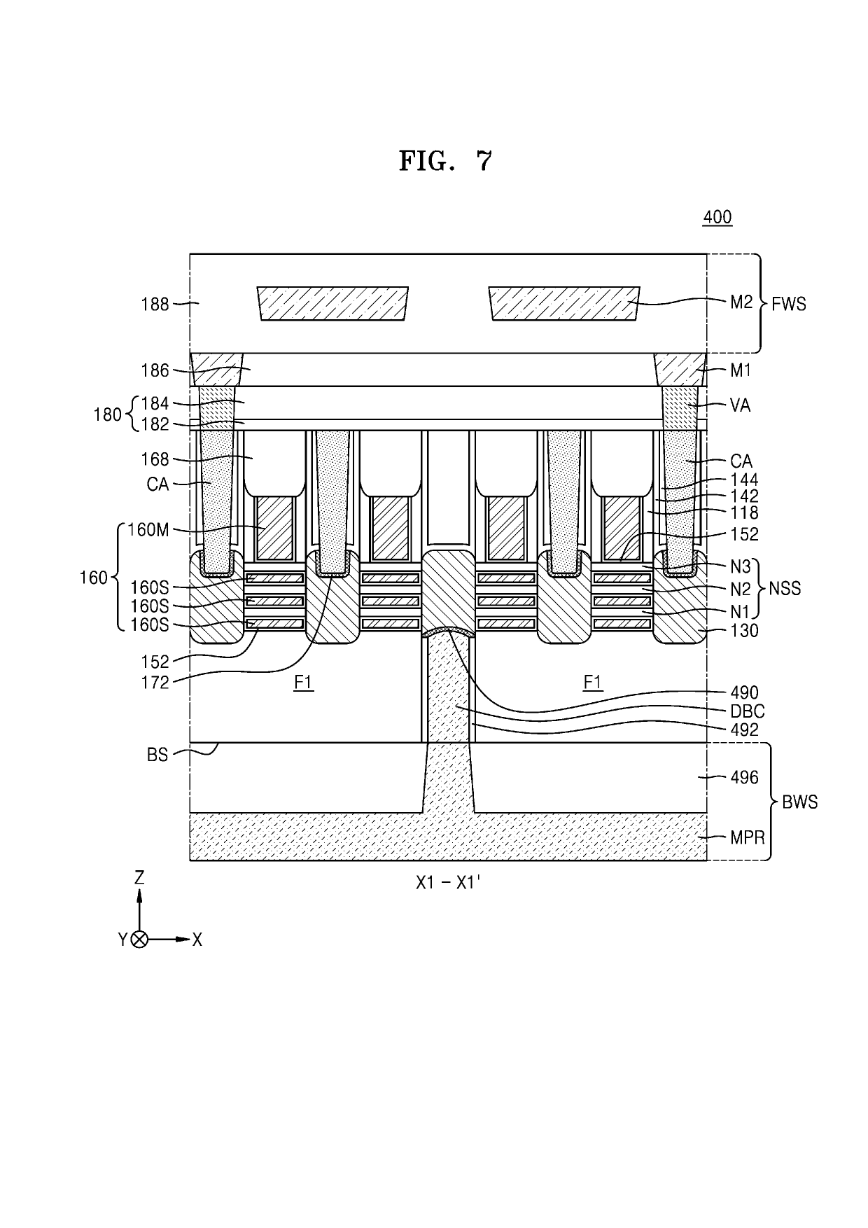

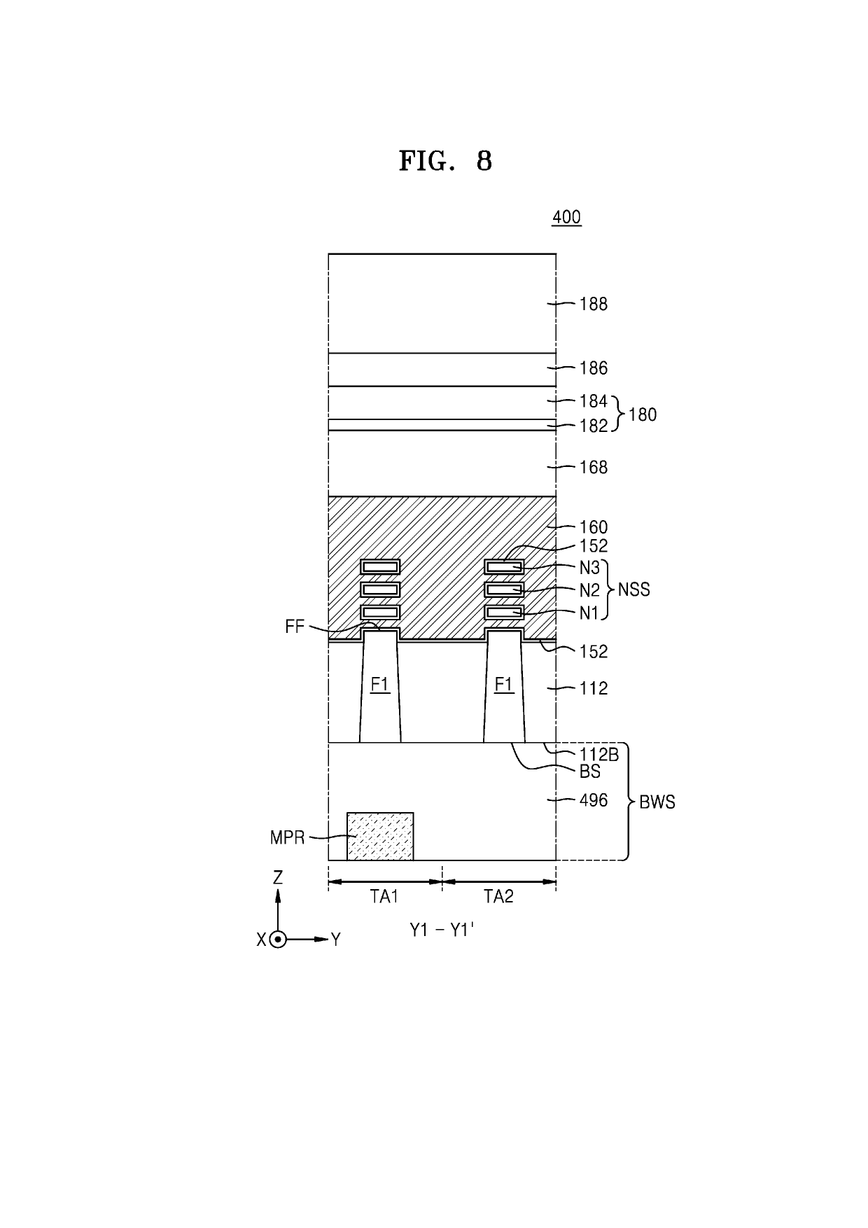

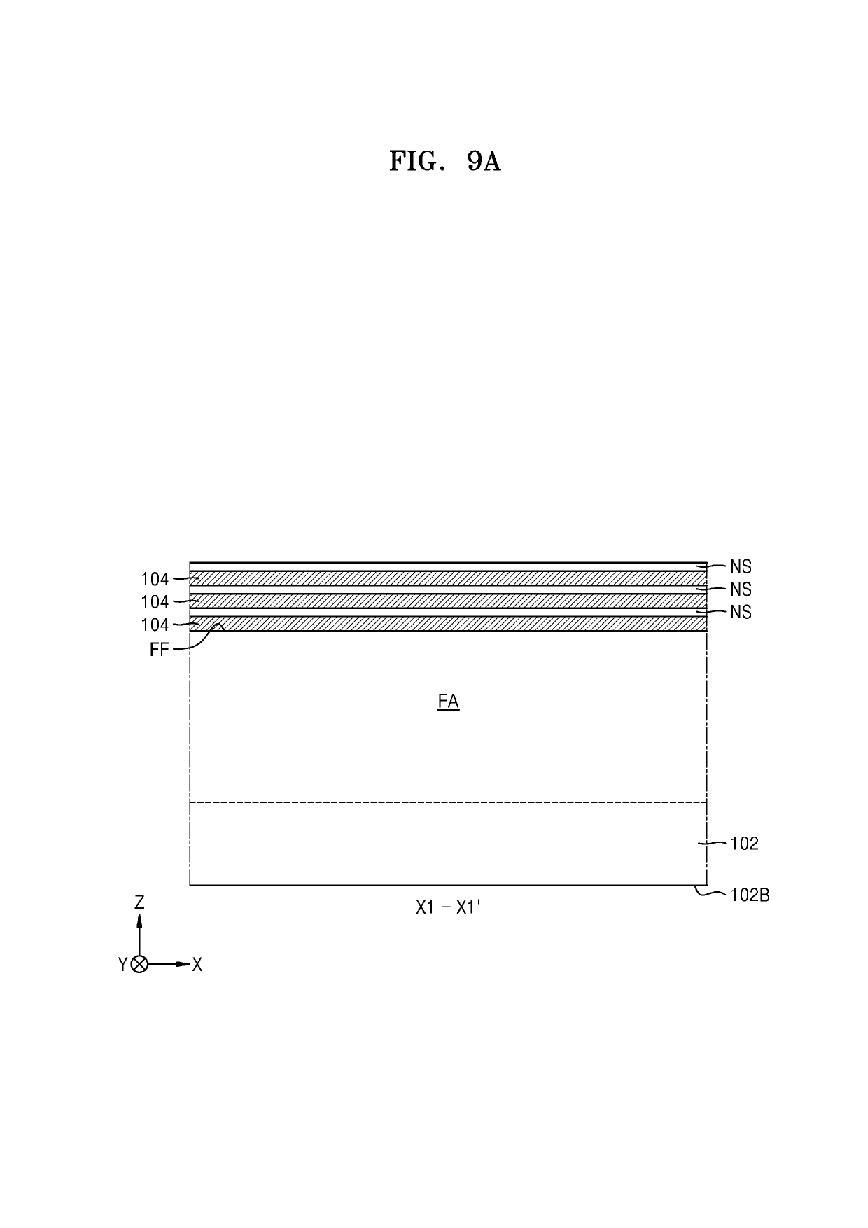

FIGS. 7 and 8 are cross-sectional views of an IC device 400 according to other embodiments. FIG. 7 is a cross-sectional view corresponding to a cross-section taken along line X1-X1' of FIG. 1 in the IC device 400, and FIG. 8 is a cross-sectional view corresponding to a cross-section taken along line Y1-Y1' of FIG. 1 in the IC device 400. In FIGS. 7 and 8, the same reference numerals are used to denote the same elements as in FIGS. 1 to 4, and thus, repeated descriptions thereof are omitted.

Referring to FIGS. 7 and 8, the IC device 400 may have substantially the same configuration as the IC device 100 described with reference to FIGS. 1 to 4. However, the IC device 400 may include a backside wiring structure BWS.

The backside wiring structure BWS may cover a backside surface BS of each of a plurality of fin-type active regions F1 and a backside surface 112B of a device isolation film 112. The backside wiring structure BWS may include a backside contact DBC electrically connected to and/or contact a source/drain region 130, a backside insulating spacer 492 surrounding the backside contact DBC, a power rail wiring MPR electrically connected to the backside contact DBC, and a backside interlayer insulating film 496. A metal silicide film 490 may be placed between the source/drain region 130 and the backside contact DBC.

The backside contact DBC may be electrically connected to a corresponding one of source/drain regions 130 through the metal silicide film 490 and extend, e.g., lengthwise, in the vertical direction (Z direction) from the corresponding one of the source/drain regions 130 toward the backside surface BS of the fin-type active region F1. The backside interlayer insulating film 496 may be placed between the plurality of fin-type active regions F1 and the power rail wiring MPR and insulate the plurality of fin-type active regions F1 from the power rail wiring MPR. In embodiments, the power rail wiring MPR may be electrically connected to a ground node or a power node, without being limited thereto.

A constituent material of each of the backside contact DBC and the power rail wiring MPR may be the same or substantially the same as a constituent material of a plurality of first wiring layers M1. A constituent material of the metal silicide film 490 may be the same as that of the metal silicide film 172, which has been described above. A constituent material of the backside insulating spacer 492 may be the same or substantially the same as a constituent material of the plurality of insulating spacers 118, which has been described above. A constituent material of the backside interlayer insulating film 496 may be the same or substantially the same as that of the upper insulating film 184, which has been described above.

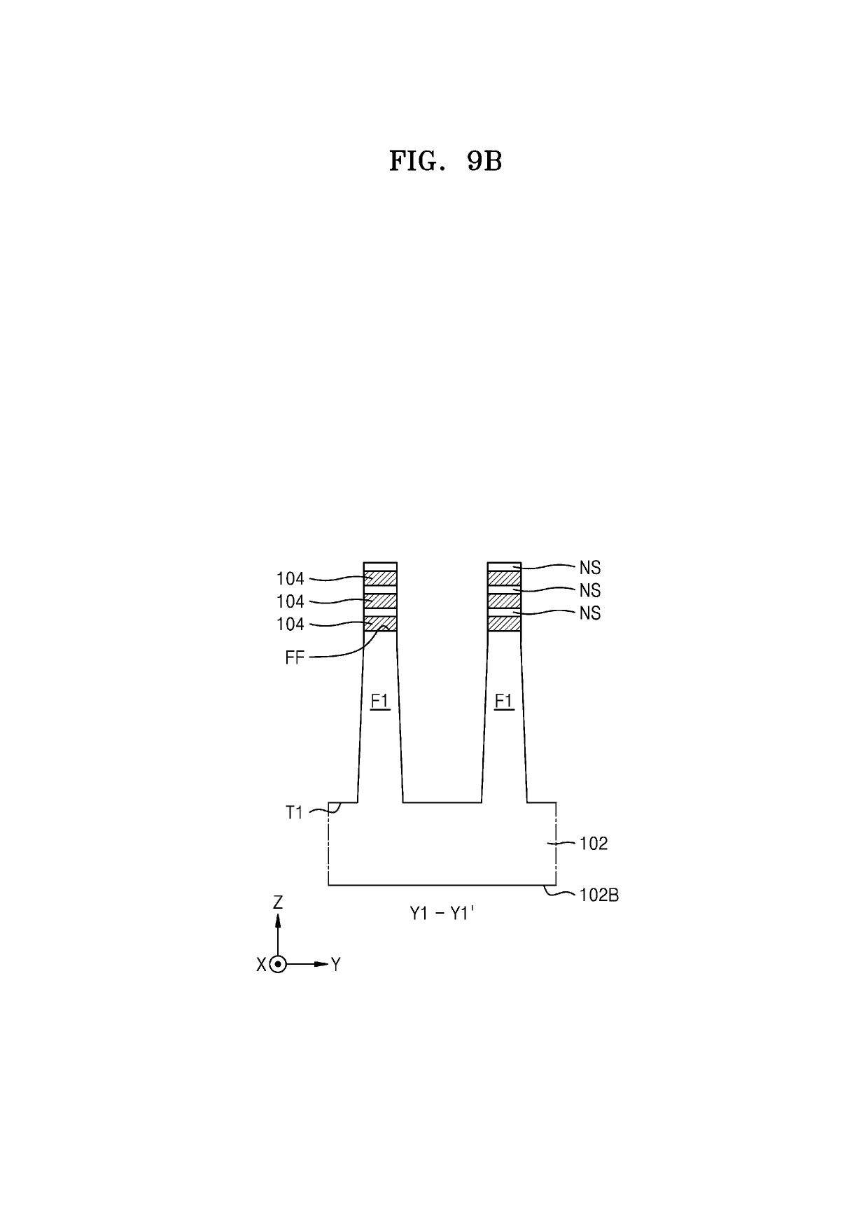

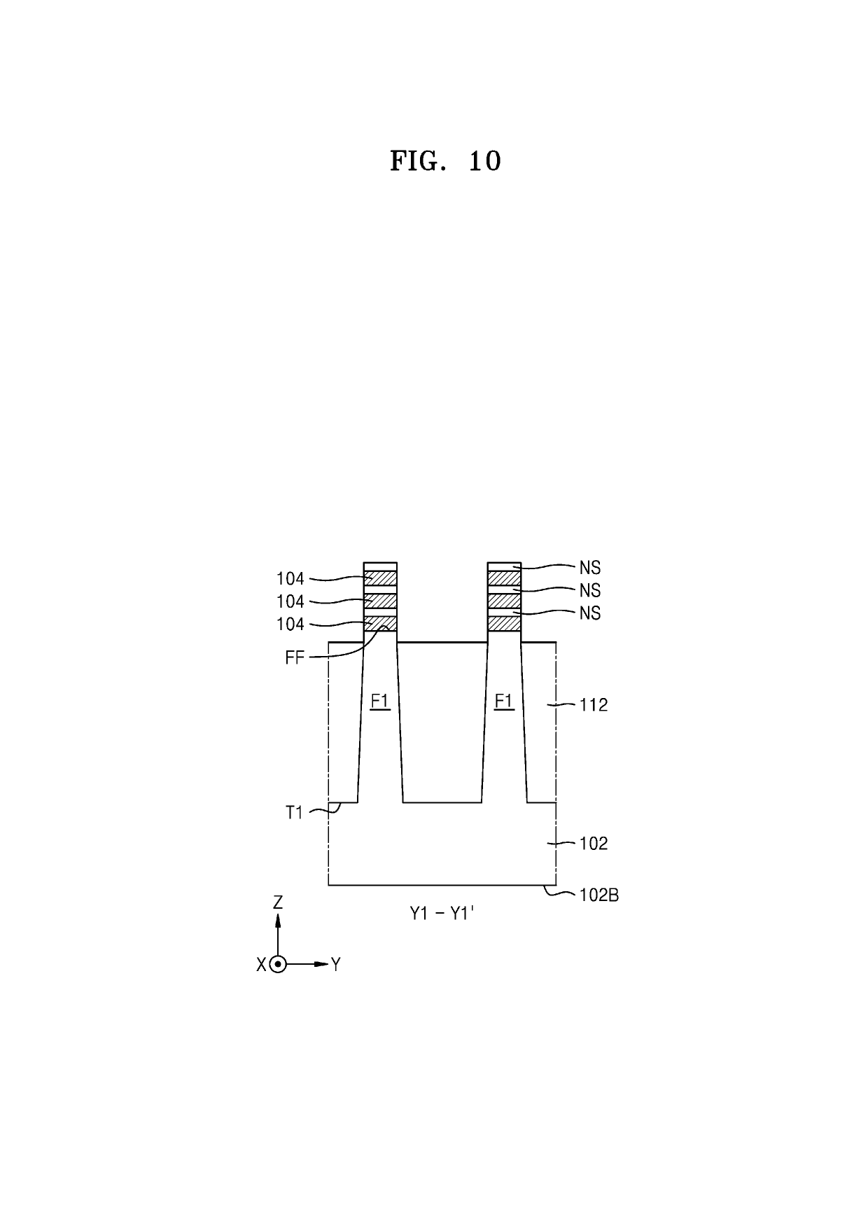

FIGS. 9A to 15B are cross-sectional views of a process sequence of a method of manufacturing an IC device, according to embodiments. More specifically, FIGS. 9A, 11A, 12A, 13A, 14A and 15A are cross-sectional views of example cross-sectional structures of a portion corresponding to a cross-section taken along line X1-X1' of FIG. 1, according to a process sequence, and FIGS. 9B, 10, 11B, 12B, 13B, 14B and 15B are cross-sectional views of example cross-sectional structures of a portion corresponding to a cross-section taken along line Y1-Y1' of FIG. 1, according to a process sequence. The method of manufacturing the IC device 100 shown in FIGS. 1 to 4 is described with reference to FIGS. 9A to 15B. In FIGS. 9A to 15B, the same reference numerals are used to denote the same elements as in FIGS. 1 to 4, and thus, repeated descriptions thereof are omitted.

Referring to FIGS. 9A and 9B, a stack structure in which a plurality of sacrificial semiconductor layers 104 and a plurality of nanosheet semiconductor layers NS are alternately stacked may be formed on a substrate 102. In the stack structure, the plurality of sacrificial semiconductor layers 104 and the plurality of nanosheet semiconductor layers NS may include semiconductor materials having different etch rates from each other. For example, the sacrificial semiconductor layers 104 may have etch selectivity over the nanosheet semiconductor layers NS. In embodiments, the plurality of nanosheet semiconductor layers NS may include a silicon (Si) layer, and the plurality of sacrificial semiconductor layers 104 may include a silicon germanium (SiGe) film. The SiGe film included in the sacrificial semiconductor layer 104 may have a Ge content, which is selected in a range of about 5 at% to about 50 at%, for example, about 10 at% to about 40 at%.

A mask pattern having openings partially exposing a top surface of the stack structure may be formed, and each of the plurality of sacrificial semiconductor layers 104, the plurality of nanosheet semiconductor layers NS, and the substrate 102 may be partially etched by using the mask pattern as an etch mask to form a plurality of fin-type active regions F1. A plurality of trench regions T1 may be defined by the plurality of fin-type active regions F1 on the substrate 102. Each of the plurality of sacrificial semiconductor layers 104 and the plurality of nanosheet semiconductor layers NS may partially remain on a fin top surface FF of each of the plurality of fin-type active regions F1.

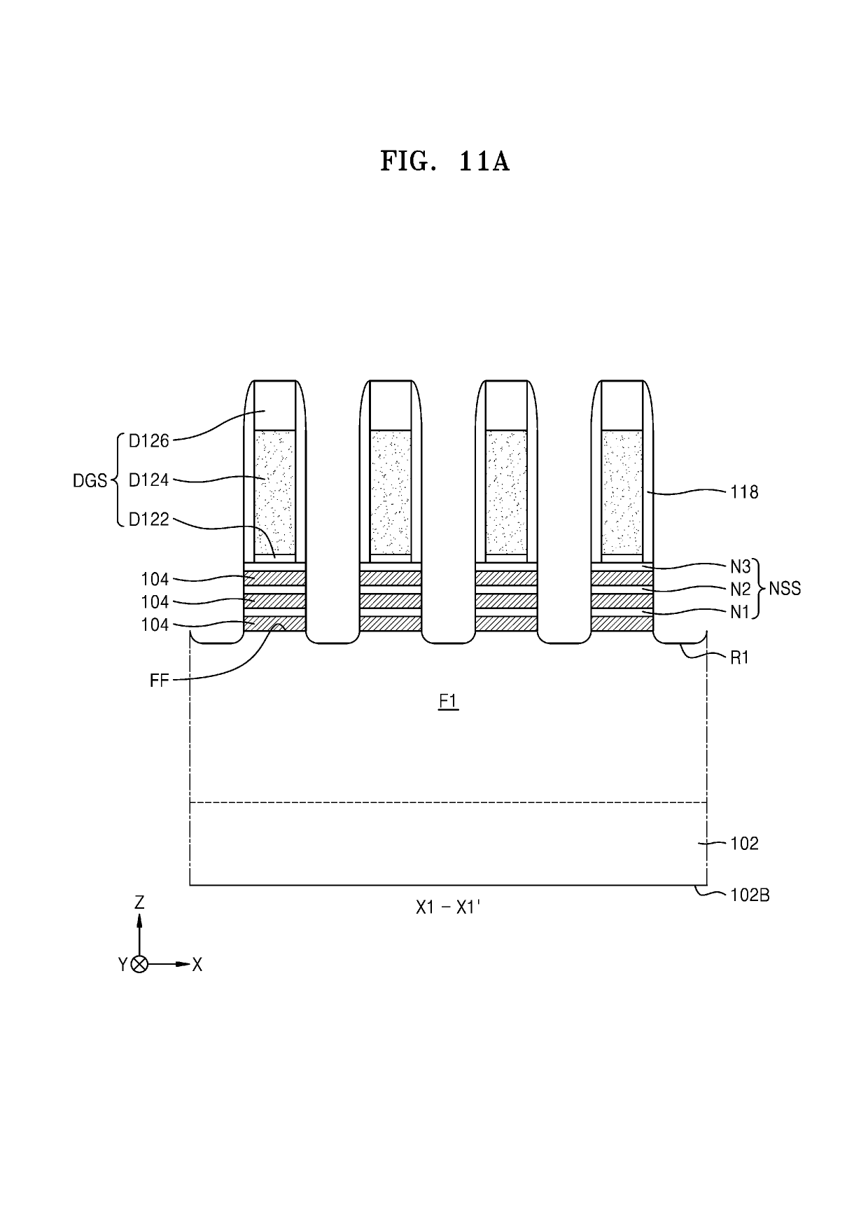

Referring to FIG. 10, a device isolation film 112 may be formed on the resultant structure on which the processes described with reference to FIGS. 9A and 9B have been performed. The device isolation film 112 may be formed to fill the plurality of trench regions T1 and cover sidewalls of each of the plurality of fin-type active regions F1. After the device isolation film 112 is formed, the stack structure including the plurality of sacrificial semiconductor layers 104 and the plurality of nanosheet semiconductor layers NS, which remains on the substrate 102, may protrude over a top surface of the device isolation film 112, and a top surface of an uppermost one of the plurality of nanosheet semiconductor layers NS may be exposed.

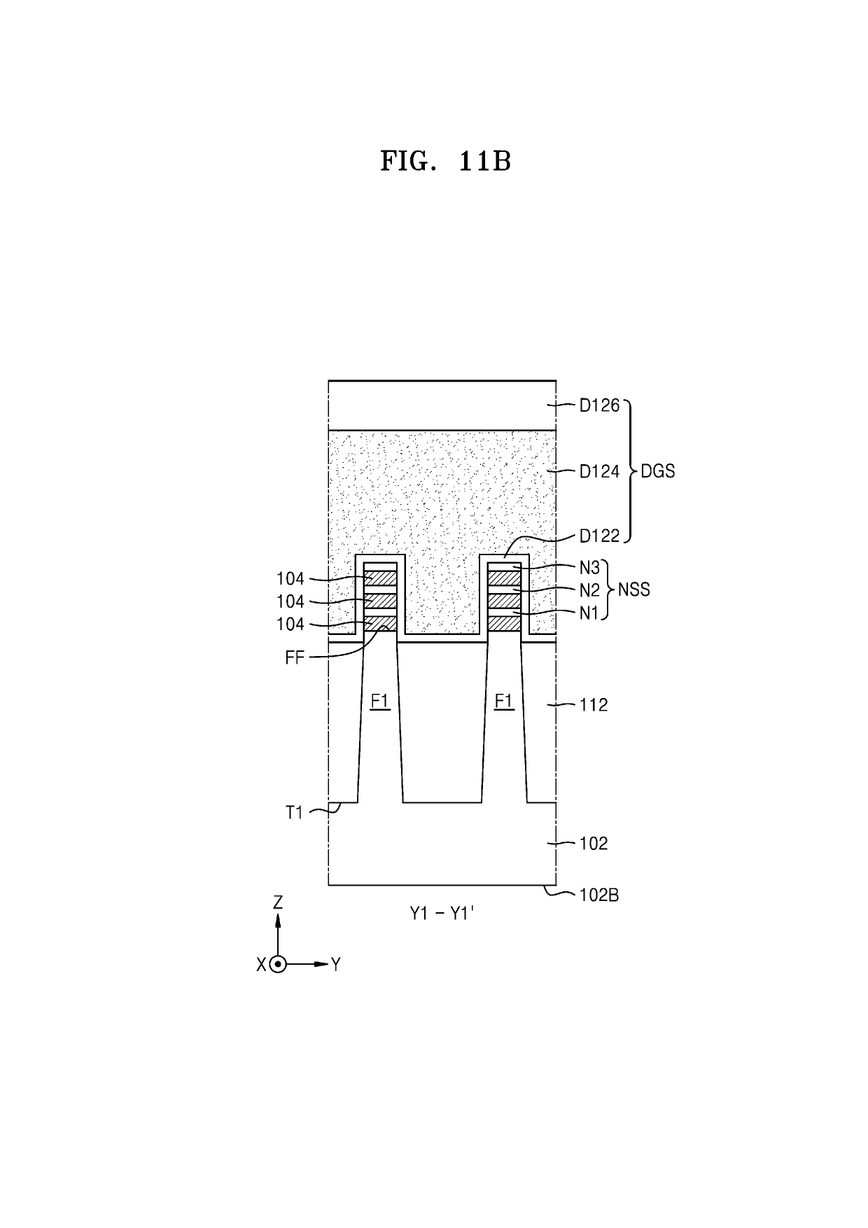

Referring to FIGS. 11A and 11B, a plurality of dummy gate structures DGS may be formed on the resultant structure on which the processes described with reference to FIG. 10 have been performed. Each of the plurality of dummy gate structures DGS may be formed to extend lengthwise in the second horizontal direction (Y direction). Each of the plurality of dummy gate structures DGS may include a dummy oxide film D122, a dummy gate layer D124, and a capping layer D126, which are sequentially stacked on the stack structure including the plurality of sacrificial semiconductor layers 104 and the plurality of nanosheet semiconductor layers NS. In embodiments, the dummy gate layer D124 may include polysilicon, and the capping layer D126 may include a silicon nitride film.

A plurality of insulating spacers 118 may be respectively formed to cover both sidewalls of the plurality of dummy gate structures DGS, and a portion of each of the plurality of sacrificial semiconductor layers 104 and the plurality of nanosheet semiconductor layers NS and a portion of each of the plurality of fin-type active regions F1 may be etched by using the plurality of dummy gate structures DGS and the plurality of insulating spacers 118 as etch masks. Thus, the plurality of nanosheet semiconductor layers NS may be divided into a plurality of nanosheet stacks NSS including first to third nanosheets N1, N2, and N3, and a plurality of recesses R1 may be respectively formed in upper portions of the plurality of fin-type active regions F1.

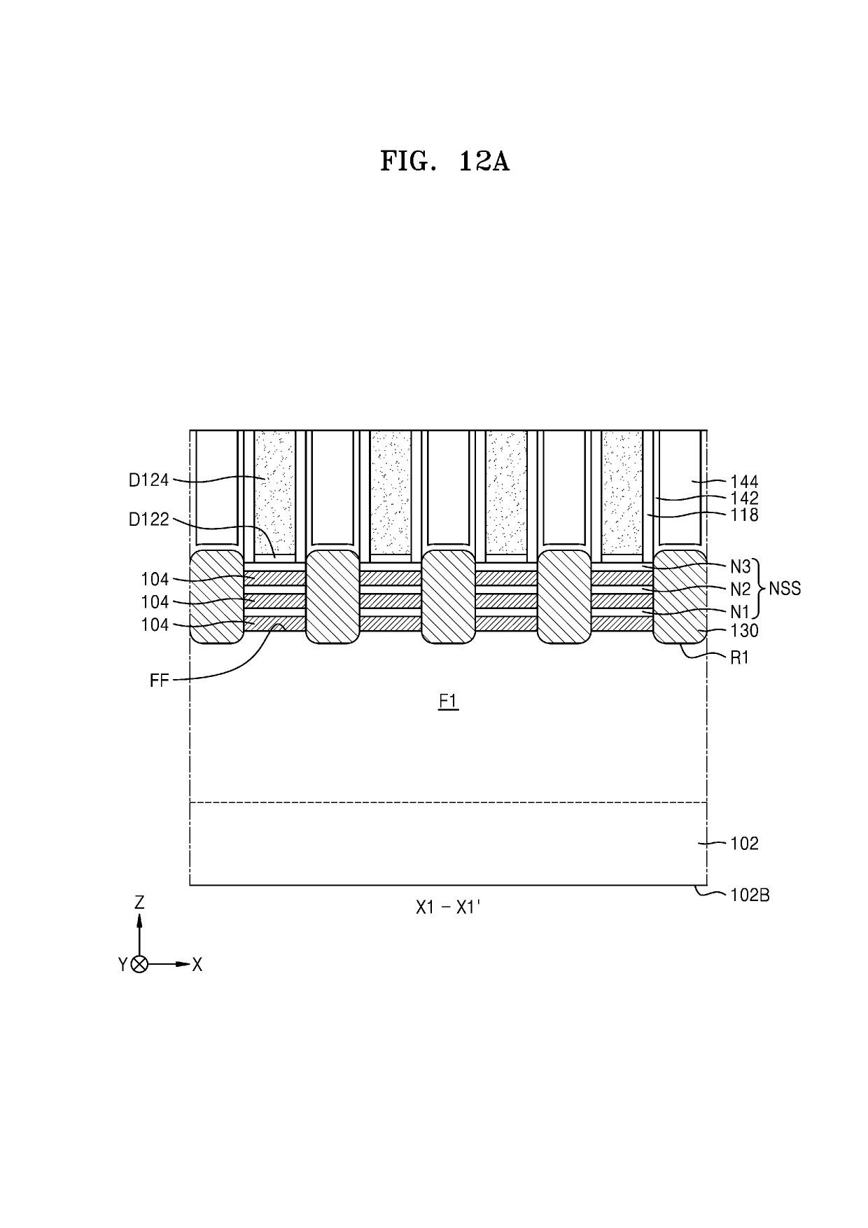

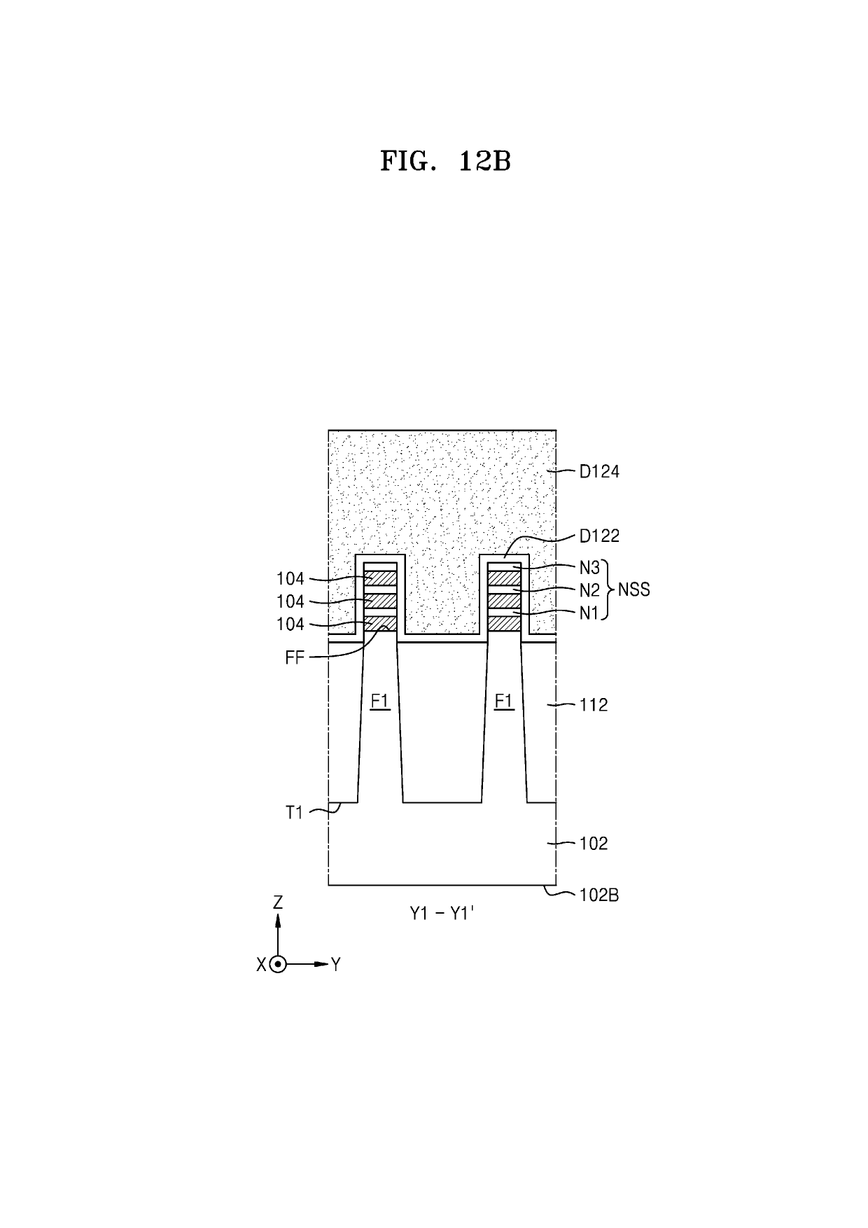

Referring to FIGS. 12A and 12B, a plurality of source/drain regions 130 filling the plurality of recesses R1 may be formed in the resultant structure of FIGS. 11A and 11B. In embodiments, to form the plurality of source/drain regions 130, a semiconductor material may be epitaxially grown from a sidewall of each of the first to third nanosheets N1, N2, and N3 exposed at the plurality of recesses R1, and surfaces of the plurality of fin-type active regions F1. The process of forming the plurality of source/drain regions 130 may be separately performed by distinguishing a first transistor region (refer to TA1 in FIG. 3) from a second transistor region (refer to TA2 in FIG. 3). In embodiments, after the source/drain region 130 arranged in the first transistor region TA1 is formed first, the source/drain region 130 arranged in the second transistor region TA2 may be formed. In other embodiments, after the source/drain region 130 arranged in the second transistor region TA2 is formed first, the source/drain region 130 arranged in the first transistor region TA1 may be formed.

Then, an insulating liner 142 may be formed to cover the resultant structure in which the plurality of source/drain regions 130 are formed, and an inter-gate dielectric film 144 may be formed on the insulating liner 142. Thereafter, each of the insulating liner 142 and the inter-gate dielectric film 144 may be partially etched to expose top surfaces of a plurality of capping layers (refer to D126 in FIGS. 11A and 11B. Afterwards, the dummy gate layer D124 may be exposed by removing the plurality of capping layers D126, and the insulating liner 142 and the inter-gate dielectric film 144 may be partially removed such that a top surface of the inter-gate dielectric film 144 and a top surface of the dummy gate layer D124 are at the same level or substantially at the same level as each other.

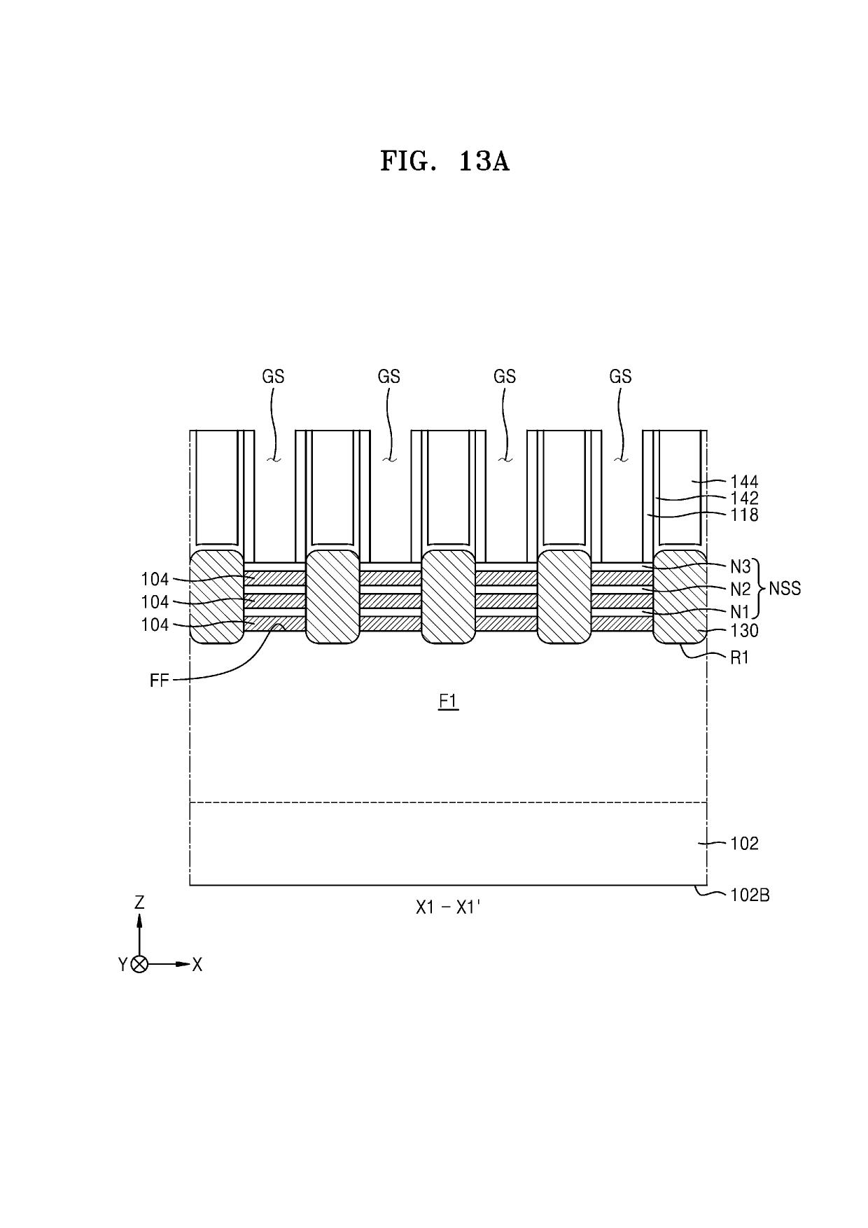

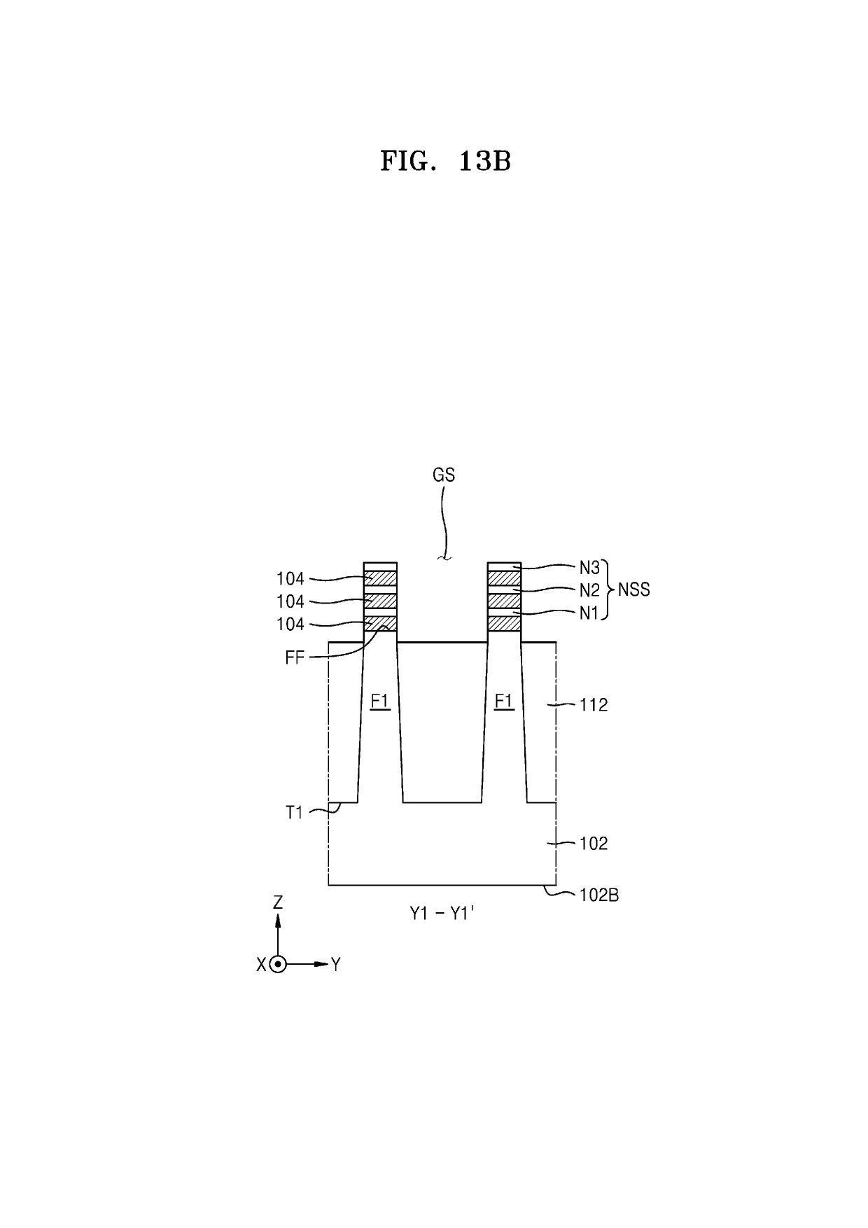

Referring to FIGS. 13A and 13B, a gate space GS may be prepared by removing the dummy gate layer D124 and the dummy oxide film D122 from the resultant structure of FIGS. 12A and 12B.

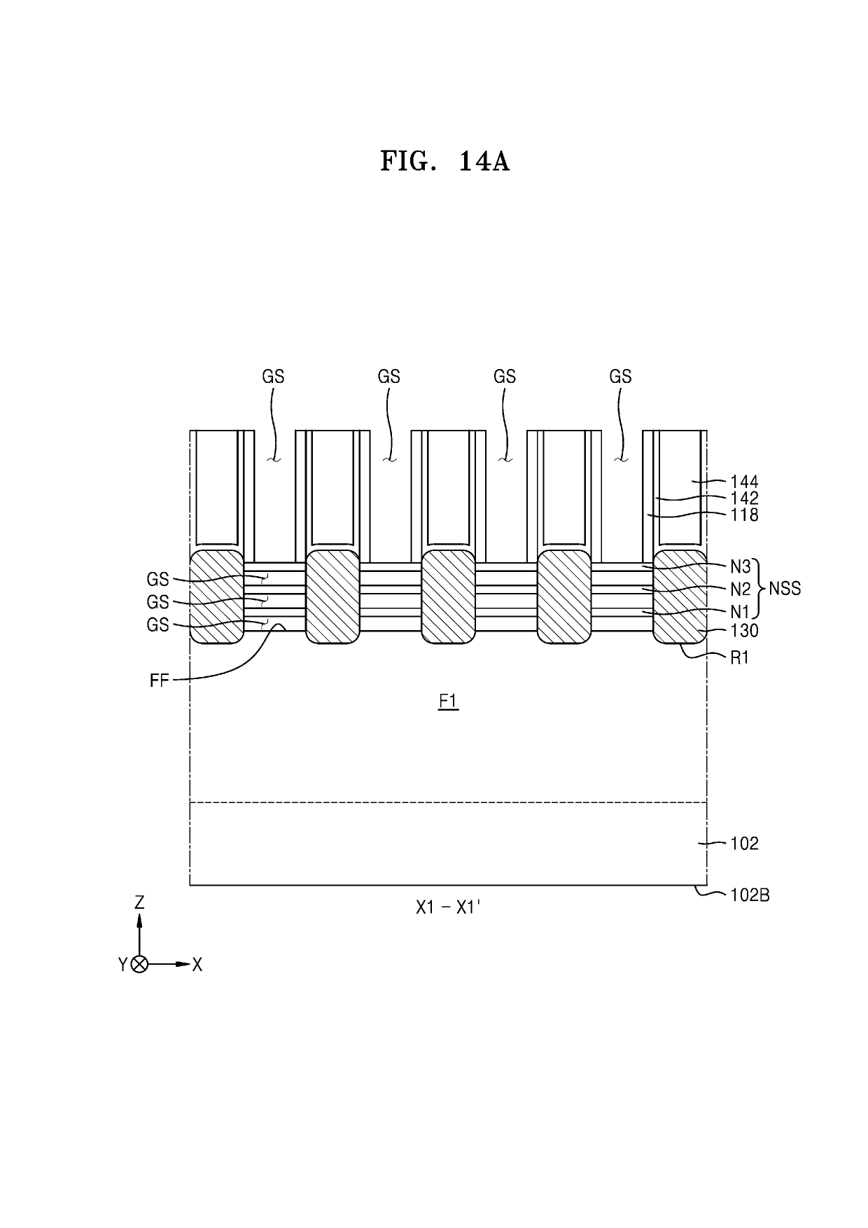

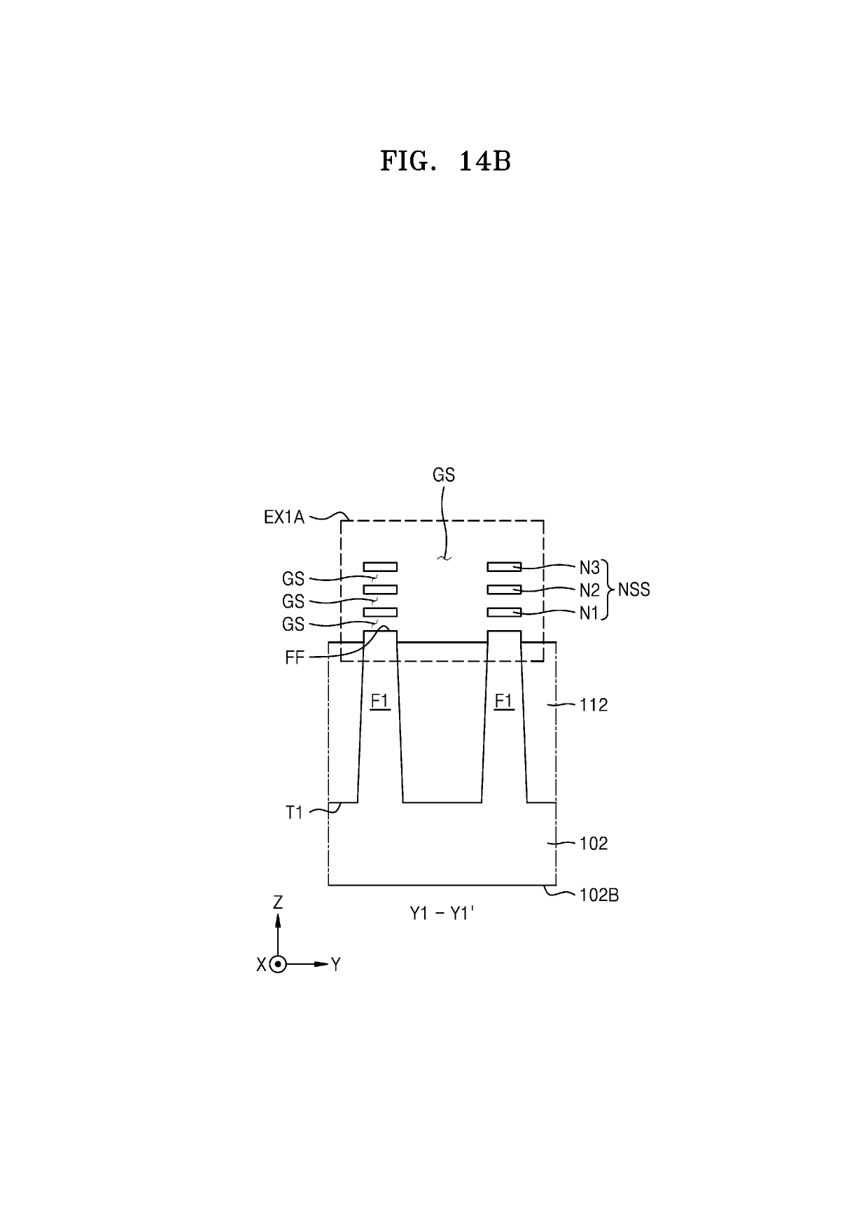

Referring to FIGS. 14A and 14B, in the resultant structure of FIGS. 13A and 13B, the plurality of sacrificial semiconductor layers 104 remaining on the substrate 102 may be selectively removed through the gate space GS. Thus, the gate space GS may extend to a space between each pair of adjacent ones of the first to third nanosheets N1, N2, and N3 and a space between a first nanosheet N and the fin top surface FF.

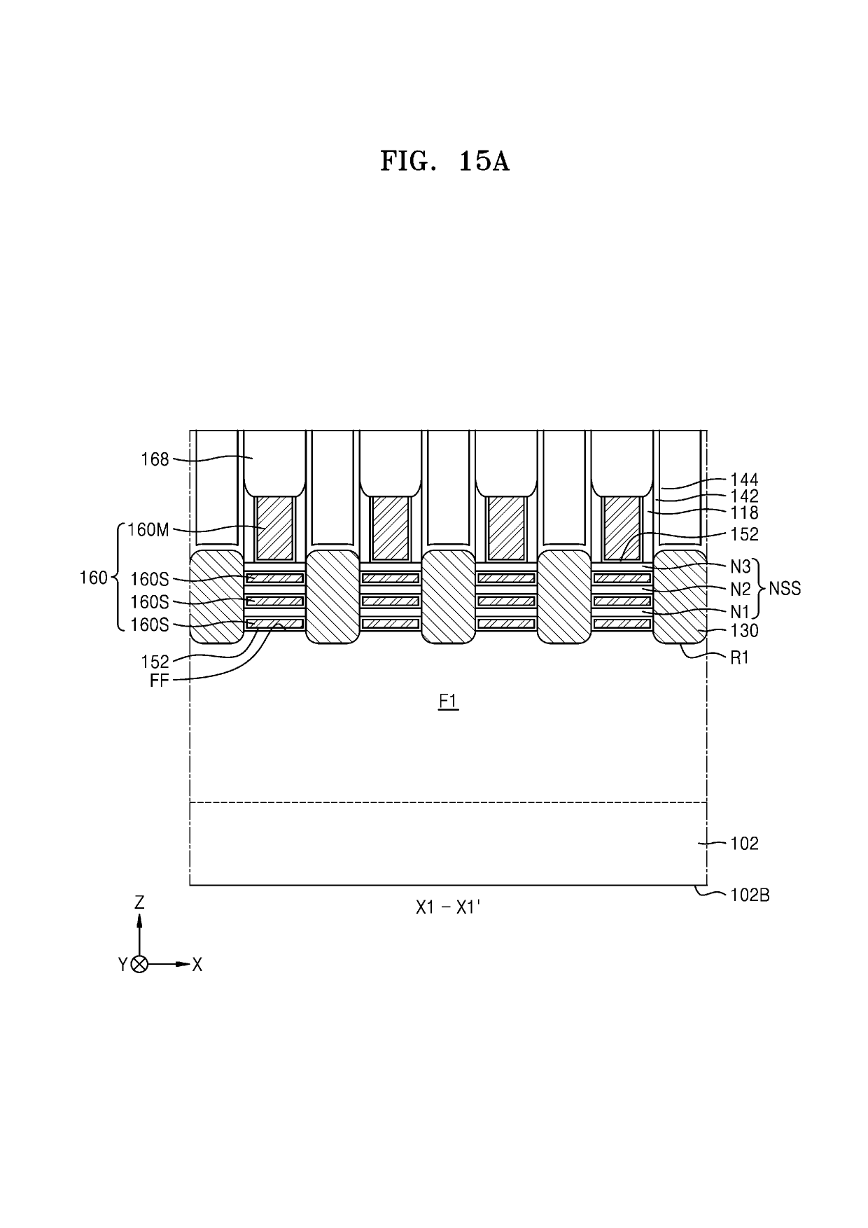

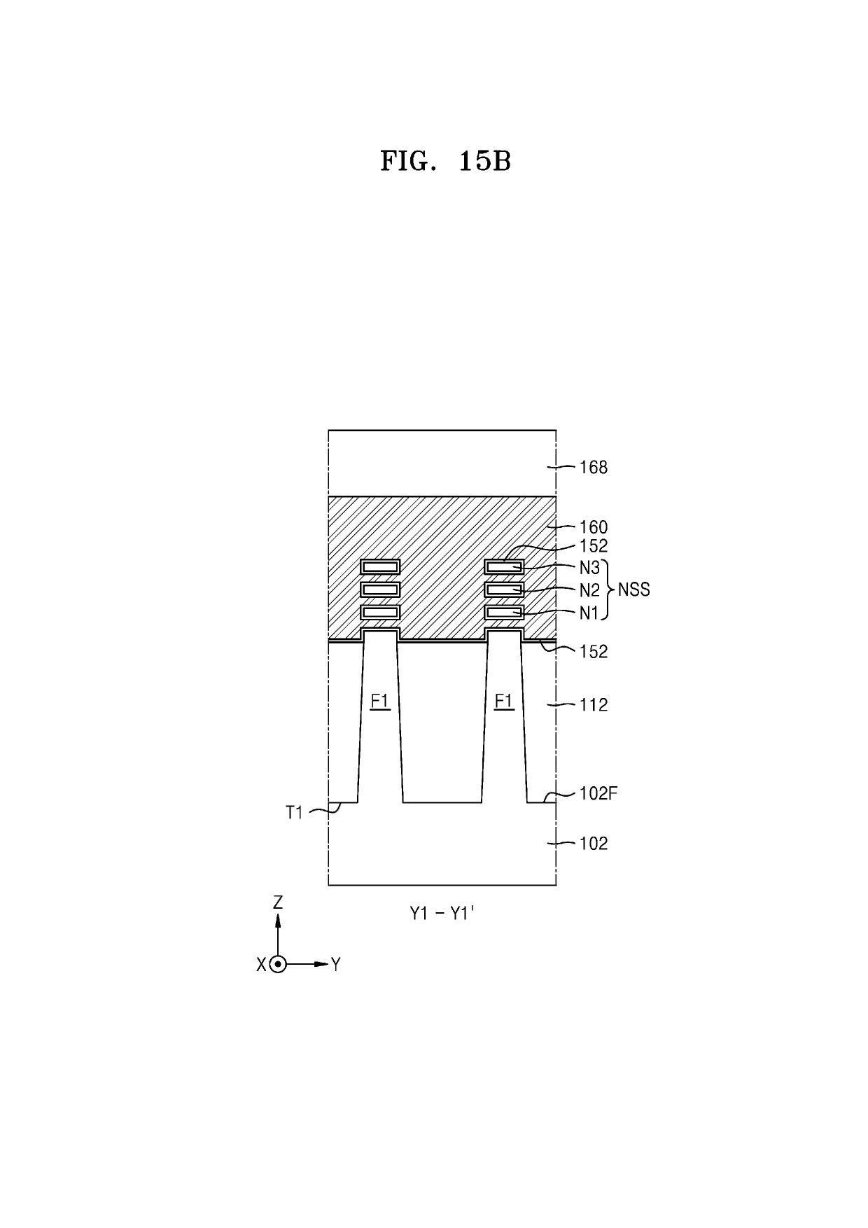

Referring to FIGS. 15A and 15B, in the resultant structure of FIGS. 14A and 14B, a gate dielectric film 152 may be formed to cover respective exposed surfaces of the first to third nanosheets N1, N2, and N3 and the plurality of fin-type active regions F1. The gate dielectric film 152 may be formed by using an ALD process. Thereafter, a gate line 160 filling the gate space (refer to GS in FIGS. 14A and 14B) may be formed on the gate dielectric film 152. Thereafter, a height of each of the gate line 160, the gate dielectric film 152, and the insulating spacer 118 may be reduced by removing a portion of each of the gate line 160, the gate dielectric film 152, and the insulating spacer 118 from a top surface of each thereof, and a plurality of capping insulating patterns 168 may be formed to cover the top surface of each of the gate line 160, the gate dielectric film 152, and the insulating spacer 118.

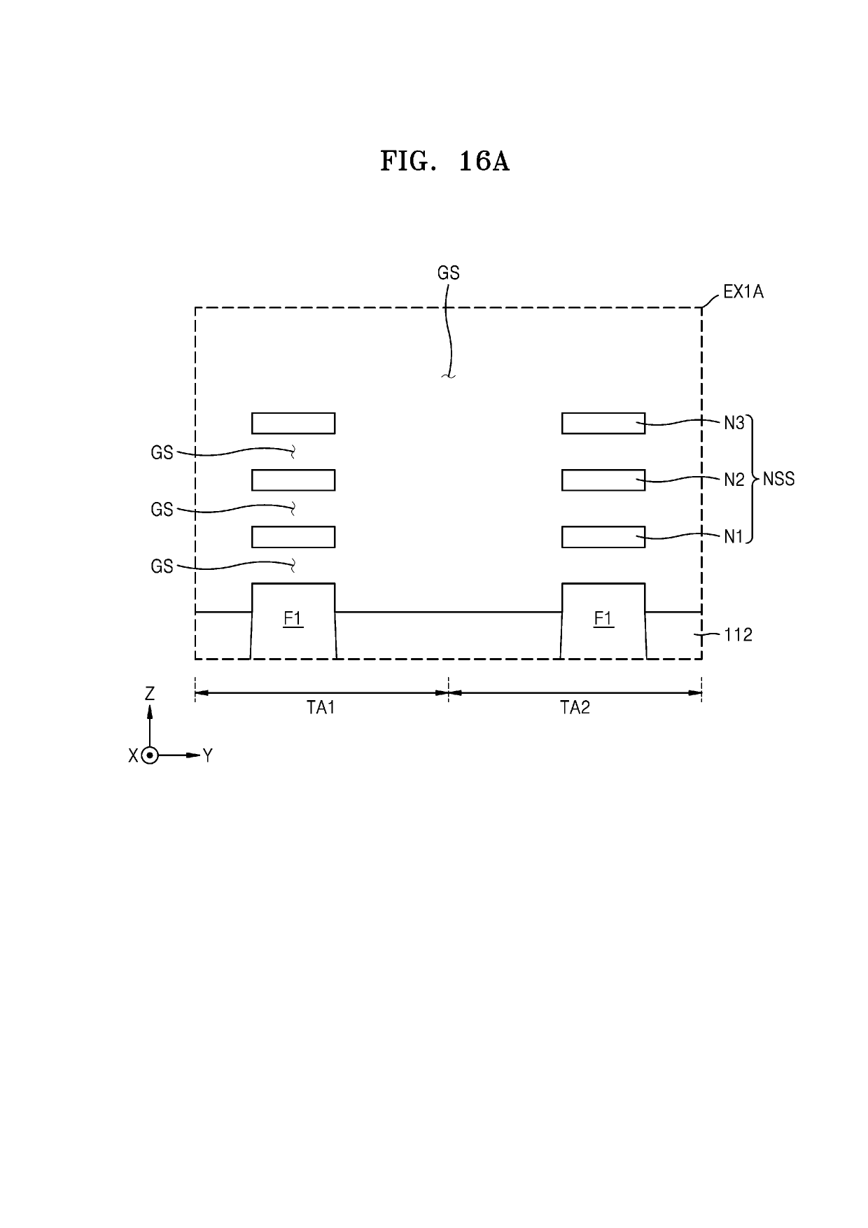

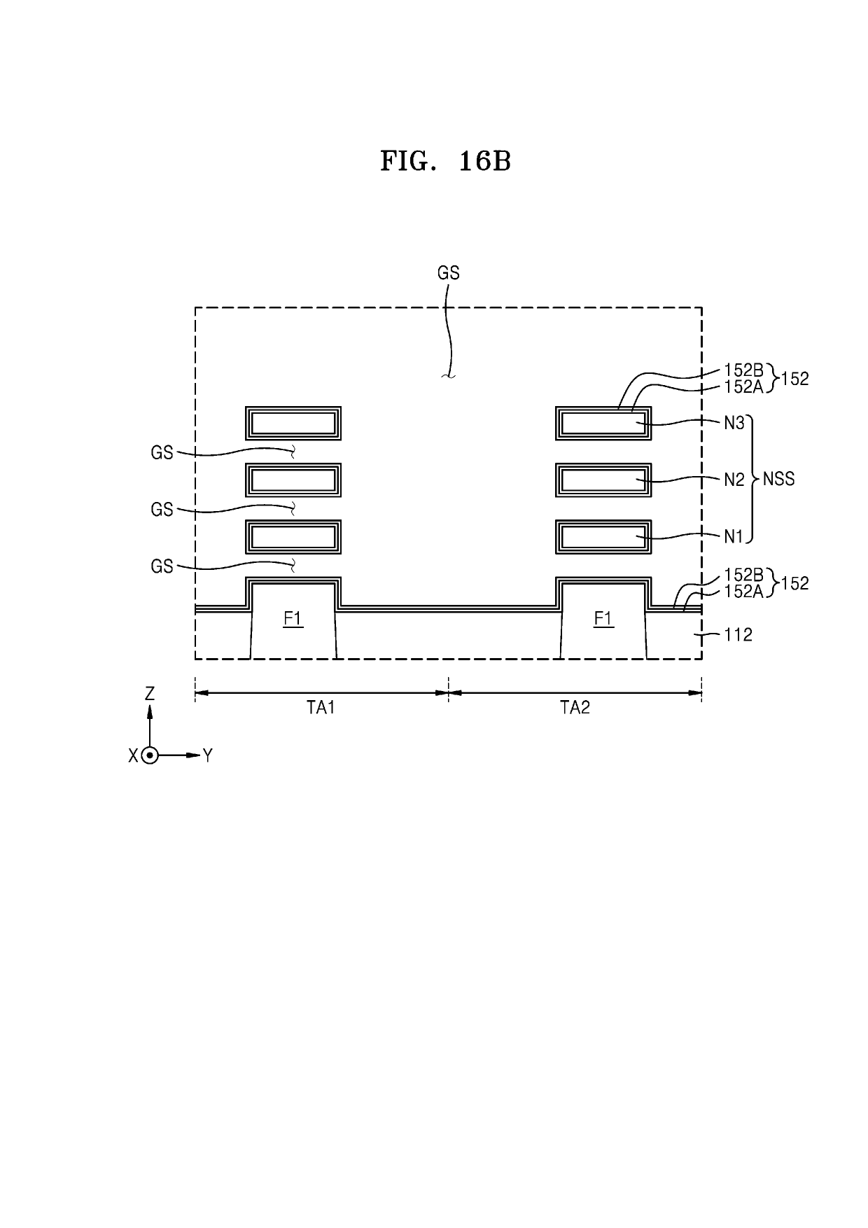

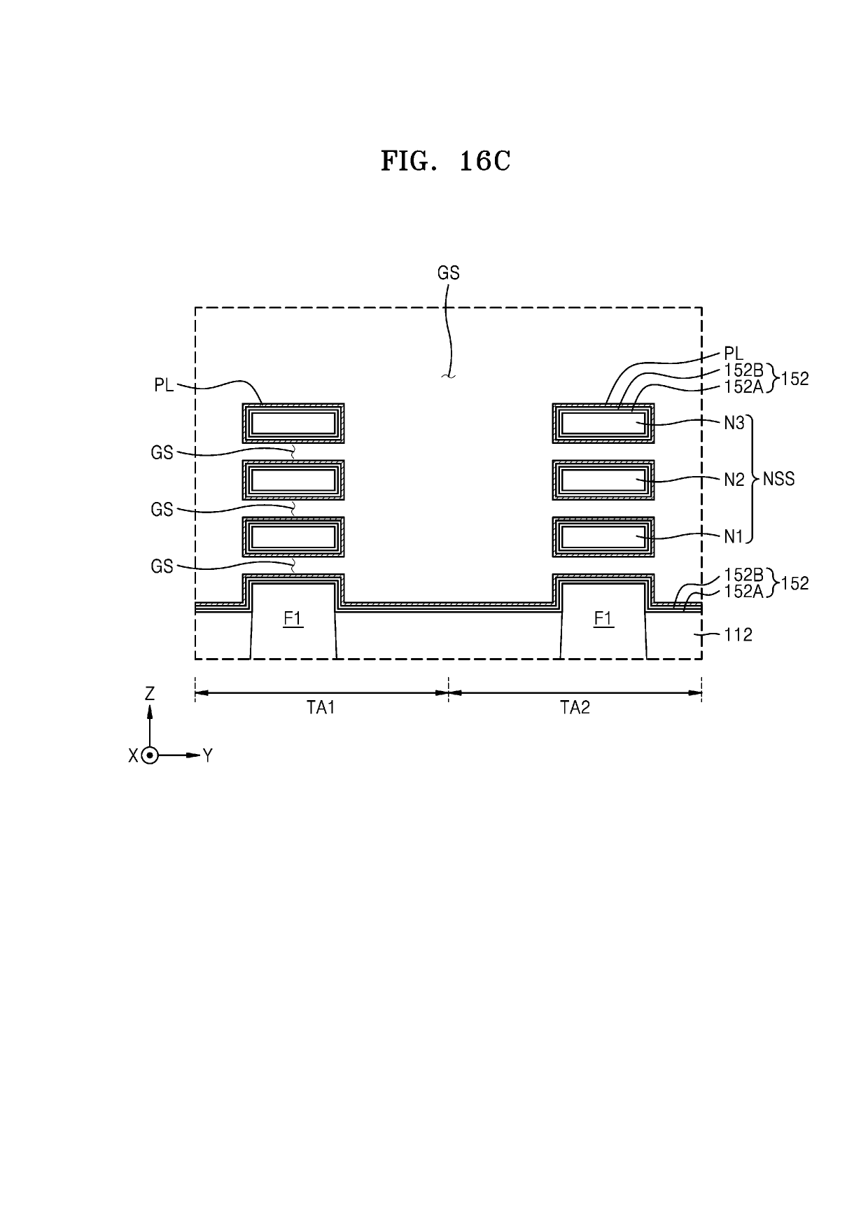

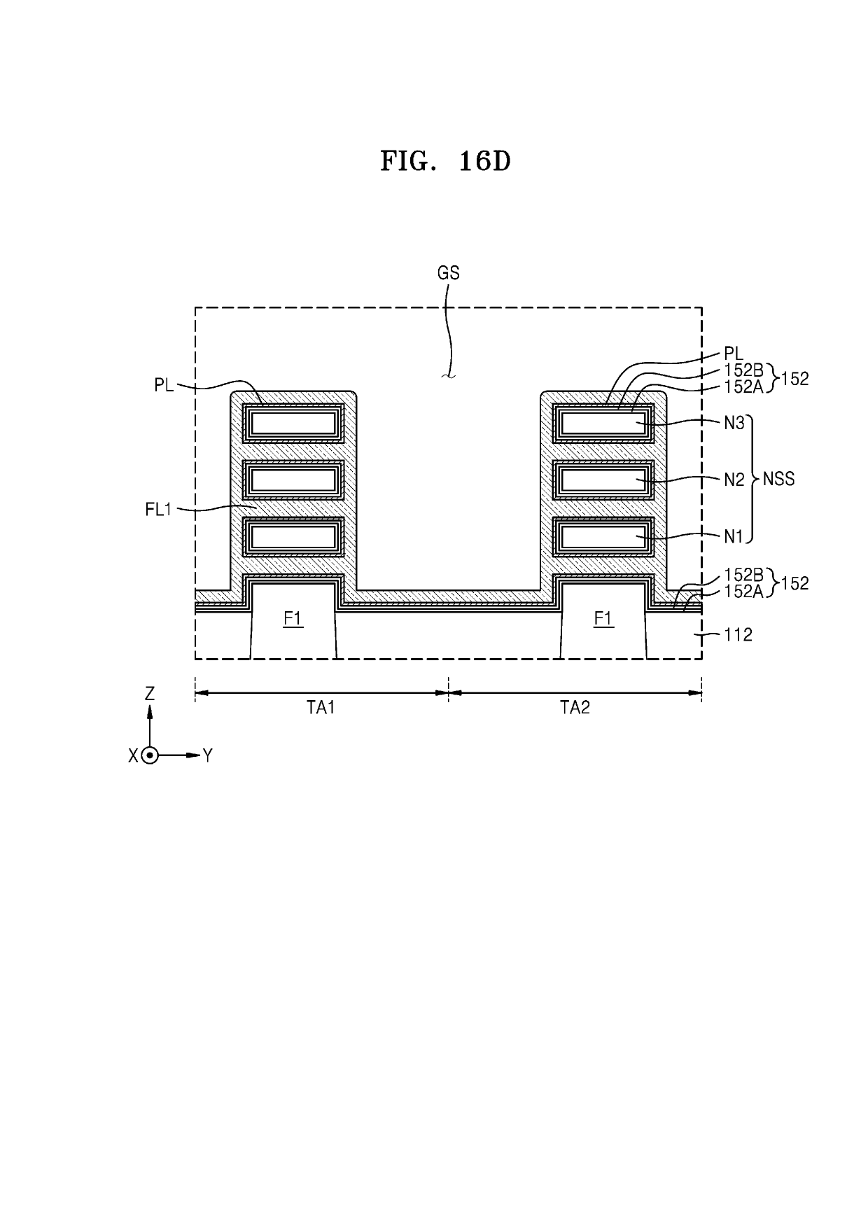

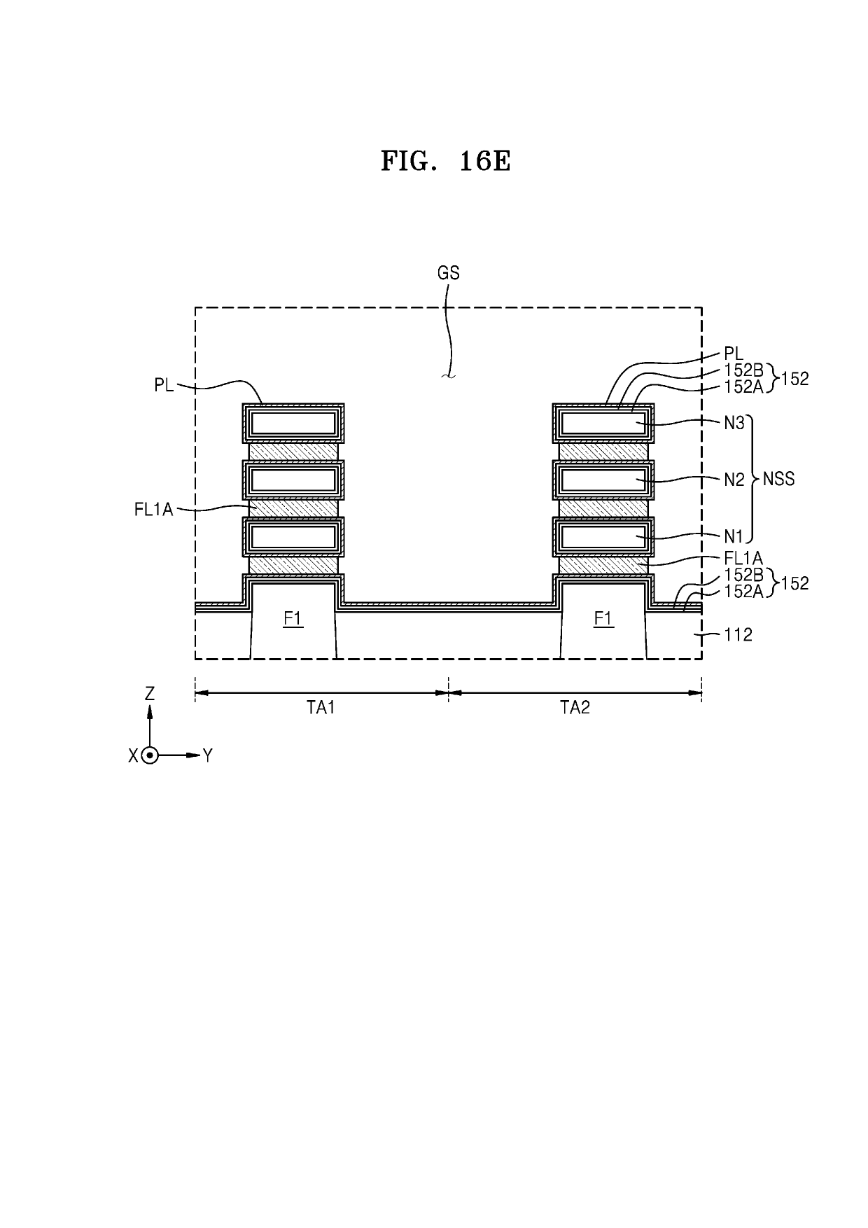

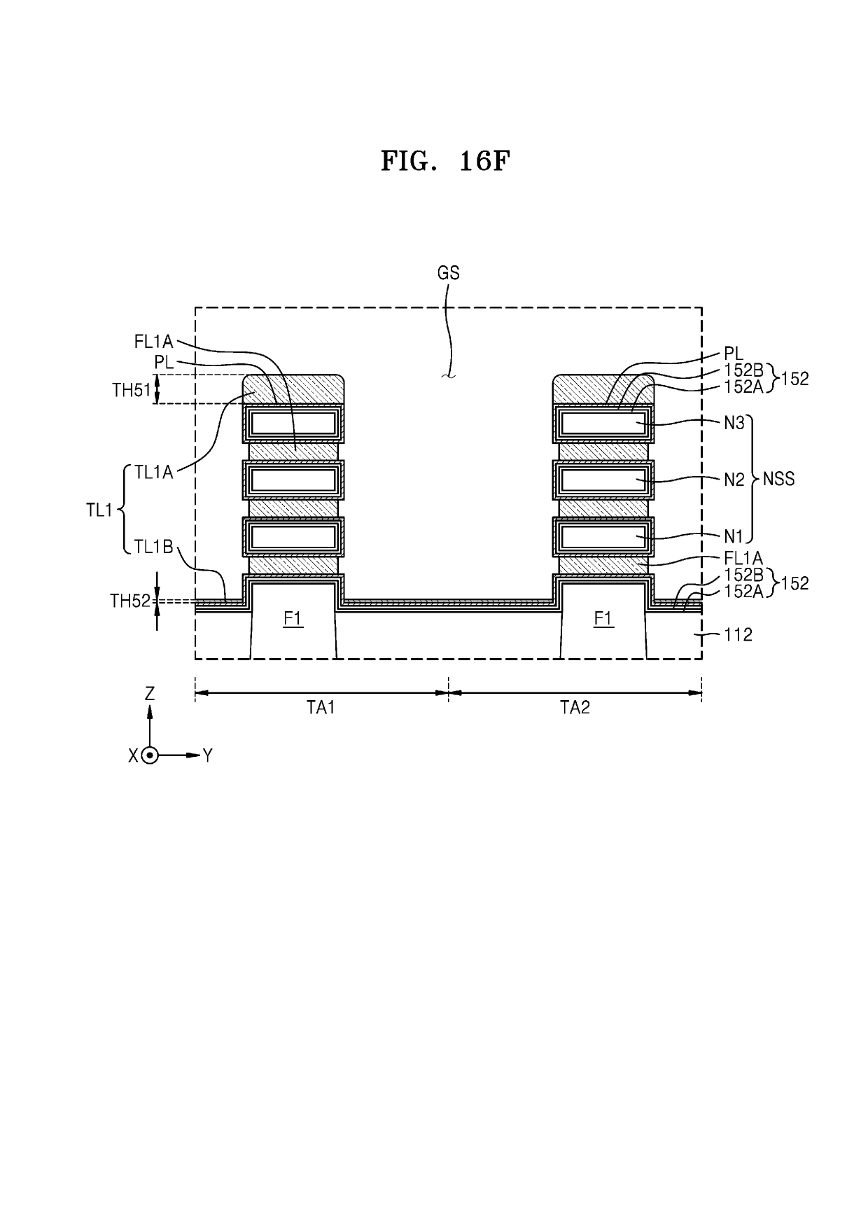

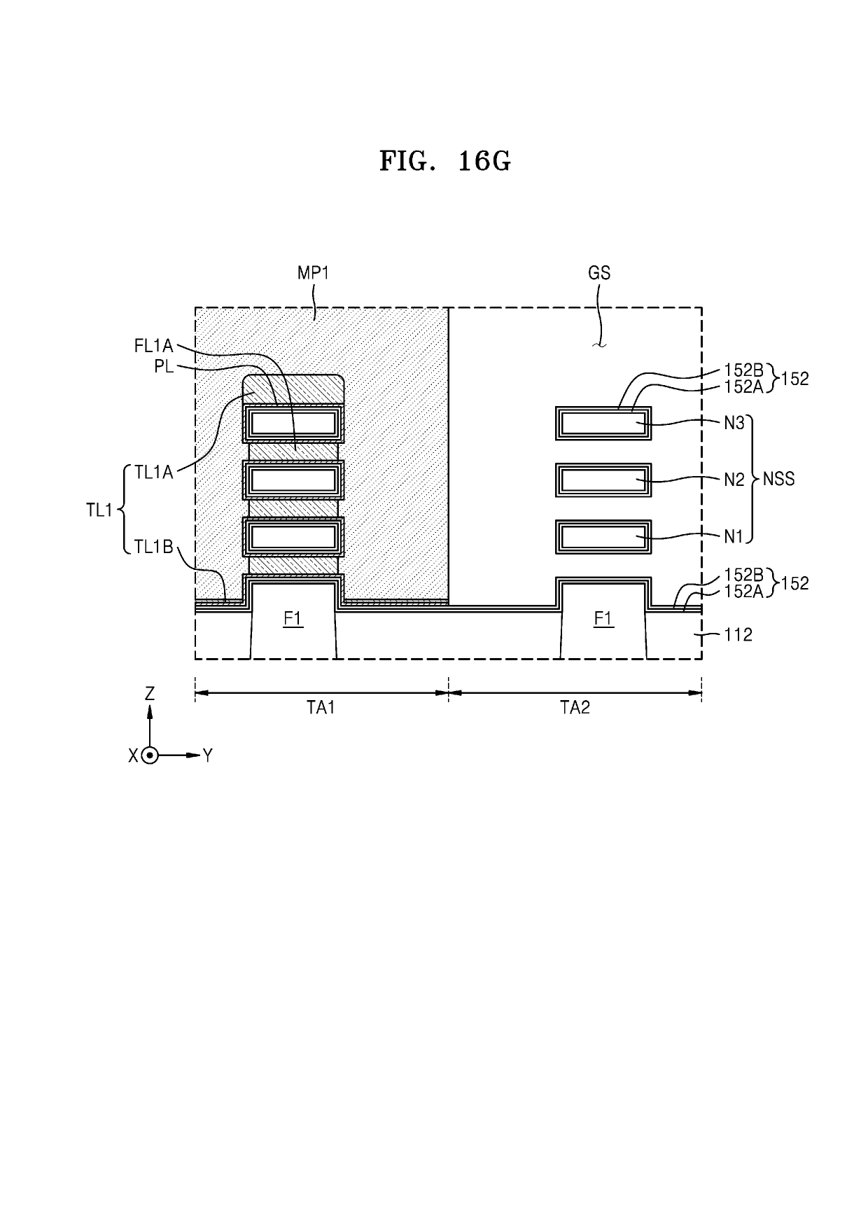

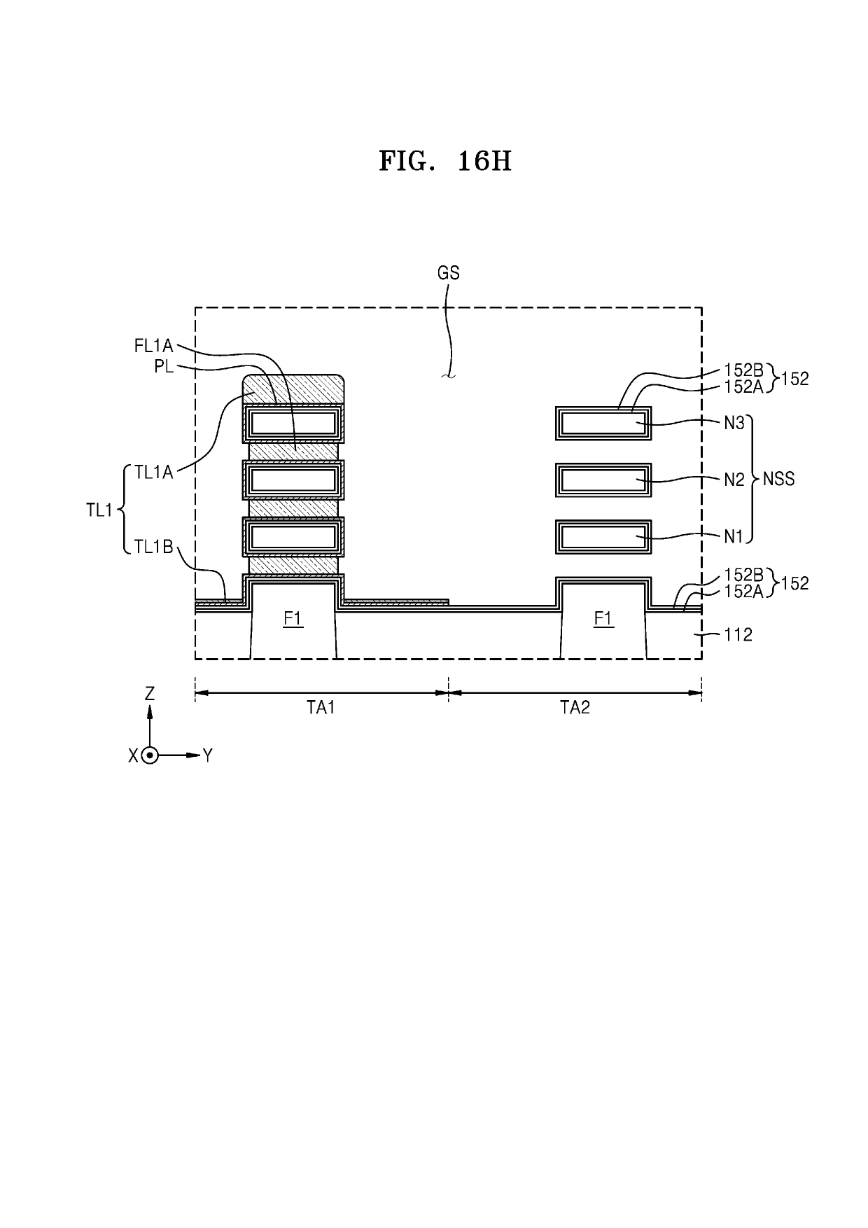

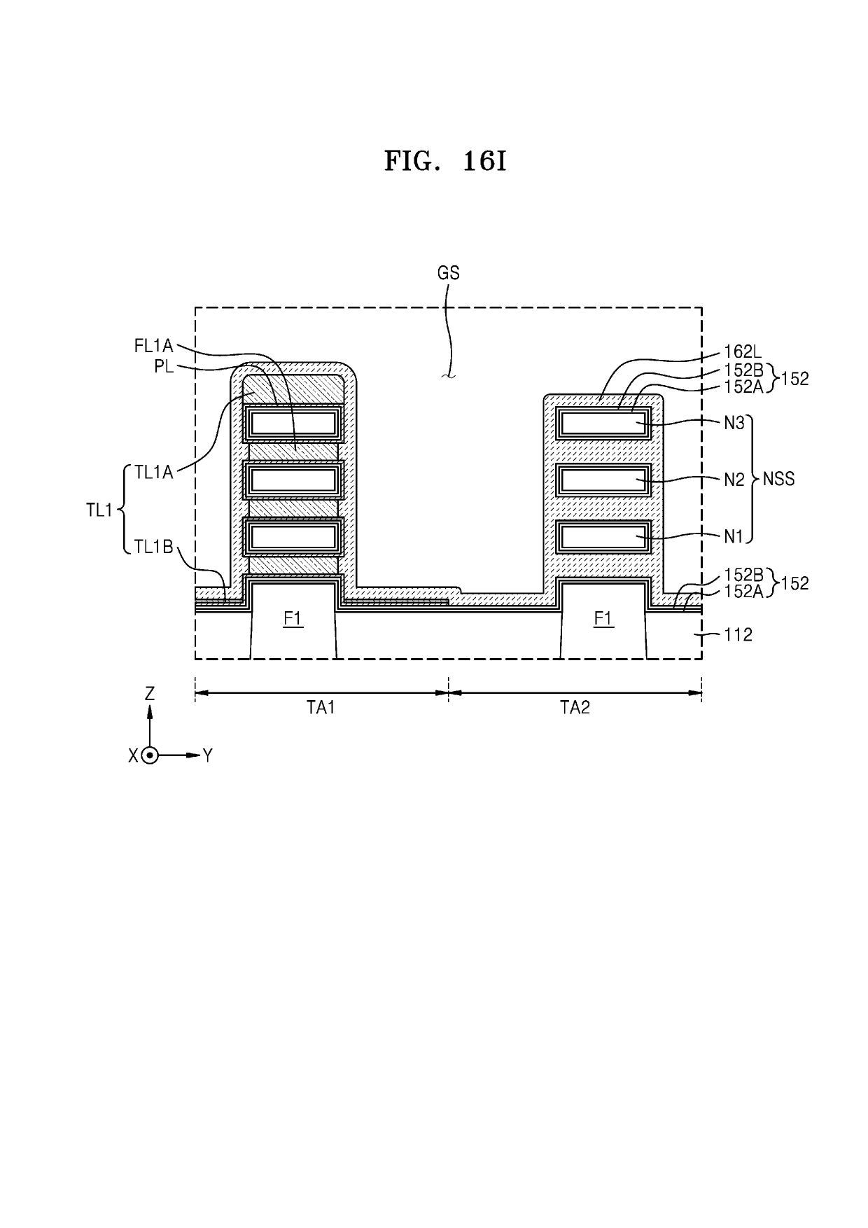

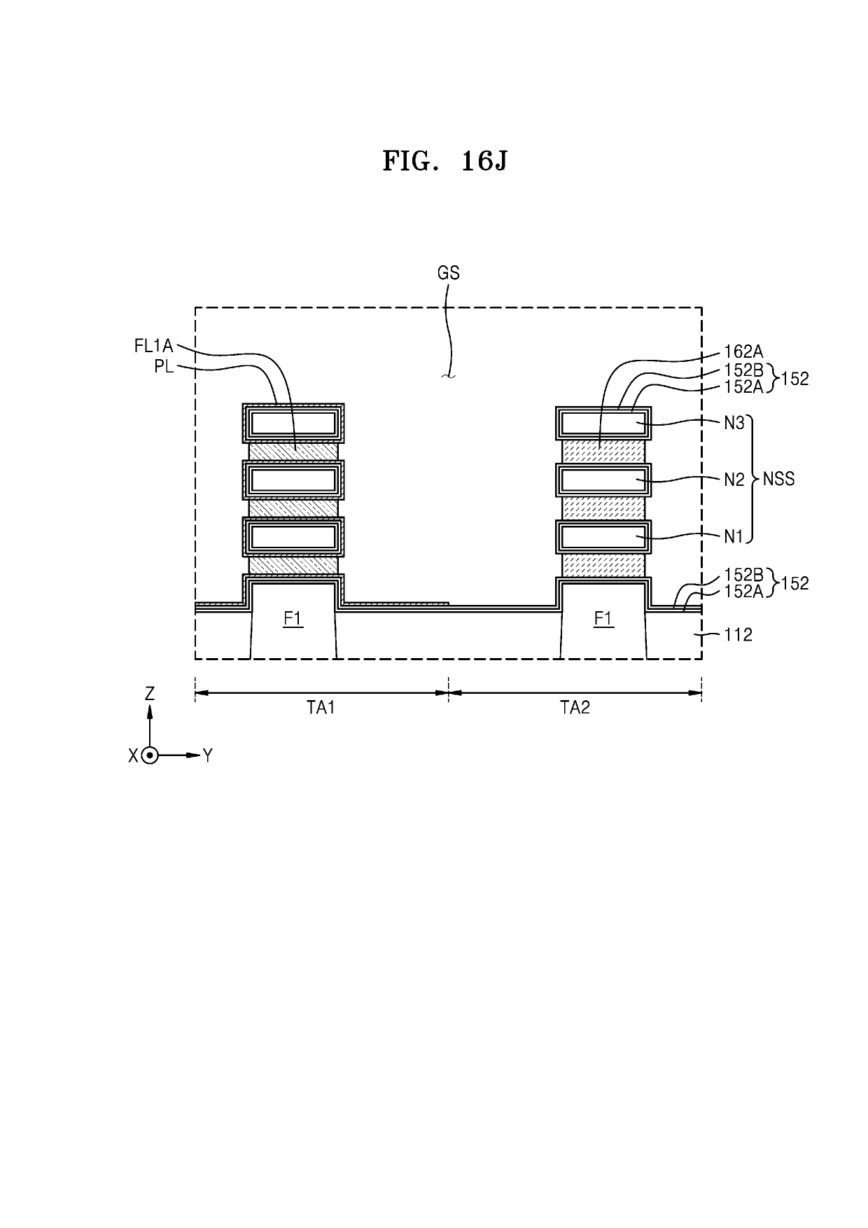

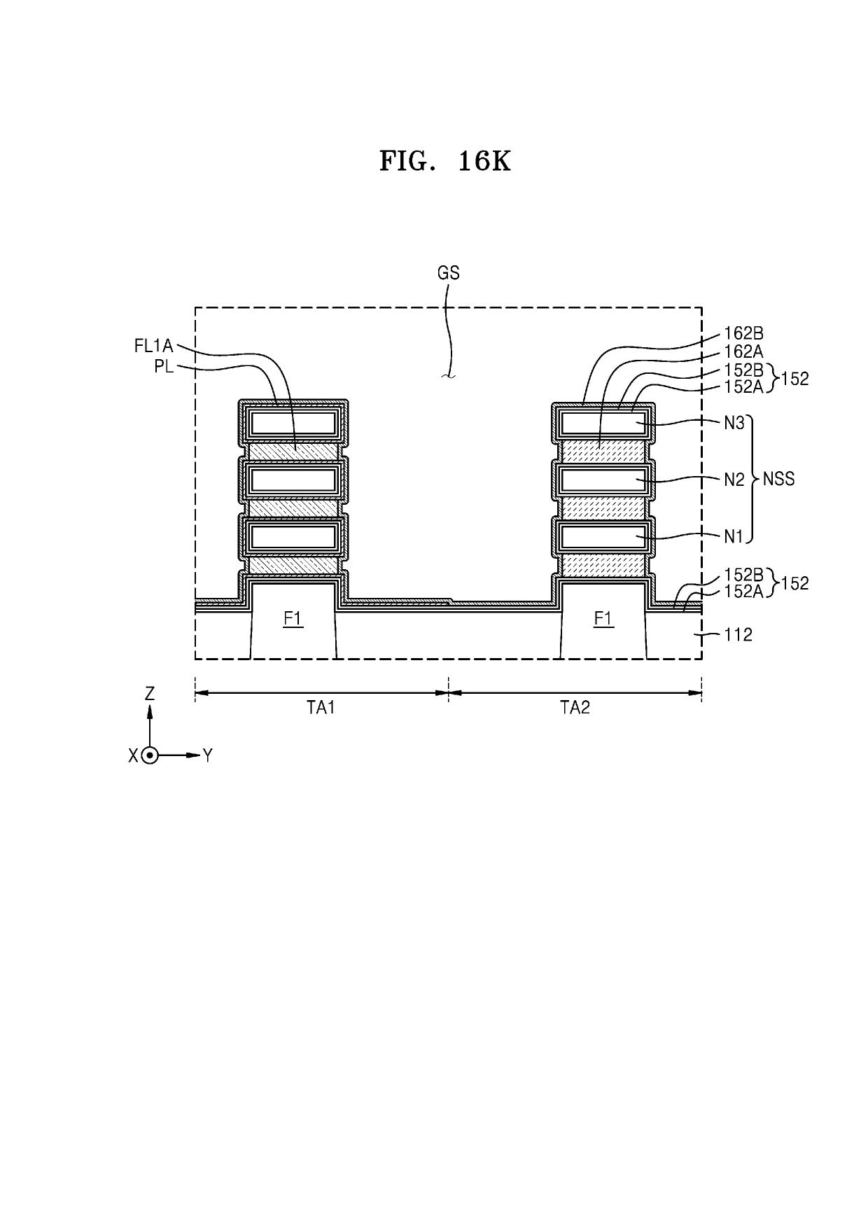

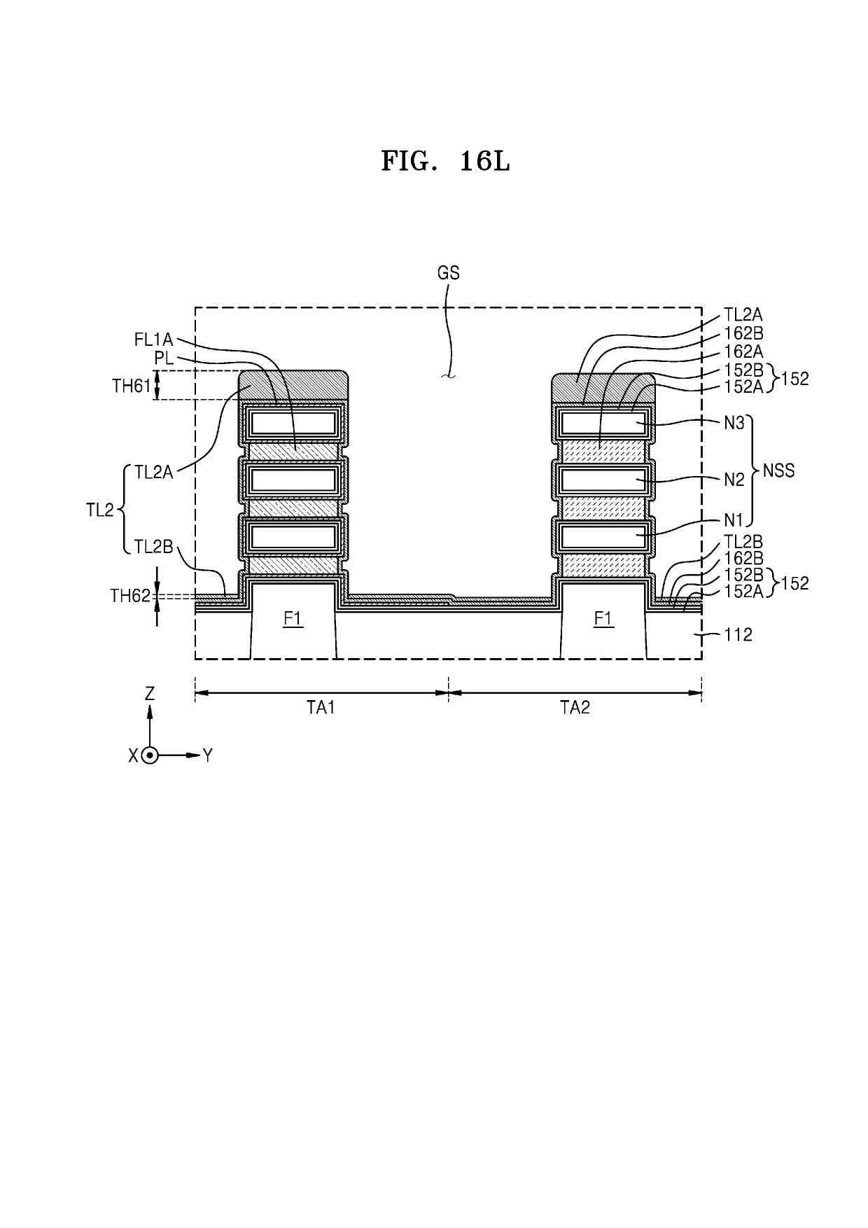

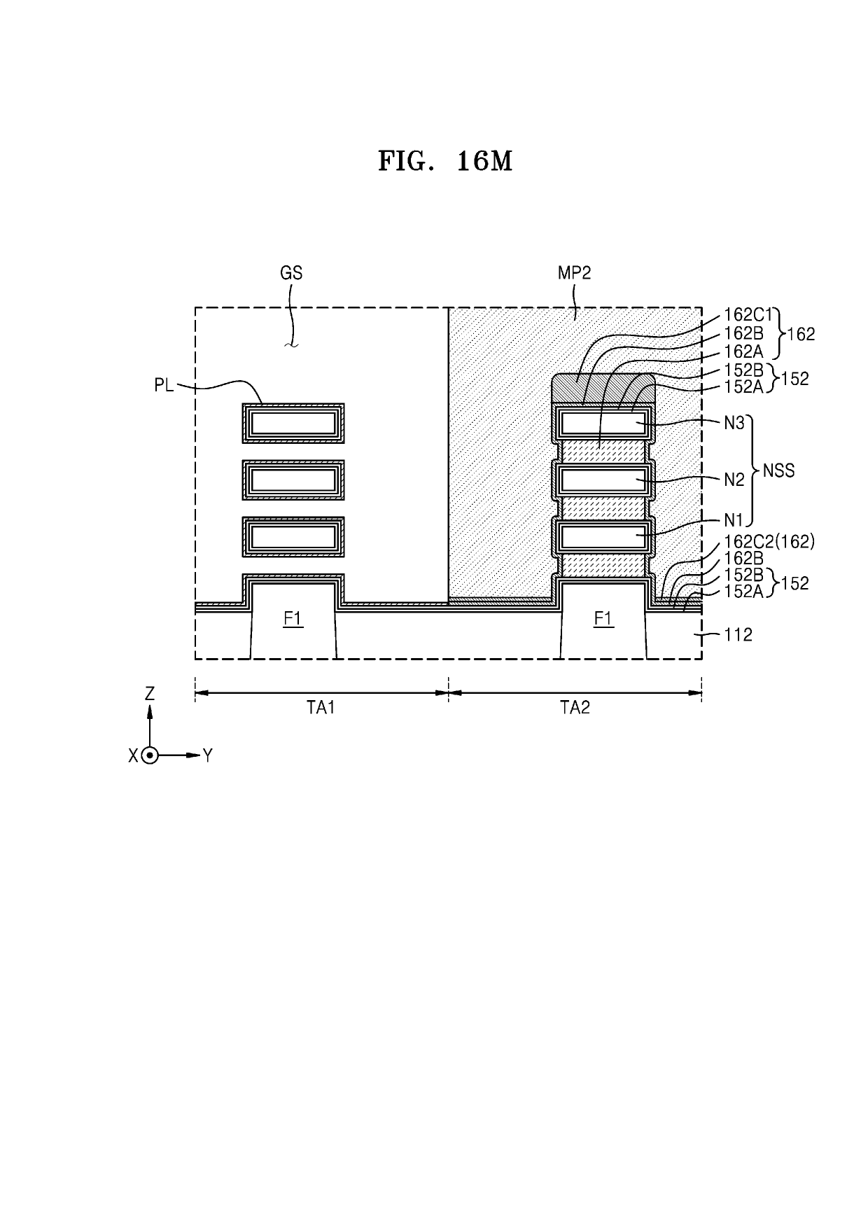

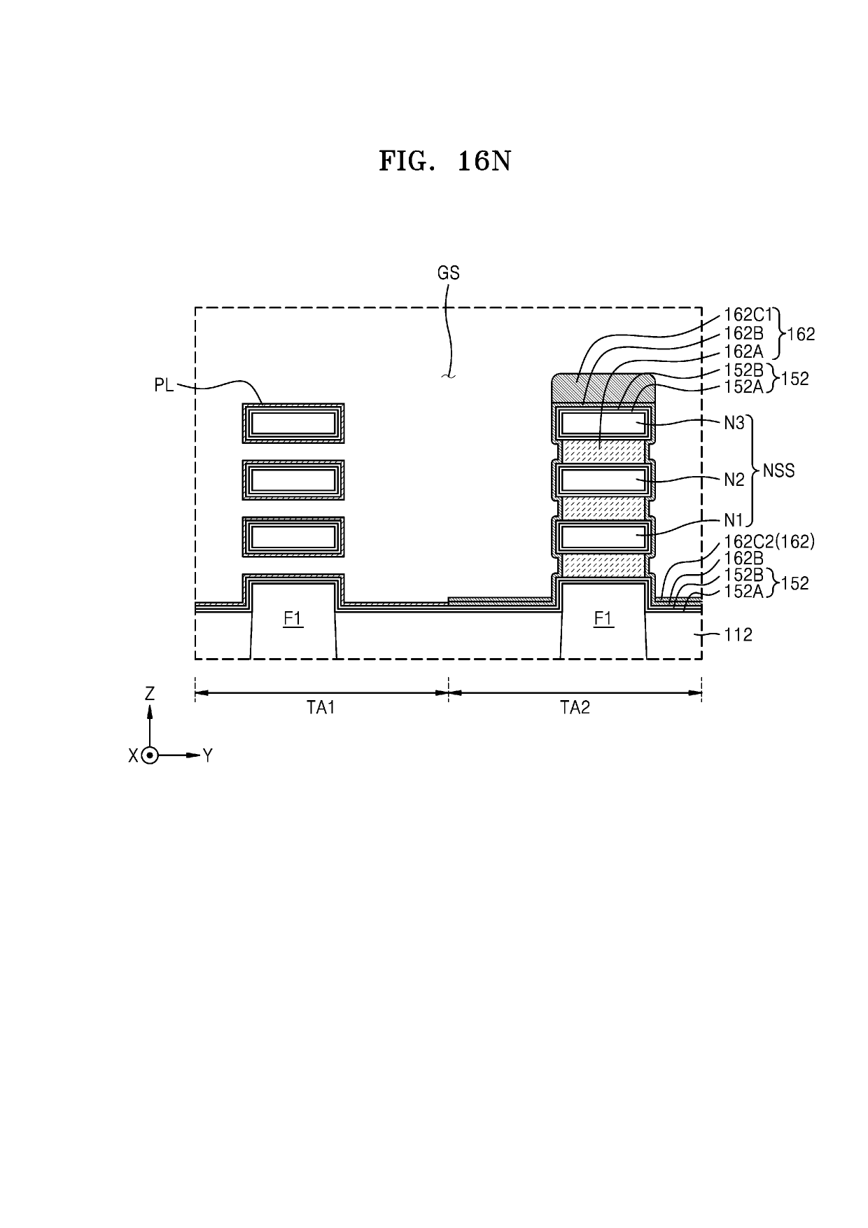

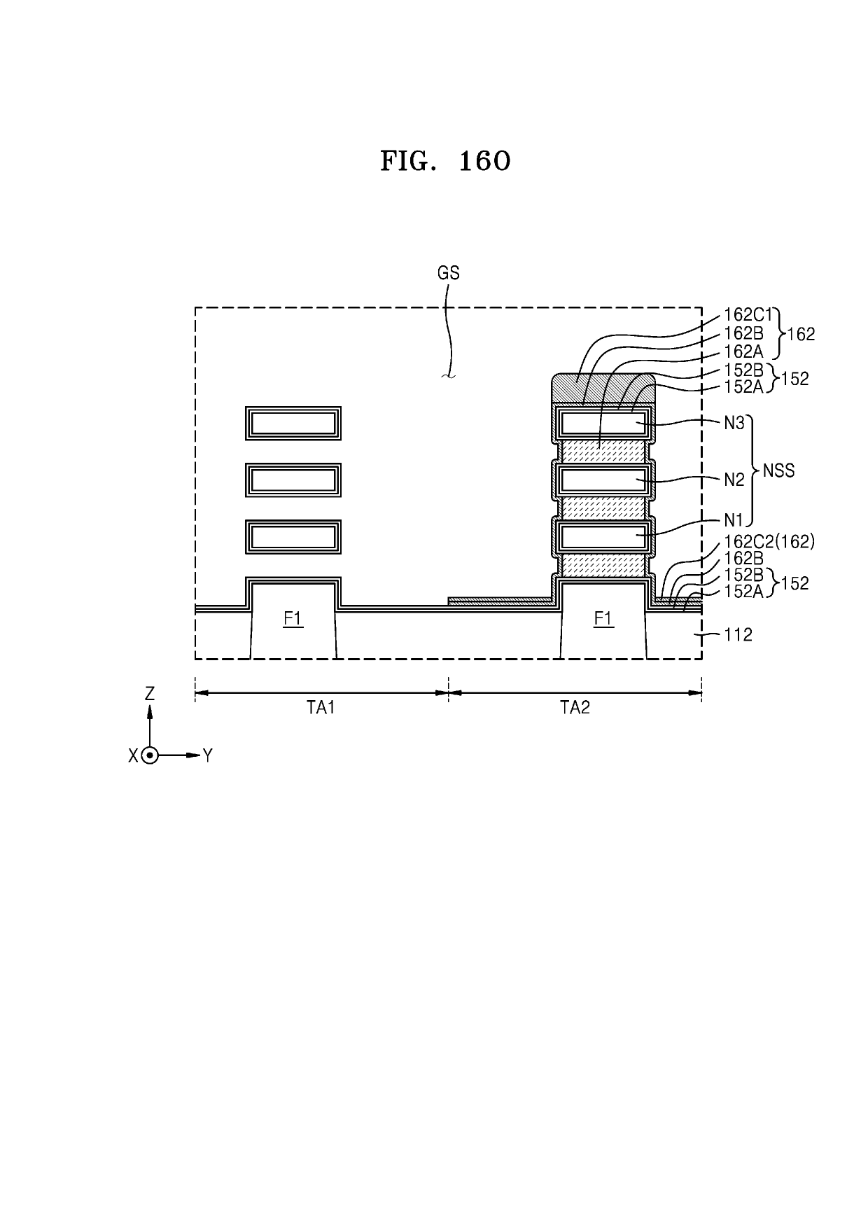

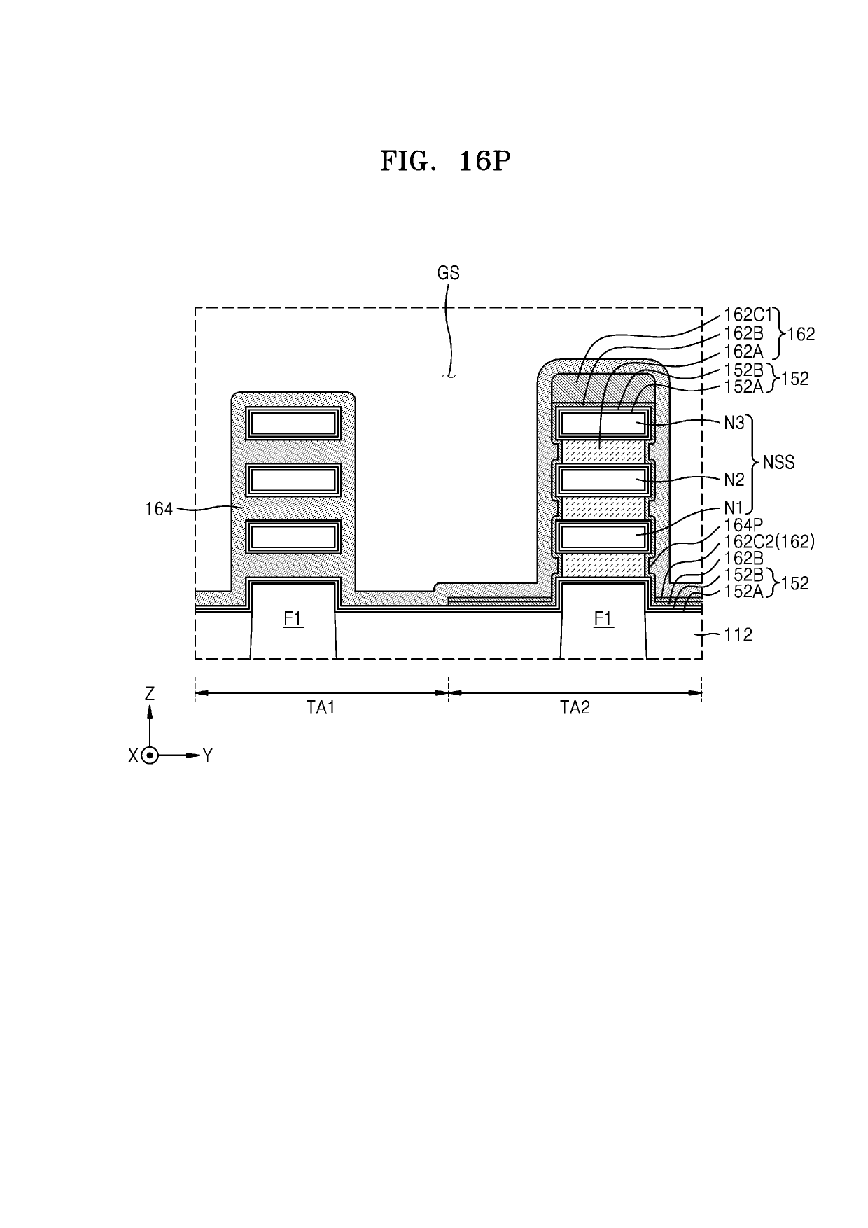

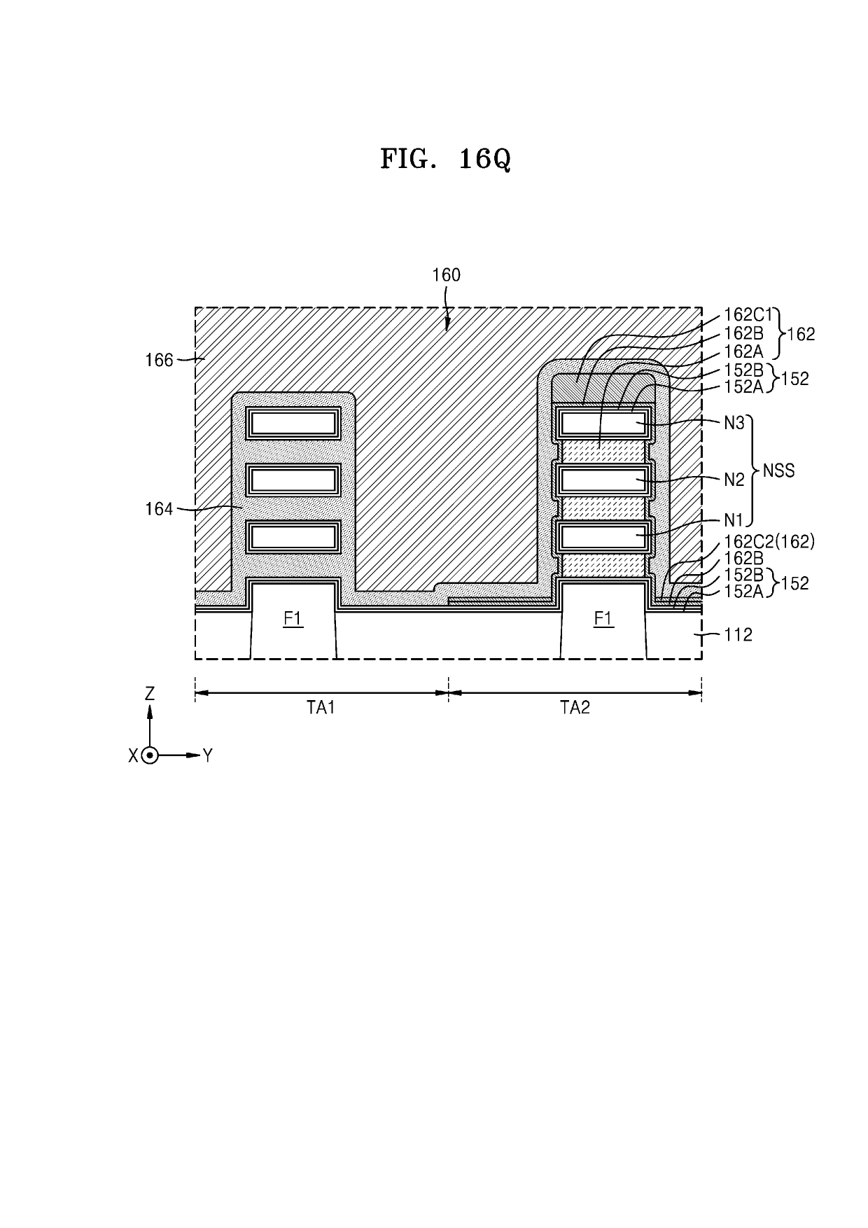

FIGS. 16A to 16Q are cross-sectional views of enlarged cross-sectional configurations corresponding to portion "EX1A" of FIG. 14B, according to a process sequence, to specifically explain the processes of forming the gate dielectric film 152 and the gate line 160 as described with reference to FIGS. 15A and 15B. In FIGS. 16A to 16Q, the same reference numerals are used to denote the same elements as in FIGS. 1 to 4 and 9A to 15B, and thus, repeated descriptions thereof are omitted.

Referring to FIG. 16A, a gate space GS exposing first to third nanosheets N1, N2, and N3, a fin top surface FF, and a device isolation film 112 may be formed as described above with reference to FIGS. 14A and 14B.

Referring to FIG. 16B, a gate dielectric film 152 including a stack structure of an interface film 152A and a high-dielectric film 152B may be formed on an exposed surface of each of the first to third nanosheets N1, N2, and N3, the fin top surface FF, and the device isolation film 112 through the gate space GS.

Referring to FIG. 16C, a protective film PL may be formed to conformally cover exposed surfaces of the gate dielectric film 152 exposed through the gate space GS. The protective film PL may protect the gate dielectric film 152 during subsequent processes. In embodiments, the protective film PL may include a metal oxide film. For example, the protective film PL may include or may be an aluminum oxide film. The protective film PL may be formed by using an ALD process.

Referring to FIG. 16D, a dummy support layer FL1 may be formed to cover the resultant structure of FIG. 16C. In each of the first transistor region TA1 and the second transistor region TA2, the dummy support layer FL1 may include portions filling a space between each pair of adjacent ones of the first to third nanosheets N1, N2, and N3 and a space defined by the protective film PL between a fin-type active region F1 and the first nanosheet N1 and a portion covering the protective film PL on a sidewall of each of the first to third nanosheets N1, N2, and N3.

In embodiments, the dummy support layer FL1 may include a metal nitride. For example, the dummy support layer FL1 may include a TiN film, without being limited thereto. The dummy support layer FL1 may be formed by using an ALD process or a CVD process.

Referring to FIG. 16E, in the resultant structure of FIG. 16D, the dummy support layer FL1 may be partially removed to form a plurality of dummy support patterns FL1A. The plurality of dummy support patterns FL1A may include remaining portions of the dummy support layer FL1 in the space between each pair of adjacent ones of the first to third nanosheets N1, N2, and N3 and the space defined by the protective film PL between the fin-type active region F1 and the first nanosheet N1 in each of the first transistor region TA1 and the second transistor region TA2. In embodiments, a width of the plurality of dummy support patterns FL1A in a second horizontal direction (Y direction) may be less than a width in the second horizontal direction (Y direction) of portions of the protective film PL, which cover the first to third nanosheets N1, N2, and N3.

In embodiments, to form the plurality of dummy support patterns FL1A by partially removing the dummy support layer FL1, a wet etching process, a dry etching process, or a combination thereof may be used/performed. When the dummy support layer FL1 includes a TiN film, because the TiN film has a columnar structure, portions of the TiN film included in the dummy support layer FL1 covering the protective film PL on the sidewall of each of the first to third nanosheets N1, N2, and N3 may be removed at a relatively high etch rate. In contrast, an etch rate of portions filling the space between each pair of adjacent ones of the first to third nanosheets N1, N2, and N3 and the space defined by the protective film PL between the fin-type active region F1 and the first nanosheet N1 may be lower than an etch rate of the dummy support layer FL1 covering the protective film PL of the sidewall of each of the first to third nanosheets N1, N2, and N3. Therefore, after the protective film PL is exposed on the sidewall of each of the first to third nanosheets N1, N2, and N3 by removing portions of the TiN film, which cover the protective film PL on the sidewall of each of the first to third nanosheets N1, N2, and N3, portions of the TiN film, which fill the space between each pair of adjacent ones of the first to third nanosheets N1, N2, and N3 and the space defined by the protective film PL between the fin-type active region F1 and the first nanosheet N1, may not be removed but remained to form the plurality of dummy support patterns FL1A.

Referring to FIG. 16F, in each of the first transistor region TA1 and the second transistor region TA2, dummy protective patterns TL1 may be selectively formed on top surfaces of portions of the protective film PL covering respective uppermost surfaces of a plurality of nanosheet stacks NSS and top surfaces of portions of the protective film PL covering a top surface of a device isolation film 112, from among top surfaces of the protective film PL. The dummy protective patterns TL1 may include a plurality of upper dummy protective patterns TL1A on top surfaces of portions of the protective film PL covering the uppermost surfaces of the plurality of nanosheet stacks NSS, from among the top surfaces of the protective film PL, and a plurality of lower dummy protective patterns TL1B on top surfaces of portions of the protective film PL covering the top surface of the device isolation film 112, from among the top surfaces of the protective film PL. The plurality of upper dummy protective patterns TL1A may be spaced apart from the plurality of lower dummy protective patterns TL1B, e.g., in a vertical direction. A thickness TH51 of each of the plurality of upper dummy protective patterns TL1A in a vertical direction (Z direction) may be greater than a thickness TH52 of each of the plurality of lower dummy protective patterns TL1B in the vertical direction (Z direction).

In embodiments, the dummy protective patterns TL1 may include a metal nitride. For example, the dummy protective patterns TL1 may include a titanium nitride (TiN) film, without being limited thereto. The dummy protective patterns TL1 may be formed by using a PVD process. After the dummy protective patterns TL1 are formed, sidewalls of the plurality of dummy support patterns FL1A may be exposed to the gate space GS between an upper dummy protective pattern TL1A and a lower dummy protective pattern TL1B adjacent thereto.

Referring to FIG. 16G, in the resultant structure of FIG. 16F, a mask pattern MP1 may be formed to selectively cover the first transistor region TA1 and not to cover the second transistor region TA2, from among the first transistor region TA1 and the second transistor region TA2. In embodiments, the mask pattern MP1 may include a hardmask material including a bottom anti-reflective coating (BARC) film or a spin-on-hardmask (SOH) material.

Thereafter, in the second transistor region TA2, the dummy protective patterns TL1 and the plurality of dummy support patterns FL1A may be removed by using the mask pattern MP1 as an etch mask to expose the protective film PL, and the exposed protective film PL may be removed to expose the gate dielectric film 152.

In embodiments, in the second transistor region TA2, the dummy protective patterns TL1, the plurality of dummy support patterns FL1A, and the protective film PL may be removed by using a wet etching process. During the removal of the dummy protective patterns TL1 and the plurality of dummy support patterns FL1A from the second transistor region TA2, a portion of the lower dummy protective patterns TL1B of the dummy protective patterns TL1, which is located in the first transistor region TA1 and exposed toward the second transistor region TA2 under the mask pattern MP1, may have a relatively small thickness. Accordingly, during the etching process of removing the dummy protective patterns TL1 and the plurality of dummy support patterns FL1A from the second transistor region TA2, a portion of the dummy protective patterns TL1, which is located in the first transistor region TA1, may be prevented from being undesirably etched from the portion exposed toward the second transistor region TA2. Thus, a serious lateral recess may be prevented from being formed in the dummy protective patterns TL1. During the removal of the dummy protective patterns TL1 and the plurality of dummy support patterns FL1A from the second transistor region TA2, a relatively great lateral recess may be formed in the dummy protective pattern TL1 located in the first transistor region TA1, e.g., when the thickness TH52 of the lower dummy protective pattern TL1B is relatively thick. In this case, structures in the first transistor region TA1 may be damaged due to the lateral recess. According to the inventive concept, because a portion of the lower dummy protective pattern TL1B of the dummy protective pattern TL1, which is located in the first transistor region TA1 and exposed toward the second transistor region TA2 under the mask pattern MP1, has the relatively small thickness, there may be no concern that the structures in the first transistor region TA1 are damaged. For example, the thin thickness TH52 of the lower dummy protective pattern TL1B may be beneficial for the process of the present embodiment.

Referring to FIG. 16H, the mask pattern MP1 may be removed from the resultant structure of FIG. 16G, and thus, the plurality of dummy support patterns FL1A, the dummy protective patterns TL1, and the protective film PL may be exposed in the first transistor region TA1. The mask pattern MP1 may be removed by using ashing and stripping processes.

FIG. 16H illustrates a case in which the plurality of lower dummy protective patterns TL1B covering the protective film PL remain on the top surface of the device isolation film 112 in the resultant structure from which the mask pattern MP1 has been removed, but the inventive concept is not limited thereto. For example, during the removal of the mask pattern MP1, at least portions of the plurality of lower dummy protective patterns TL1B having the relatively small thickness may be removed together, and thus, the protective film PL may be exposed on the top surface of the device isolation film 112.

Referring to FIG. 16I, a work-function metal-containing film 162L of a second conductivity type may be formed to cover the entire surface of the resultant structure of FIG. 16H in the first transistor region TA1 and the second transistor region TA2.

In the second transistor region TA2, the work-function metal-containing film 162L may be in contact with the gate dielectric film 152. In the second transistor region TA2, the work-function metal-containing film 162L may include portions filling a space between each pair of adjacent ones of the first to third nanosheets N1, N2, and N3 and a space defined by the gate dielectric film 152 between the fin-type active region F1 and the first nanosheet N1, portions covering the gate dielectric film 152 on the sidewall of each of the first to third nanosheets N1, N2, and N3, and portions covering the gate dielectric film 152 on the device isolation film 112. The work-function metal-containing film 162L may include or may be a P-type work-function metal-containing film, for example, a P-type metal nitride film. In embodiments, the work-function metal-containing film 162L may include or may be a titanium nitride (TiN) film, a tungsten nitride (WN) film, or a molybdenum nitride (MoN) film. For example, the work-function metal-containing film 162L may include or may be a TiN film, without being limited thereto.

In embodiments, the work-function metal-containing film 162L may include the same constituent material as the plurality of dummy support patterns FL1A and the dummy protective pattern TL1 in the first transistor region TA1. The work-function metal-containing film 162L may be formed by using an ALD process or a CVD process.

Referring to FIG. 16J, in the resultant structure of FIG. 16I, the work-function meal-containing film 162L may be partially removed to form a plurality of work-function metal-containing patterns 162A. The plurality of work-function metal-containing patterns 162A may include remaining portions of the work-function metal-containing film 162L in the space between each pair of adjacent ones of the first to third nanosheets N1, N2, and N3 and the space defined by the gate dielectric film 152 between the fin-type active region F1 and the first nanosheet N1 in the second transistor region TA2. As described above with reference to FIG. 4, a second width W12 of each of the plurality of work-function metal-containing patterns 162A may be less than or equal to a first width W11 of the first to third nanosheets N1, N2, and N3. In the first transistor region TA1, after the work-function metal-containing film 162L is partially removed, the sidewalls of each of the plurality of dummy support patterns FL1A and a portion of the protective film PL may be exposed.

To form the plurality of work-function metal-containing patterns 162A in the second transistor region TA2 by partially removing the work-function metal-containing film 162L, a wet etching process, a dry etching process, or a combination thereof may be used. When the work-function metal-containing film 162L includes or is a TiN film, because the TiN film has a columnar structure, portions of the TiN film included in the work-function metal-containing film 162L covering the protective film PL on the sidewall of each of the first to third nanosheets N1, N2, and N3 may be removed at a relatively high etch rate. In contrast, an etch rate of portions filling the space between each pair of adjacent ones of the first to third nanosheets N1, N2, and N3 and the space defined by the gate dielectric film 152 between the fin-type active region F1 and the first nanosheet N1 may be lower than an etch rate of the work-function metal-containing film 162L on the sidewall of each of the first to third nanosheets N1, N2, and N3. Therefore, in the second transistor region TA2, after the gate dielectric film 152 is exposed on the sidewall of each of the first to third nanosheets N1, N2, and N3 by removing portions of the TiN film, which cover the gate dielectric film 152 on the sidewall of each of the first to third nanosheets N1, N2, and N3, portions of the TiN film, which fill the space between each pair of adjacent ones of the first to third nanosheets N1, N2, and N3 and the space defined by the gate dielectric film 152 between the fin-type active region F1 and the first nanosheet N1, may not be removed but remained to form the plurality of work-function metal-containing patterns 162A.

Referring to FIG. 16K, in the first transistor region TA1 and the second transistor region TA2, a work-function metal-containing liner 162B may be formed to conformally cover the entire surface of the resultant structure of FIG. 16J. The work-function metal-containing liner 162B may be formed by using an ALD process. In embodiments, the work-function metal-containing liner 162B may include the same material as the plurality of dummy support patterns FL1A in the first transistor region TA1. For example, the work-function metal-containing liner 162B and the plurality of dummy support patterns FL1A may include the same material and may be selected from a TiN film, a WN film, and a MoN film.

Referring to FIG. 16L, in each of the first transistor region TA1 and the second transistor region TA2, a work-function metal-containing block layer TL2 may be selectively formed on top surfaces of portions of the work-function metal-containing liner 162B covering respective uppermost surfaces of the plurality of nanosheet stacks NSS and top surfaces of portions of the work-function metal-containing liner 162B covering the top surface of the device isolation film 112, from among top surfaces of the work-function metal-containing liner 162B. The work-function metal-containing block layer TL2 may include a plurality of upper work-function metal-containing block layers TL2A on the top surfaces of the work-function metal-containing liner 162B covering the uppermost surfaces of the plurality of nanosheet stacks NSS, from among the top surfaces of the work-function metal-containing liner 162B, and a plurality of lower work-function metal-containing block layers TL2B on the top surfaces of the work-function metal-containing liner 162B covering the top surface of the device isolation film 112, from among the top surfaces of the work-function metal-containing liner 162B. The plurality of upper work-function metal-containing block layers TL2A may be spaced apart from the plurality of lower work-function metal-containing block layers TL2B, e.g., in a vertical direction. A thickness TH61 of each of the plurality of upper work-function metal-containing block layers TL2A in a vertical direction (Z direction) may be greater than a thickness TH62 of each of the plurality of lower work-function metal-containing block layers TL2B in the vertical direction (Z direction).

In embodiments, the work-function metal-containing block layer TL2 may include a metal nitride. For example, the work-function metal-containing block layer TL2 may include a TiN film, without being limited thereto. The work-function metal-containing block layer TL2 may be formed using a PVD process. After the work-function metal-containing block layer TL2 is formed, the work-function metal-containing liner 162B may be exposed to the gate space GS between the upper work-function metal-containing block layer TL2A and the lower work-function metal-containing block layer TL2B adjacent thereto.

Referring to FIG. 16M, a mask pattern MP2 selectively covering the second transistor region TA2 and not covering the first transistor region TA1, from among the first transistor region TA1 and the second transistor region TA2, may be formed in the resultant structure of FIG. 16L. In embodiments, the mask pattern MP2 may include a hardmask material including a BARC film or an SOH material.

Thereafter, in the first transistor region TA1, the work-function metal-containing block layer TL2, the work-function metal-containing liner 162B, and the plurality of dummy support patterns FL1A may be removed by using the mask pattern MP2 as an etch mask to expose the protective film PL. An upper work-function metal-containing block 162C1 and a lower work-function metal-containing block 162C2, which include the remaining portions of the work-function metal-containing block layer TL2, may be formed in the second transistor region TA2.

In embodiments, in the first transistor region TA1, the work-function metal-containing block layer TL2, the work-function metal-containing liner 162B, and the plurality of dummy support patterns FL1A may be removed by using a wet etching process. During the removal of the work-function metal-containing block layer TL2, the work-function metal-containing liner 162B, and the plurality of dummy support patterns FL1A from the first transistor region TA1, a portion of the lower work-function metal-containing block layer TL2B of the work-function metal-containing block layer TL2, which is located in the second transistor region TA2 and exposed toward the first transistor region TA1 under the mask pattern MP2, may have a relatively small thickness. Accordingly, during the etching process of removing the work-function metal-containing block layer TL2, the work-function metal-containing liner 162B, and the plurality of dummy support patterns FL1A from the first transistor region TL1, a portion of the work-function metal-containing block layer TL2, which is located in the second transistor region TA2, may be prevented from being undesirably etched from the portion exposed toward the first transistor region TA1. Thus, a serious lateral recess may be prevented from being formed in the work-function metal-containing block layer TL2. During the removal of the work-function metal-containing block layer TL2, the work-function metal-containing liner 162B, and the plurality of dummy support patterns FL1A from the first transistor region TA1, a relatively great lateral recess may be formed in the work-function metal-containing block layer TL2 located in the second transistor region TA2, e.g., when the thickness TH62 of the lower work-function metal-containing block layer TL2B is relatively thick. In this case, structures in the second transistor region TA2 may be damaged through the lateral recess. According to the inventive concept, because a portion of the lower work-function metal-containing block layer TL2B of the work-function metal-containing block layer TL2, which is located in the second transistor region TA2 and exposed toward the first transistor region TA1 under the mask pattern MP2, has the relatively small thickness, there may be no concern that the structures in the second transistor region TA2 are damaged. For example, the thin thickness TH62 of the lower work-function metal-containing block layer TL2B may be beneficial for the process of the present embodiment.

After the work-function metal-containing block layer TL2, the work-function metal-containing liner 162B, and the plurality of dummy support patterns FL1A are removed from the first transistor region TA1, a portion of the upper work-function metal-containing block layer TL2A of the work-function metal-containing block layer TL2, which remains in the second transistor region TA2, may be remained as the upper work-function metal-containing block 162C1, while a portion of the lower work-function metal-containing block layer TL2B of the work-function metal-containing block layer TL2, which remains in the second transistor region TA2, may be remained as the lower work-function metal-containing block 162C2.

Referring to FIG. 16N, the mask pattern MP2 may be removed from the resultant structure of FIG. 16M, and thus, the upper work-function metal-containing block 162C1, the lower work-function metal-containing block 162C2, and the work-function metal-containing liner 162B may be exposed in the second transistor region TA2. The mask pattern MP2 may be removed by using ashing and stripping processes.

Referring to FIG. 16O, the protective film PL in the first transistor region TA1 may be selectively removed from the resultant structure of FIG. 16N, and thus, the gate dielectric film 152 may be exposed in the first transistor region TA1.

Referring to FIG. 16P, a blanket work-function metal-containing layer 164 may be formed on the entire surface of the resultant structure of FIG. 16O. The blanket work-function metal-containing layer 164 may be formed to surround the first to third nanosheets N1, N2, and N3 in the first transistor region TA1 and to include portions filling a space between each pair of adjacent ones of the first to third nanosheets N1, N2, and N3 and a space defined by the gate dielectric film 152 between the fin-type active region F1 and the first nanosheet N1 and a portion covering the gate dielectric film 152 on the sidewall of each of the first to third nanosheets N1, N2, and N3. In addition, the blanket work-function metal-containing layer 164 may be formed to surround the first to third nanosheets N1, N2, and N3 and the work-function metal-containing structure 162 in the second transistor region TA2.

During the formation of the blanket work-function metal-containing layer 164, a plurality of protrusions 164P may be formed on an inner surface of the blanket work-function metal-containing layer 164, which is in contact with the work-function metal-containing liner 162B. The plurality of protrusions 164P may protrude toward respective regions between the first to third nanosheets N1, N2, and N3 surrounded by the work-function metal-containing structure 162. The plurality of protrusions 164P may be in contact with a plurality of concave surfaces included in a rough surface of the blanket work-function metal-containing layer 164.

Referring to FIG. 16Q, in the resultant structure of FIG. 16P, a gap-fill metal film 166 covering the work-function metal-containing structure 162 may be formed to form a gate line 160 in the first transistor region TA1 and the second transistor region TA2.

As described above with reference to FIGS. 15A and 15B, a plurality of capping insulating patterns 168 may be formed to cover a top surface of each of the gate line 160, the gate dielectric film 152, and the insulating spacer 118. Thereafter, as illustrated in FIGS. 2 and 3, source/drain contact holes respectively exposing the plurality of source/drain regions 130 may be formed between every pair of adjacent ones of a plurality of gate lines 160. Then, metal silicide films 172 may be formed on surfaces of the plurality of source/drain regions 130 through the source/drain contact holes, and source/drain contacts CA filling respective source/drain contact holes may be formed on the metal silicide films 172.

Next, an etch stop film 182 and an upper insulating film 184 may be sequentially formed to cover a top surface of each of the source/drain contact CA, the plurality of capping insulating patterns 168, and the inter-gate dielectric film 144 to form an upper insulating structure 180. Afterwards, a plurality of source/drain via contacts VA, a plurality of gate contacts, and a plurality of shared contacts may be formed. The plurality of source/drain via contacts VA may pass through the upper insulating structure 180 in the vertical direction (Z direction) and be electrically connected to and/or contact the source/drain contacts CA. The plurality of gate contacts may pass through the upper insulating structure 180 and the capping insulating pattern 168 in the vertical direction (Z direction) and be electrically connected to and/or contact the gate lines 160. The plurality of shared contacts may electrically connect the gate lines 160 to the source/drain contacts CA. Thereafter, an interlayer insulating film 186 may be formed to cover the upper insulating structure 180, and a plurality of first wiring layers M1 may be formed to pass through the interlayer insulating film 186. Subsequently, a frontside wiring structure FWS may be formed on the interlayer insulating film 186 and the plurality of first wiring layers M1, and thus, the IC device 100 described with reference to FIGS. 1 to 4 may be manufactured.

According to the method of manufacturing the IC device 100 described with reference to FIGS. 9A to 16Q, as in the processes described with reference to FIGS. 16F and 16G, when the dummy support pattern FL1A and the dummy protective pattern TL1, which are unnecessary in the final structure of the IC device 100, are removed from the second transistor region TA2 while protecting the dummy support pattern FL1A and the dummy protective pattern TL1 in the first transistor region TA1, a portion of the lower dummy protective pattern TL1B of the dummy protective pattern TL1, which is exposed toward the second transistor region TA2 under the mask pattern MP1, may have a relatively small thickness. Accordingly, it may be possible to prevent a problem of damage to structures in the first transistor region TA1 due to undesirable etching of a portion of the dummy protective pattern TL1, which is located in the first transistor region TA1 and exposed toward the second transistor region TA2, by an etching atmosphere during the removal of the dummy support pattern FL1A and the dummy protective pattern TL1, which are unnecessary in the final structure of the IC device 100, from the second transistor region TA2.

In addition, as in the processes described with reference to FIGS. 16L and 16M, when the plurality of work-function metal-containing patterns 162A, the work-function metal-containing liner 162B, and the work-function metal-containing block layer TL2, which are unnecessary in the final structure of the IC device 100, are removed from the first transistor region TA1 while protecting the plurality of work-function metal-containing patterns 162A, the work-function metal-containing liner 162B, and the work-function metal-containing block layer TL2, which remain to form the work-function metal-containing structure 162 in the second transistor region TA2, a portion of the work-function metal-containing block layer TL2, which is exposed toward the first transistor region TA1 under the mask pattern MP2, may have a relatively small thickness. Accordingly, it may be helpful to prevent a problem of damage to structures in the second transistor region TA2 due to undesirable etching of a portion of the work-function metal-containing block layer TL2, which is located in the second transistor region TA2 and exposed toward the first transistor region TA1, by an etching atmosphere/process during the removal of the plurality of work-function metal-containing patterns 162A, the work-function metal-containing liner 162B, and the work-function metal-containing block layer TL2, which are unnecessary in the final structure of the IC device 100, from the first transistor region TA1.

Therefore, according to the method of manufacturing the IC device 100, which has been described with reference to FIGS. 9A to 16Q, even when an area of each of the first transistor region TA1 and the second transistor region TA2 having different channel types is reduced and a distance between the first transistor region TA1 and the second transistor region TA2 is reduced due to the downscaling of the IC device 100, the likelihood of process defects may be eliminated during the process of manufacturing the IC device 100. Thus, different electrical characteristics respectively required for the first transistor region TA1 and the second transistor region TA2 may be stably ensured according to various arrangement structures in the IC device 100 including the first transistor region TA1 and the second transistor region TA2, and the performance and reliability of each of the first transistor region TA1 and the second transistor region TA2 may be ensured.

To manufacture the IC devices 200 and 300 described with reference to FIGS. 5 and 6, the processes described with reference to FIGS. 9A to 15B and 16A to 16Q may be performed. However, as described with reference to FIG. 16J, by controlling a removed amount of the work-function metal-containing film 162L during the process of partially removing the work-function metal-containing film 162L, the plurality of work-function metal-containing patterns 262A illustrated in FIG. 5 or the plurality of work-function metal-containing patterns 362A illustrated in FIG. 6 may be formed.

To manufacture the IC device 400 described with reference to FIGS. 7 and 8, the processes described with reference to FIGS. 9A to 15B and 16A to 16Q may be performed. However, after the frontside wiring structure FWS is formed, a substrate 102 may be removed from a backside surface of the substrate 102, and each of the plurality of fin-type active regions F1 and the device isolation film 112 may be partially removed. As a result, a backside surface BS of each of the plurality of fin-type active regions F1 and a backside surface 112B of the device isolation film 112 may be exposed. In embodiments, to remove the substrate 102 and partially remove each of the plurality of fin-type active regions F1 and the device isolation film 112, at least one process selected from a mechanical grinding process, a chemical mechanical polishing (CMP) process, a wet etching process, and a combination thereof may be used.

Afterwards, a contact hole exposing a selected one of the plurality of source/drain regions 130 may be formed, e.g., in a fin-type active region F1. During the formation of the contact hole, a lower portion of the selected source/drain region 130 may be consumed, and thus, a bottom surface of the selected source/drain region 130 may have a concave shape toward the inside of the contact hole corresponding thereto. In this way, a plurality of contact holes may be formed in the fin-type active regions F1.

Thereafter, a backside insulating spacer 492 may be formed to cover an inner sidewall of each of the plurality of contact holes, a metal silicide film 490 may be formed on a surface of the selected source/drain region 130 through the contact hole defined by the backside insulating spacer 492, and a backside contact DBC may be formed to fill the contact hole. Subsequently, a backside interlayer insulating film 496 may be formed to cover the backside contact DBC, the backside surface BS of the fin-type active region F1, and the backside surface 112B of the device isolation film 112, and a power rail wring MPR may pass through the backside interlayer insulating film 496 and be electrically connected to and/or contact the backside contact DBC.

Although examples of the methods of manufacturing the IC devices 100, 200, 300, and 400 illustrated in FIGS. 1 to 8 have been described with reference to FIGS. 9A to 15B and 16A to 16Q, it will be understood that the IC devices 100, 200, 300, and 400 illustrated in FIGS. 1 to 8 may be modified in various ways and manufactured with various modifications and changes to the processes described with reference to FIGS. 9A to 15B and 16A to 16Q within the scope of the inventive concept.

For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a fin-type active region extending in a first horizontal direction;
a nanosheet stack spaced apart in a vertical direction from a fin top surface of the fin-type active region, the nanosheet stack comprising a plurality of nanosheets vertically overlapping the fin top surface of the fin-type active region;
a device isolation film covering sidewalls of the fin-type active region; and
a gate line extending in a second horizontal direction on the fin-type active region and the device isolation film, the gate line comprising a work-function metal-containing structure surrounding the plurality of nanosheets, wherein the second horizontal direction intersects the first horizontal direction,
wherein a first thickness in the vertical direction of a portion of the work-function metal-containing structure, which covers a top surface of the nanosheet stack, is greater than a second thickness in the second horizontal direction of a portion of the work-function metal-containing structure, which covers a sidewall of the nanosheet stack.

2. The integrated circuit device of claim 1, wherein each of both sidewalls of the work-function metal-containing structure in the second horizontal direction comprises a concave surface and a convex surface.

3. The integrated circuit device of claim 1, wherein the work-function metal-containing structure comprises:
a plurality of work-function metal-containing patterns respectively arranged between the plurality of nanosheets and arranged in a line in the vertical direction;
a work-function metal-containing liner covering the plurality of nanosheets and the plurality of work-function metal-containing patterns; and
an upper work-function metal-containing block covering an uppermost surface of the work-function metal-containing liner,
wherein a thickness of the upper work-function metal-containing block in the vertical direction is greater than a thickness of each of the plurality of work-function metal-containing patterns in the vertical direction.

4. The integrated circuit device of claim 3, wherein, in the second horizontal direction, a width of each of the plurality of work-function metal-containing patterns is equal to or less than a width of each of the plurality of nanosheets.

5. The integrated circuit device of claim 3, wherein the work-function metal-containing liner of the work-function metal-containing structure comprises a vertical extension and a lateral extension, the vertical extension covering a sidewall of each of the plurality of nanosheets and the plurality of work-function metal-containing patterns, and the lateral extension overlapping the device isolation film in the vertical direction, and
the work-function metal-containing structure further comprises a lower work-function metal-containing block spaced apart from the upper work-function metal-containing block, wherein the lower work-function metal-containing block covers the lateral extension of the work-function metal-containing liner at a position overlapping the device isolation film in the vertical direction, and in the vertical direction, a thickness of the lower work-function metal-containing block is less than a thickness of the upper work-function metal-containing block.

6. The integrated circuit device of claim 1, wherein the first thickness of the work-function metal-containing structure is greater than a third thickness in the vertical direction of a portion of the work-function metal-containing structure, which covers the device isolation film.

7. The integrated circuit device of claim 1, further comprising a gate dielectric film between the plurality of nanosheets and the gate line,
wherein the work-function metal-containing structure comprises:
a plurality of work-function metal-containing patterns respectively arranged between the plurality of nanosheets and arranged in a line in the vertical direction;
a work-function metal-containing liner covering the plurality of nanosheets and the plurality of work-function metal-containing patterns; and
an upper work-function metal-containing block covering an uppermost surface of the work-function metal-containing liner,
wherein the gate dielectric film comprises portions in contact with the plurality of work-function metal-containing patterns and portions in contact with the work-function metal-containing liner, and
wherein the gate dielectric film is spaced apart in the vertical direction from the upper work-function metal-containing block, with the work-function metal-containing liner therebetween.

8. The integrated circuit device of claim 1, wherein the gate line further comprises a blanket work-function metal-containing layer surrounding the work-function metal-containing structure on the fin-type active region, the blanket work-function metal-containing layer having a conductivity type different from a conductivity type of the work-function metal-containing structure,
each of both sidewalls of the work-function metal-containing structure in the second horizontal direction comprises a plurality of convex surfaces and a plurality of concave surfaces, and
the blanket work-function metal-containing layer comprises a plurality of protrusions in contact with the plurality of concave surfaces, the plurality of protrusions protruding toward respective regions between the plurality of nanosheets.

9. An integrated circuit device comprising:
a first fin-type active region extending in a first horizontal direction in a first transistor region;
a second fin-type active region extending in the first horizontal direction in a second transistor region;
a first nanosheet stack spaced apart in a vertical direction from a first fin top surface of the first fin-type active region, the first nanosheet stack comprising a plurality of first region nanosheets vertically overlapping the first fin top surface of the first fin-type active region;
a second nanosheet stack spaced apart in the vertical direction from a second fin top surface of the second fin-type active region, the second nanosheet stack comprising a plurality of second region nanosheets vertically overlapping the second fin top surface of the second fin-type active region; and
a gate line surrounding the plurality of first region nanosheets and the plurality of second region nanosheets, the gate line extending in a second horizontal direction, wherein the second horizontal direction intersects the first horizontal direction,
wherein the gate line comprises:
a blanket work-function metal-containing layer of a first conductivity type surrounding the plurality of first region nanosheets; and
a work-function metal-containing structure of a second conductivity type surrounding the plurality of second region nanosheets,
wherein a first thickness in the vertical direction of a portion of the work-function metal-containing structure, which covers a top surface of the second nanosheet stack, is greater than a second thickness in the second horizontal direction of a portion of the work-function metal-containing structure, which covers a sidewall of the second nanosheet stack.

10. The integrated circuit device of claim 9, wherein each of both sidewalls of the work-function metal-containing structure in the second horizontal direction comprises a concave surface and a convex surface.

11. The integrated circuit device of claim 9, wherein a sidewall of the work-function metal-containing structure, which faces the first nanosheet stack, has a rough surface,
in the rough surface, first surfaces covering the plurality of second region nanosheets comprise convex surfaces protruding toward the first nanosheet stack, and,
in the rough surface, second surfaces covering respective regions between the plurality of second region nanosheets comprise concave surfaces that are concave toward the first nanosheet stack.

12. The integrated circuit device of claim 9, wherein the work-function metal-containing structure comprises:
a plurality of work-function metal-containing patterns respectively arranged between the plurality of second region nanosheets and arranged in a line in the vertical direction;
a work-function metal-containing liner covering the plurality of second region nanosheets and the plurality of work-function metal-containing patterns; and
an upper work-function metal-containing block covering an uppermost surface of the work-function metal-containing liner,
wherein a thickness of the upper work-function metal-containing block in the vertical direction is greater than a thickness of each of the plurality of work-function metal-containing patterns in the vertical direction.

13. The integrated circuit device of claim 12, wherein, in the second horizontal direction, a width of each of the plurality of work-function metal-containing patterns is less than or equal to a width of each of the plurality of second region nanosheets.

14. The integrated circuit device of claim 12, wherein, in the second horizontal direction, a width of each of the plurality of work-function metal-containing patterns is greater than a width of each of the plurality of second region nanosheets.

15. The integrated circuit device of claim 12, further comprising a device isolation film overlapping the gate line in the vertical direction, the device isolation film covering sidewalls of each of the first fin-type active region and the second fin-type active region,
wherein the work-function metal-containing liner of the work-function metal-containing structure comprises a vertical extension covering a sidewall of each of the plurality of second region nanosheets and a lateral extension overlapping the device isolation film in the vertical direction,
the work-function metal-containing structure further comprises a lower work-function metal-containing block spaced apart from the upper work-function metal-containing block, wherein the lower work-function metal-containing block covers the lateral extension of the work-function metal-containing liner at a position overlapping the device isolation film in the vertical direction, and
a thickness of the lower work-function metal-containing block is less than a thickness of the upper work-function metal-containing block in the vertical direction.

16. The integrated circuit device of claim 9, further comprising a device isolation film overlapping the gate line in the vertical direction, the device isolation film covering sidewalls of each of the first fin-type active region and the second fin-type active region,
wherein the first thickness of the work-function metal-containing structure is greater than a third thickness in the vertical direction of a portion of the work-function metal-containing structure, which covers the device isolation film.

17. The integrated circuit device of claim 9, wherein the blanket work-function metal-containing layer comprises a first region portion surrounding the first region nanosheets in the first transistor region and a second region portion surrounding the second region nanosheets, in the second transistor region, and
the work-function metal-containing structure comprises a portion between the second nanosheet stack and the blanket work-function metal-containing layer, in the second transistor region.

18. The integrated circuit device of claim 9, wherein the gate line further comprises a gap-fill metal film covering the blanket work-function metal-containing layer and the work-function metal-containing structure.

19. An integrated circuit device comprising:
a first fin-type active region extending in a first horizontal direction in an NMOS transistor region;
a second fin-type active region extending in the first horizontal direction in a PMOS transistor region;
a device isolation film covering both sidewalls of the first fin-type active region and the second fin-type active region in a second horizontal direction, wherein the second horizontal direction intersects the first horizontal direction;
a first nanosheet stack spaced apart in a vertical direction from a first fin top surface of the first fin-type active region, the first nanosheet stack comprising a plurality of first region nanosheets vertically overlapping the first fin top surface of the first fin-type active region;
a second nanosheet stack spaced apart in the vertical direction from a second fin top surface of the second fin-type active region, the second nanosheet stack comprising a plurality of second region nanosheets vertically overlapping the second fin top surface of the second fin-type active region; and
a gate line extending in the second horizontal direction on the first fin-type active region, the second fin-type active region, and the device isolation film,
wherein the gate line comprises:
a P-type work-function metal-containing structure surrounding the plurality of second region nanosheets; and
an N-type blanket work-function metal-containing layer comprising a portion surrounding the plurality of first region nanosheets and a portion surrounding the plurality of second region nanosheets and the P-type work-function metal-containing structure,
wherein a first thickness in the vertical direction of a portion of the P-type work-function metal-containing structure, which covers a top surface of the second nanosheet stack, is greater than a second thickness in the second horizontal direction of a portion of the P-type work-function metal-containing structure, which covers a sidewall of the second nanosheet stack, and
each of both sidewalls of the P-type work-function metal-containing structure in the second horizontal direction comprises concave surfaces and convex surfaces.

20. The integrated circuit device of claim 19, wherein the P-type work-function metal-containing structure comprises:
a plurality of P-type work-function metal-containing patterns respectively arranged between the plurality of second region nanosheets and arranged in a line in the vertical direction;
a P-type work-function metal-containing liner covering the plurality of second region nanosheets and the plurality of P-type work-function metal-containing patterns; and
an upper P-type work-function metal-containing block covering an uppermost surface of the P-type work-function metal-containing liner,
wherein the N-type blanket work-function metal-containing layer comprises a plurality of protrusions protruding toward the concave surfaces of the P-type work-function metal-containing structure.
